(19) United States
(12) Patent Application Publication
(10) Pub. No.: US 2025/0040388 A1
(43) Pub. Date: Jan. 30, 2025

(54) DISPLAY DEVICE

(71) Applicant: SEMICONDUCTOR ENERGY LABORATORY CO., LTD., Atsugi-shi (JP)

(72) Inventors: Kunio KIMURA, Zama, (JP); Takuya KAWATA, Atsugi, (JP); Yukiko HONDA, Ebina (JP); Noriko SHIBATA, Atsugi (JP)

(21) Appl. No.: 18/783,679

(22) Filed: Jul. 25, 2024

(30) Foreign Application Priority Data
Jul. 28, 2023 (JP) 2023-123339

(51) Int. Cl. H10K 59/35; H10K 59/80

(52) U.S. Cl. CPC H10K 59/351; H10K 59/8051; H10K 59/8052

(57) ABSTRACT

A display device includes first to third light-emitting devices. The first light-emitting device includes a first anode, a first cathode, and a first light-emitting layer between the first anode and the first cathode. The second light-emitting device includes a second anode, a second cathode, and a second light-emitting layer between the second anode and the second cathode. The third light-emitting device includes a third anode; a third cathode; and a third light-emitting layer and a fourth light-emitting layer between the third anode and the third cathode. The fourth light-emitting layer is between the third light-emitting layer and the third cathode and is in contact with the third light-emitting layer. The first to third light-emitting devices have different emission colors. The first and third light-emitting layers include a first light-emitting substance. The second and fourth light-emitting layers include a second light-emitting substance. A peak wavelength of an emission spectrum of the first light-emitting substance and a peak wavelength of an emission spectrum of the second light-emitting substance are different from each other.

### BACKGROUND OF THE INVENTION

### 1. Field of the Invention

One embodiment of the present invention relates to a display device. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specifically, examples of the technical field of one embodiment of the present invention disclosed in this specification include a semiconductor device, a display device, a liquid crystal display device, a light-emitting apparatus, a lighting device, a power storage device, a memory device, an image capturing device, a driving method thereof, and a manufacturing method thereof.

### 2. Description of the Related Art

Light-emitting devices (organic EL devices) that include organic compounds and utilize electroluminescence (EL) have been put to practical use. In the basic structure of such light-emitting devices, an organic compound layer (EL layer) including a light-emitting material is sandwiched between a pair of electrodes. Carriers are injected by application of voltage to the device, and recombination energy of the carriers is used to obtain light emission from the light-emitting material.

Such light-emitting devices are of self-luminous type and thus have advantages over liquid crystal devices such as high visibility and no need for backlight when used in pixels of a display, and are suitable as devices used in flat panel displays. Displays that include such light-emitting devices are also highly advantageous in that they can be thin and lightweight. Another feature of such light-emitting devices is that they have an extremely fast response speed.

Displays that include organic EL devices sometimes need to be provided with not only subpixels of three colors of red, green, and blue but also a subpixel of the fourth color, e.g., yellow, to achieve improved color expression. In one example method for achieving such a display, a subpixel of the fourth color is formed using a light-emitting device that includes a yellow-light-emitting substance. Patent Document 1 discloses a yellow-light-emitting substance and a light-emitting device including this substance.

In another example method for achieving such a display, single-type light-emitting devices emitting red light, green light, and blue light and a tandem-type light-emitting device fabricated using the same materials as the single-type light-emitting devices are formed over one substrate and the tandem-type light-emitting device is used to form a subpixel of the fourth color. Patent Document 2 discloses a structure of a display in which a single-type light-emitting device and a tandem-type light-emitting device are provided over one substrate.

### REFERENCES

### Patent Documents

[Patent Document 1] Japanese Published Patent Application No. 2019-214726
[Patent Document 2] United States Patent Application Publication No. 2016/0155378

### SUMMARY OF THE INVENTION

In dealing with the need for a subpixel of the fourth color, employing the manufacturing method in which a light-emitting device is fabricated using a light-emitting substance and a light-emitting layer of the fourth color requires additional steps, masks, and materials, which might increase the manufacturing cost.

Employing the method in which both the single-type light-emitting device and the tandem-type light-emitting device are formed over one substrate also requires additional steps and materials for an intermediate layer (a charge-generation layer) and the like in the tandem-type light-emitting device. Moreover, in a display with such a structure, the voltage applied to the single-type light-emitting device needs to be different from the voltage applied to the tandem-type light-emitting device, necessitating an additional circuit structure and possibly increasing the manufacturing cost.

Thus, an object of one embodiment of the present invention is to provide a display device in which a subpixel of the fourth color is formed without adding a step, a mask, a material, a circuit structure, or the like. Another object of one embodiment of the present invention is to provide a display device with reduced manufacturing cost. Another object of one embodiment of the present invention is to provide an inexpensive display device. Another object of one embodiment of the present invention is to provide a novel display device.

Note that the description of these objects does not preclude the existence of other objects. In one embodiment of the present invention, there is no need to achieve all of these objects. Other objects will be apparent from and can be derived from the description of the specification, the drawings, the claims, and the like.

One embodiment of the present invention is a display device including first to third light-emitting devices. The first light-emitting device includes a first anode, a first cathode, and a first light-emitting layer between the first anode and the first cathode. The second light-emitting device includes a second anode, a second cathode, and a second light-emitting layer between the second anode and the second cathode. The third light-emitting device includes a third anode; a third cathode; and a third light-emitting layer and a fourth light-emitting layer between the third anode and the third cathode. The fourth light-emitting layer is between the third light-emitting layer and the third cathode and is in contact with the third light-emitting layer. A color of light emitted from the first light-emitting device, a color of light emitted from the second light-emitting device, and a color of light emitted from the third light-emitting device are different from each other. The first light-emitting layer and the third light-emitting layer include a first light-emitting substance. The second light-emitting layer and the fourth light-emitting layer include a second light-emitting substance. A peak wavelength of an emission spectrum of the first light-emitting substance and a peak wavelength of an emission spectrum of the second light-emitting substance are different from each other.

Another embodiment of the present invention is a display device including first to third light-emitting devices. The first light-emitting device includes a first anode, a first cathode, and a first light-emitting layer between the first anode and the first cathode. The second light-emitting device includes a second anode, a second cathode, and a second light-emitting layer between the second anode and the second cathode. The third light-emitting device includes a third anode; a third cathode; and a third light-emitting layer and a fourth light-emitting layer between the third anode and the third cathode. The fourth light-emitting layer is between the third light-emitting layer and the third cathode and is in contact with the third light-emitting layer. The first light-emitting layer and the third light-emitting layer include a first light-emitting substance. The second light-emitting layer and the fourth light-emitting layer include a second light-emitting substance. The first light-emitting device does not include the second light-emitting substance. The second light-emitting device does not include the first light-emitting substance. A peak wavelength of an emission spectrum of the first light-emitting substance and a peak wavelength of an emission spectrum of the second light-emitting substance are different from each other.

In the display device with any of the above structures, it is preferable that the peak wavelength of the emission spectrum of the first light-emitting substance be longer than the peak wavelength of the emission spectrum of the second light-emitting substance, and a thickness of the third light-emitting layer be smaller than a thickness of the fourth light-emitting layer.

In the display device with any of the above structures, it is preferable that the peak wavelength of the emission spectrum of the first light-emitting substance be longer than the peak wavelength of the emission spectrum of the second light-emitting substance, and the first light-emitting layer and the third light-emitting layer include a hole-transport material. The first light-emitting layer preferably has a higher hole-transport property than the second light-emitting layer. The third light-emitting layer preferably has a higher hole-transport property than the fourth light-emitting layer. It is further preferable that the first light-emitting device include a hole-blocking layer between the first light-emitting layer and the first cathode.

Another embodiment of the present invention is the display device with any of the above structures further including a fourth light-emitting device. The fourth light-emitting device includes a fourth anode, a fourth cathode, and a fifth light-emitting layer between the fourth anode and the fourth cathode. The third light-emitting device includes a sixth light-emitting layer between the third anode and the third cathode. The sixth light-emitting layer is between the fourth light-emitting layer and the third cathode and is in contact with the fourth light-emitting layer. The fifth light-emitting layer and the sixth light-emitting layer include a third light-emitting substance. A peak wavelength of an emission spectrum of the third light-emitting substance is different from the peak wavelength of the emission spectrum of the first light-emitting substance and the peak wavelength of the emission spectrum of the second light-emitting substance.

Another embodiment of the present invention is a display device including first to third light-emitting devices. The first light-emitting device includes a first anode; a first cathode; and a first light-emitting layer and a first hole-blocking layer between the first anode and the first cathode. The first hole-blocking layer is between the first light-emitting layer and the first cathode. The second light-emitting device includes a second anode, a second cathode, and a second light-emitting layer between the second anode and the second cathode. The third light-emitting device includes a third anode; a third cathode; and a third light-emitting layer and a fourth light-emitting layer between the third anode and the third cathode. The fourth light-emitting layer is between the third light-emitting layer and the third cathode. A color of light emitted from the first light-emitting device, a color of light emitted from the second light-emitting device, and a color of light emitted from the third light-emitting device are different from each other. The first light-emitting layer and the third light-emitting layer include a first light-emitting substance and a hole-transport material. The second light-emitting layer and the fourth light-emitting layer include a second light-emitting substance. A peak wavelength of an emission spectrum of the first light-emitting substance and a peak wavelength of an emission spectrum of the second light-emitting substance are different from each other.

In the display device with any of the above structures, the third light-emitting device may include a second hole-blocking layer between the third light-emitting layer and the fourth light-emitting layer. In the display device with any of the above structures, the first light-emitting layer preferably has a higher hole-transport property than the second light-emitting layer. The third light-emitting layer preferably has a higher hole-transport property than the fourth light-emitting layer.

Another embodiment of the present invention is a display device including first to third light-emitting devices. The first light-emitting device includes a first anode; a first cathode; and a first light-emitting layer, a second light-emitting layer, and a first intermediate layer between the first anode and the first cathode. The first intermediate layer is between the first light-emitting layer and the second light-emitting layer. The second light-emitting device includes a second anode; a second cathode; and a third light-emitting layer, a fourth light-emitting layer, and a second intermediate layer between the second anode and the second cathode. The second intermediate layer is between the third light-emitting layer and the fourth light-emitting layer. The third light-emitting device includes a third anode; a third cathode; and a fifth light-emitting layer, a sixth light-emitting layer, and a third intermediate layer between the third anode and the third cathode. The third intermediate layer is between the fifth light-emitting layer and the sixth light-emitting layer. A color of light emitted from the first light-emitting device, a color of light emitted from the second light-emitting device, and a color of light emitted from the third light-emitting device are different from each other. The first light-emitting layer, the second light-emitting layer, and the fifth light-emitting layer include a first light-emitting substance. The third light-emitting layer, the fourth light-emitting layer, and the sixth light-emitting layer include a second light-emitting substance. A peak wavelength of an emission spectrum of the first light-emitting substance and a peak wavelength of an emission spectrum of the second light-emitting substance are different from each other.

Another embodiment of the present invention is a display device including first to third light-emitting devices. The first light-emitting device includes a first anode; a first cathode; and a first light-emitting layer, a second light-emitting layer, and a first intermediate layer between the first anode and the first cathode. The first intermediate layer is between the first light-emitting layer and the second light-emitting layer. The second light-emitting device includes a second anode; a second cathode; and a third light-emitting layer, a fourth light-emitting layer, and a second intermediate layer between the second anode and the second cathode. The second intermediate layer is between the third light-emitting layer and the fourth light-emitting layer. The third light-emitting device includes a third anode; a third cathode; and a fifth light-emitting layer, a sixth light-emitting layer, and a third intermediate layer between the third anode and the third cathode. The third intermediate layer is between the fifth light-emitting layer and the sixth light-emitting layer. The first light-emitting layer, the second light-emitting layer, and the fifth light-emitting layer include a first light-emitting substance. The third light-emitting layer, the fourth light-emitting layer, and the sixth light-emitting layer include a second light-emitting substance. The first light-emitting device does not include the second light-emitting substance. The second light-emitting device does not include the first light-emitting substance. A peak wavelength of an emission spectrum of the first light-emitting substance and a peak wavelength of an emission spectrum of the second light-emitting substance are different from each other.

In the display device with the above structure, it is preferable that the first intermediate layer, the second intermediate layer, and the third intermediate layer each include an organic compound and an alkali metal or an alkaline earth metal.

In the display device with the above structure, it is preferable that the first intermediate layer, the second intermediate layer, and the third intermediate layer include the same organic compound and the same alkali metal or the same alkaline earth metal.

Another embodiment of the present invention is the display device with the above structure further including a fourth light-emitting device. The fourth light-emitting device includes a fourth anode; a fourth cathode; and a seventh light-emitting layer, an eighth light-emitting layer, and a fourth intermediate layer between the fourth anode and the fourth cathode. The fourth intermediate layer is between the seventh light-emitting layer and the eighth light-emitting layer. The third light-emitting device includes a ninth light-emitting layer between the third anode and the third cathode. The ninth light-emitting layer is in contact with the sixth light-emitting layer. The seventh light-emitting layer, the eighth light-emitting layer, and the ninth light-emitting layer include a third light-emitting substance. A peak wavelength of an emission spectrum of the third light-emitting substance is different from the peak wavelength of the emission spectrum of the first light-emitting substance and the peak wavelength of the emission spectrum of the second light-emitting substance.

In the display device with the above structure, it is preferable that the first intermediate layer, the second intermediate layer, the third intermediate layer, and the fourth intermediate layer each include an organic compound and an alkali metal or an alkaline earth metal.

In the display device with the above structure, it is preferable that the first intermediate layer, the second intermediate layer, the third intermediate layer, and the fourth intermediate layer include the same organic compound and the same alkali metal or the same alkaline earth metal.

According to one embodiment of the present invention, a display device in which a subpixel of the fourth color is formed without adding a step, a mask, a material, a circuit structure, or the like can be provided. According to one embodiment of the present invention, a display device with reduced manufacturing cost can be provided. According to one embodiment of the present invention, an inexpensive display device can be provided. According to one embodiment of the present invention, a novel display device can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

In the accompanying drawings:

FIG. 1A is a top view illustrating a structure of a display device of an embodiment and

FIG. 1B is a cross-sectional view illustrating the structure of the display device of the embodiment;

FIGS. 2A and 2B are cross-sectional views illustrating structures of a display device of an embodiment;

FIGS. 3A and 3B are cross-sectional views illustrating structures of a display device of an embodiment;

FIGS. 4A and 4B are cross-sectional views illustrating structures of a display device of an embodiment;

FIGS. 5A and 5B are cross-sectional views illustrating structures of a display device of an embodiment;

FIG. 6 is a cross-sectional view illustrating a structure of a display device of an embodiment;

FIG. 7 is a cross-sectional view illustrating a structure of a display device of an embodiment;

FIGS. 8A to 8C are cross-sectional views illustrating structures of a display device of an embodiment;

FIG. 9A is a top view illustrating a structure of a display device of an embodiment and FIG. 9B is a cross-sectional view illustrating the structure of the display device of the embodiment;

FIGS. 10A to 10D are cross-sectional views illustrating an example of a method for manufacturing a display device;

FIGS. 11A to 11D are cross-sectional views illustrating an example of a method for manufacturing a display device;

FIGS. 12A and 12B are cross-sectional views illustrating an example of a method for manufacturing a display device;

FIGS. 13A to 13F each illustrate a light-emitting device;

FIGS. 14A and 14B are perspective views illustrating an example of a display device;

FIG. 15 is a cross-sectional view illustrating an example of a display device;

FIGS. 16A to 16D illustrate examples of electronic devices;

FIGS. 17A to 17F illustrate examples of electronic devices; and

FIGS. 18A to 18G illustrate examples of electronic devices.

### DETAILED DESCRIPTION OF THE INVENTION

Embodiments of the present invention will be described in detail below with reference to the drawings. Note that the present invention is not limited to the following description, and the modes and details of the present invention can be modified in various ways without departing from the spirit and scope of the present invention. Therefore, the present invention should not be construed as being limited to the description in the following embodiments.

Note that the position, size, range, or the like of each component illustrated in drawings and the like is not accurately represented in some cases for easy understanding. Therefore, the disclosed invention is not necessarily limited to the position, size, range, or the like disclosed in the drawings and the like.

Ordinal numbers such as “first” and “second” in this specification and the like are used for convenience and do not denote the order of steps or the stacking order of layers in some cases. Therefore, for example, description can be made even when “first” is replaced with “second” or “third”, as appropriate. In addition, the ordinal numbers in this specification and the like are not necessarily the same as those used to specify one embodiment of the present invention.

In the description of structures of the present invention in this specification and the like with reference to the drawings, the same components in different drawings are denoted by the same reference numeral in some cases.

In this specification and the like, the terms “film” and “layer” can be interchanged with each other. For example, the term “conductive layer” can be changed into the term “conductive film” in some cases. For another example, the term “insulating film” can be changed into the term “insulating layer” in some cases.

### Embodiment 1

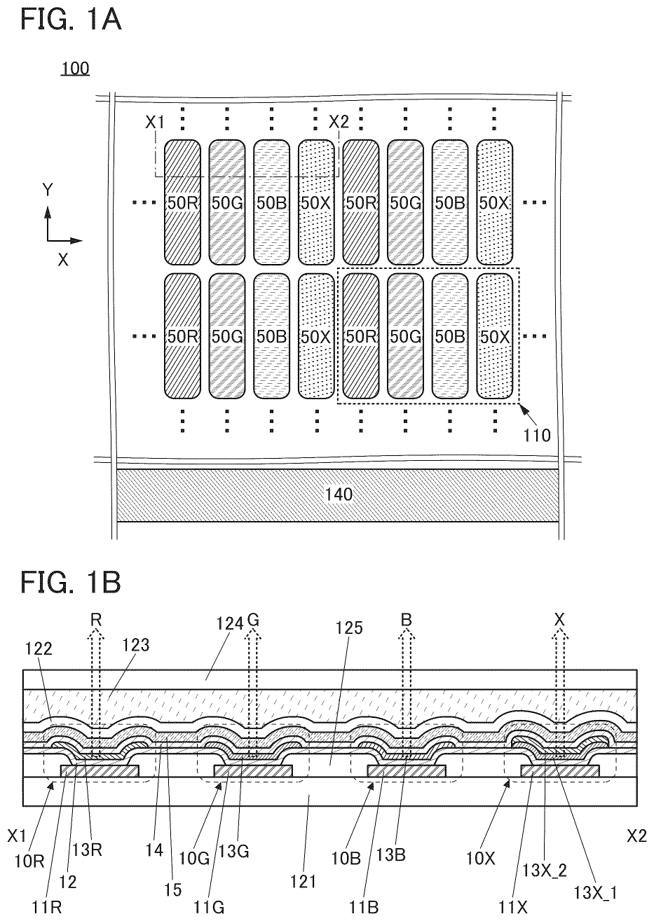

In this embodiment, display devices of embodiments of the present invention will be described with reference to FIGS. 1A and 1B, FIGS. 2A and 2B, FIGS. 3A and 3B, FIGS. 4A and 4B, FIGS. 5A and 5B, FIG. 6, FIG. 7, FIGS. 8A to 8C, and FIGS. 9A and 9B.

FIG. 1A is a top view of a display device 100 of one embodiment of the present invention. The display device 100 includes a display portion in which a plurality of pixels 110 are arranged, and a connection portion 140 outside the display portion. A plurality of subpixels are arranged in a matrix in the display portion. FIG. 1A illustrates subpixels arranged in two rows and eight columns, which form the pixels 110 in two rows and two columns. The connection portion 140 can also be referred to as a cathode contact portion.

The top surface shape of the subpixel illustrated in FIG. 1A corresponds to the top surface shape of a light-emitting region. In this specification and the like, a top surface shape refers to a shape in a plan view, i.e., a shape seen from above. Examples of the top surface shape of the subpixel include polygons such as a triangle, a tetragon (including a rectangle, a rhombus, and a square), and a pentagon; polygons with rounded corners; an ellipse; and a circle.

The range of the circuit layout for forming the subpixels is not limited to the range of the subpixels illustrated in FIG. 1A, and the components of the circuit may be located outside the range of the subpixels. For example, some or all of the transistors of a subpixel 50R illustrated in FIG. 1A may be located outside the range of the subpixel 50R. The transistors of the subpixel 50R may be located within the range of the subpixel 50R, the range of a subpixel 50G, the range of a subpixel 50B, or the range of a subpixel 50X illustrated in FIG. 1A, or may be located in two or more of these ranges.

Although the subpixels 50R, 50G, 50B, and 50X have the same or substantially the same aperture ratio (also referred to as size or size of a light-emitting region) in FIG. 1A, one embodiment of the present invention is not limited thereto. The aperture ratio of each of the subpixels 50R, 50G, 50B, and 50X can be determined as appropriate. The subpixels 50R, 50G, 50B, and 50X may have different aperture ratios, or two or more of the subpixels 50R, 50G, 50B, and 50X may have the same or substantially the same aperture ratio.

The pixel 110 illustrated in FIG. 1A employs stripe arrangement. The pixel 110 illustrated in FIG. 1A includes four subpixels of the subpixels 50R, 50G, 50B, and 50X. The subpixels 50R, 50G, 50B, and 50X emit light of different colors. Examples of the subpixels 50R, 50G, and 50B include red (R), green (G), and blue (B) subpixels. Examples of the subpixel 50X include yellow (Y), cyan (C), magenta (M), and white (W) subpixels.

In this specification and the like, the row direction, the column direction, and the depth direction are sometimes referred to as the X direction, the Y direction, and the Z direction, respectively. FIG. 1A illustrates an example where subpixels of different colors are arranged in the X direction and subpixels of the same color are arranged in the Y direction.

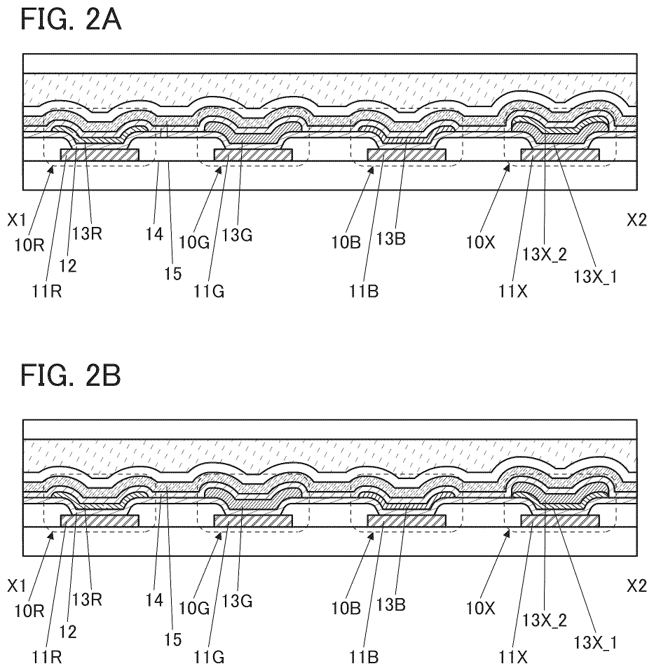

FIG. 1B is a cross-sectional view along the dashed-dotted line X1-X2 in FIG. 1A. FIGS. 2A and 2B, FIGS. 3A and 3B, FIGS. 4A and 4B, FIGS. 5A and 5B, FIG. 6, FIG. 7, FIGS. 8A to 8C, and FIGS. 9A and 9B illustrate variation examples of the cross-sectional view along the dashed-dotted line X1-X2 in FIG. 1A.

In the display device 100, a light-emitting device 10R, a light-emitting device 10G, a light-emitting device 10B, and a light-emitting device 10X are provided over a layer 121 including transistors (not illustrated), and a protective layer 122 is provided to cover these light-emitting devices. A substrate 124 is attached above these components with a resin layer 123. An insulating layer 125 is provided in a region between adjacent light-emitting devices.

The display device of one embodiment of the present invention preferably has a top-emission structure in which light is emitted in a direction opposite to the substrate where the light-emitting devices are formed.

The layer 121 can have a stacked-layer structure in which a plurality of transistors (not illustrated) are provided over a substrate and an insulating layer is provided to cover these transistors, for example. The layer 121 may have a recess portion between adjacent light-emitting devices. For example, an insulating layer being the outermost surface of the layer 121 may have a recess portion. Structure examples of the layer 121 will be described later in Embodiment 4.

Light emitted from the light-emitting device 10R, light emitted from the light-emitting device 10G, light emitted from the light-emitting device 10B, and light emitted from the light-emitting device 10X have different colors. For example, it is preferable that the light-emitting device 10R emit red (R) light, the light-emitting device 10G emit green (G) light, and the light-emitting device 10B emit blue (B) light. The light-emitting device 10X preferably emits yellow (Y), cyan (C), magenta (M), or white (W) light.

As illustrated in FIG. 1B, the light-emitting devices 10R, 10G, 10B, and 10X are provided in the display device 100 in the following manner: an anode 11R, an anode 11G, an anode 11B, and an anode 11X are provided over the layer 121; a hole-injection/transport layer 12 is provided over the anode 11R, the anode 11G, the anode 11B, and the anode 11X; a light-emitting layer 13R, a light-emitting layer 13G, a light-emitting layer 13B, and a light-emitting layer 13X_1 are provided over the hole-injection/transport layer 12; a light-emitting layer 13X_2 is provided over the light-emitting layer 13X_1; an electron-injection/transport layer 14 is provided over the light-emitting layer 13R, the light-emitting layer 13G, the light-emitting layer 13B, and the light-emitting layer 13X_2; and a cathode 15 is formed over the electron-injection/transport layer 14. Note that the hole-injection/transport layer 12 preferably has a stacked-layer structure; for example, the hole-injection/transport layer 12 preferably has a stacked-layer structure in which a hole-injection layer and a hole-transport layer are stacked in this order from the anode side. The electron-injection/transport layer 14 preferably has a stacked-layer structure; for example, the electron-injection/transport layer 14 preferably has a stacked-layer structure in which an electron-transport layer and an electron-injection layer are stacked in this order from the light-emitting layer side.

The hole-injection/transport layer 12, the electron-injection/transport layer 14, and the cathode 15 are preferably layers shared by the light-emitting devices (hereinafter, such layers are sometimes referred to as common layers). The light-emitting layers 13R, 13G, 13B, 13X_1, and 13X_2 are preferably formed in the respective light-emitting devices by a vacuum evaporation method using a metal mask.

The light-emitting device 10R includes the hole-injection/transport layer 12, the light-emitting layer 13R, and the electron-injection/transport layer 14 between the anode 11R and the cathode 15. The light-emitting layer 13R is located between the hole-injection/transport layer 12 and the electron-injection/transport layer 14. The light-emitting layer 13R includes at least a light-emitting substance R. As the light-emitting substance R, a light-emitting substance that emits red light can be used.

The light-emitting device 10G includes the hole-injection/transport layer 12, the light-emitting layer 13G, and the electron-injection/transport layer 14 between the anode 11G and the cathode 15. The light-emitting layer 13G is located between the hole-injection/transport layer 12 and the electron-injection/transport layer 14. The light-emitting layer 13G includes at least a light-emitting substance G. As the light-emitting substance G, a light-emitting substance that emits green light can be used.

The light-emitting device 10B includes the hole-injection/transport layer 12, the light-emitting layer 13B, and the electron-injection/transport layer 14 between the anode 11B and the cathode 15. The light-emitting layer 13B is located between the hole-injection/transport layer 12 and the electron-injection/transport layer 14. The light-emitting layer 13B includes at least a light-emitting substance B. As the light-emitting substance B, a light-emitting substance that emits blue light can be used.

In this specification and the like, the blue wavelength range ranges from 400 nm to less than 490 nm, and blue light emission has at least one emission spectrum peak in this range. The green wavelength range ranges from 490 nm to less than 580 nm, and green light emission has at least one emission spectrum peak in this range. The red wavelength range ranges from 580 nm to 750 nm, and red light emission has at least one emission spectrum peak in this range.

The light-emitting device 10X includes, between the anode 11X and the cathode 15, the hole-injection/transport layer 12, a light-emitting layer (also referred to as a stacked light-emitting layer) with a structure in which a plurality of light-emitting layers having different emission colors are stacked to be in contact with each other, and the electron-injection/transport layer 14. Here, the number of light-emitting layers that are stacked to form the stacked light-emitting layer of the light-emitting device 10X is preferably two or three. By including a stack of light-emitting layers having different emission colors, the light-emitting device 10X can emit light whose color is different from the emission colors of the light-emitting layers.

In the example illustrated in FIG. 1B, the light-emitting device 10X includes a stacked light-emitting layer composed of two light-emitting layers (13X_1 and 13X_2). The light-emitting layer 13X_1 and the light-emitting layer 13X_2 are located between the hole-injection/transport layer 12 and the electron-injection/transport layer 14. The light-emitting layer 13X_2 is located between the light-emitting layer 13X_1 and the cathode 15 and is in contact with the light-emitting layer 13X_1. In other words, the light-emitting layer 13X_2 is in contact with the surface included in the light-emitting layer 13X_1 and facing the cathode 15.

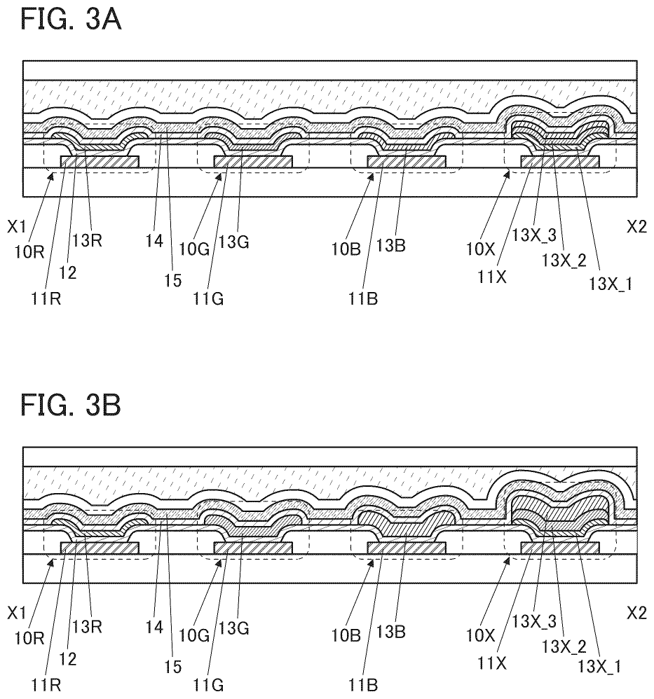

In the example illustrated in FIG. 3A, the light-emitting device 10X includes a stacked light-emitting layer composed of three light-emitting layers (13X_1, 13X_2, and 13X_3). The light-emitting layer 13X_1, the light-emitting layer 13X_2, and the light-emitting layer 13X_3 are located between the hole-injection/transport layer 12 and the electron-injection/transport layer 14. The light-emitting layer 13X_2 is located between the light-emitting layer 13X_1 and the cathode 15 and is in contact with the light-emitting layer 13X_1. The light-emitting layer 13X_3 is located between the light-emitting layer 13X_2 and the cathode 15 and is in contact with the light-emitting layer 13X_2. In other words, the light-emitting layer 13X_2 is in contact with the surface included in the light-emitting layer 13X_1 and facing the cathode 15, and the light-emitting layer 13X_3 is in contact with the surface included in the light-emitting layer 13X_2 and facing the cathode 15.

Each of the light-emitting layers included in the light-emitting device 10X is formed in the same process as any of the light-emitting layer 13R, the light-emitting layer 13G, and the light-emitting layer 13B by a vacuum evaporation method using a metal mask. Employing such a structure enables the light-emitting device 10X to be fabricated without adding steps or materials for providing the light-emitting device 10X in the display device 100, which can reduce the cost of the display device 100.

In this specification, the description “a light-emitting layer is formed in the same process as a light-emitting layer A by a vacuum evaporation method using a metal mask” means that the light-emitting layer includes the same light-emitting substance as the light-emitting layer A. The description also means that the light-emitting layer includes the same material as the light-emitting layer A and is composed of the same material as the light-emitting layer A. The description also means that the thickness of the light-emitting layer is similar to that of the light-emitting layer A. Note that in this specification, the term “similar” may include a difference slight enough to allow fluctuations in composition and thickness accuracy of a film formation apparatus. In this specification, the phrase “in the same process” can be replaced with the phrase “at the same time”.

Hereinafter, for simplicity, a layer formed in the same process as the light-emitting layer 13R by a vacuum evaporation method using a metal mask is sometimes referred to as a layer including the light-emitting substance R. A layer formed in the same process as the light-emitting layer 13G by a vacuum evaporation method using a metal mask is sometimes referred to as a layer including the light-emitting substance G. A layer formed in the same process as the light-emitting layer 13B by a vacuum evaporation method using a metal mask is sometimes referred to as a layer including the light-emitting substance B.

The light-emitting device 10X can emit yellow (Y) light when the light-emitting device 10X includes a stacked light-emitting layer composed of two light-emitting layers (13X_1 and 13X_2) as illustrated in FIG. 1B, one of the two light-emitting layers is the layer including the light-emitting substance R, and the other is the layer including the light-emitting substance G. Hereinafter, the light-emitting device 10X that includes this combination of light-emitting layers is sometimes referred to as the yellow (Y)-light-emitting device 10X.

The light-emitting device 10X can emit magenta (M) light when the light-emitting device 10X includes a stacked light-emitting layer composed of two light-emitting layers (13X_1 and 13X_2) as illustrated in FIG. 1B, one of the two light-emitting layers is the layer including the light-emitting substance R, and the other is the layer including the light-emitting substance B. Hereinafter, the light-emitting device 10X that includes this combination of light-emitting layers is sometimes referred to as the magenta (M)-light-emitting device 10X.

The light-emitting device 10X can emit cyan (C) light when the light-emitting device 10X includes a stacked light-emitting layer composed of two light-emitting layers (13X_1 and 13X_2) as illustrated in FIG. 1B, one of the two light-emitting layers is the layer including the light-emitting substance G, and the other is the layer including the light-emitting substance B. Hereinafter, the light-emitting device 10X that includes this combination of light-emitting layers is sometimes referred to as the cyan (C)-light-emitting device 10X.

The light-emitting device 10X can emit white (W) light when the light-emitting device 10X includes a stacked light-emitting layer composed of three light-emitting layers (13X_1, 13X_2, and 13X_3) as illustrated in FIG. 3A and the three light-emitting layers are the layer including the light-emitting substance R, the layer including the light-emitting substance G, and the layer including the light-emitting substance B. Hereinafter, the light-emitting device 10X that includes this combination of light-emitting layers is sometimes referred to as the white (W)-light-emitting device 10X.

In a light-emitting device in which two light-emitting layers (a light-emitting layer L and a light-emitting layer S) having different emission colors are directly stacked, the emission intensity of the light-emitting layer L emitting light with a long wavelength is sometimes higher than the emission intensity of the light-emitting layer S emitting light with a short wavelength (here, a peak wavelength of an emission spectrum of a light-emitting substance x included in the light-emitting layer L is longer than a peak wavelength of an emission spectrum of a light-emitting substance y included in the light-emitting layer S). This is partly because recombination energy is easily transferred to the light-emitting substance x, which has lower excitation energy and is more easily excited than the light-emitting substance y, in the case where the recombination center of the light-emitting device is in the vicinity of the interface between the light-emitting layer L and the light-emitting layer S, for example.

In view of the above, one embodiment of the present invention is a light-emitting device which includes a stacked light-emitting layer formed by directly stacking two light-emitting layers (the light-emitting layer L and the light-emitting layer S) having different emission colors and in which the recombination center of carriers (holes and electrons) is shifted from the interface between the light-emitting layer L and the light-emitting layer S to the light-emitting layer S.

In the case where the light-emitting device 10X includes a stacked light-emitting layer composed of two light-emitting layers (13X_1 and 13X_2) and, for example, the light-emitting layer 13X_1 and the light-emitting layer 13X_2 are respectively the light-emitting layer L emitting light with a long wavelength and the light-emitting layer S emitting light with a short wavelength, the thickness of the light-emitting layer L, to which recombination energy is easily transferred, is preferably set to be smaller than the thickness of the light-emitting layer S to shift the recombination center to the light-emitting layer S.

Specifically, in the case of the yellow (Y)-light-emitting device 10X, among the light-emitting layer 13X_1 and the light-emitting layer 13X_2, the layer including the light-emitting substance R preferably has a smaller thickness than the layer including the light-emitting substance G. For example, in the case where the light-emitting layer 13X_1 is the layer including the light-emitting substance R and the light-emitting layer 13X_2 is the layer including the light-emitting substance G, the thickness of the light-emitting layer 13X_1 is preferably smaller than that of the light-emitting layer 13X_2. In the case of the magenta (M)-light-emitting device 10X, among the light-emitting layer 13X_1 and the light-emitting layer 13X_2, the layer including the light-emitting substance R preferably has a smaller thickness than the layer including the light-emitting substance B. For example, in the case where the light-emitting layer 13X_1 is the layer including the light-emitting substance R and the light-emitting layer 13X_2 is the layer including the light-emitting substance B, the thickness of the light-emitting layer 13X_1 is preferably smaller than that of the light-emitting layer 13X_2. In the case of the cyan (C)-light-emitting device 10X, among the light-emitting layer 13X_1 and the light-emitting layer 13X_2, the layer including the light-emitting substance G preferably has a smaller thickness than the layer including the light-emitting substance B. For example, in the case where the light-emitting layer 13X_1 is the layer including the light-emitting substance G and the light-emitting layer 13X_2 is the layer including the light-emitting substance B, the thickness of the light-emitting layer 13X_1 is preferably smaller than that of the light-emitting layer 13X_2. With any of these structures, the recombination center can be shifted to the light-emitting layer S; thus, the emission intensity of the light-emitting layer S is increased, and as a result, favorable light emission can be obtained from both the light-emitting layer 13X_1 and the light-emitting layer 13X_2, leading to higher emission efficiency of the light-emitting device 10X.

FIGS. 2A and 2B illustrate specific examples of a structure in which the light-emitting layer 13X_1 and the light-emitting layer 13X_2 have different thicknesses. Here, example cases where the light-emitting device 10X is a yellow (Y)-light-emitting device are described.

In FIG. 2A, the light-emitting layer 13X_1 is a shorter-wavelength-light-emitting layer and is the layer including the light-emitting substance G. The light-emitting layer 13X_2 is a longer-wavelength-light-emitting layer and is the layer including the light-emitting substance R. In this case, the thickness of the light-emitting layer 13X_2 is preferably smaller than that of the light-emitting layer 13X_1 as illustrated in FIG. 2A. Here, as described above, the layer including the light-emitting substance G refers to a layer formed in the same process as the light-emitting layer 13G by a vacuum evaporation method using a metal mask, and the layer including the light-emitting substance R refers to a layer formed in the same process as the light-emitting layer 13R by a vacuum evaporation method using a metal mask. Thus, in this case, the light-emitting layer 13R can be regarded as having a smaller thickness than the light-emitting layer 13G.

In FIG. 2B, the light-emitting layer 13X_1 is the longer-wavelength-light-emitting layer and is the layer including the light-emitting substance R. The light-emitting layer 13X_2 is the shorter-wavelength-light-emitting layer and is the layer including the light-emitting substance G. In this case, the thickness of the light-emitting layer 13X_1 is preferably smaller than that of the light-emitting layer 13X_2 as illustrated in FIG. 2B. In this case, the light-emitting layer 13R can be regarded as having a smaller thickness than the light-emitting layer 13G.

In the case where the light-emitting device 10X includes a stacked light-emitting layer composed of three light-emitting layers (13X_1, 13X_2, and 13X_3) emitting light of the respective three colors, the following relationship is preferably satisfied between the light-emitting layers: the thickness of the layer including the light-emitting substance R<that of the layer including the light-emitting substance G<that of the layer including the light-emitting substance B. This structure makes it possible that, at each of the interfaces between the stacked layers, the recombination center can be shifted from the interface to the shorter-wavelength-light-emitting layer; thus, the emission intensity of the shorter-wavelength-light-emitting layers can be increased, and favorable light emission can be obtained from the light-emitting layer 13X_1, the light-emitting layer 13X_2, and the light-emitting layer 13X_3.

FIG. 3B illustrates a specific structure. In FIG. 3B, the light-emitting layer 13X_1 is the layer including the light-emitting substance R. The light-emitting layer 13X_2 is the layer including the light-emitting substance G. The light-emitting layer 13X_3 is the layer including the light-emitting substance B. In this case, it is preferable that the thickness of the light-emitting layer 13X_2 be larger than that of the light-emitting layer 13X_1, and the thickness of the light-emitting layer 13X_3 be larger than that of the light-emitting layer 13X_2, as illustrated in FIG. 3B. Here, as described above, the layer including the light-emitting substance G refers to a layer formed in the same process as the light-emitting layer 13G by a vacuum evaporation method using a metal mask, the layer including the light-emitting substance R refers to a layer formed in the same process as the light-emitting layer 13R by a vacuum evaporation method using a metal mask, and the layer including the light-emitting substance B refers to a layer formed in the same process as the light-emitting layer 13B by a vacuum evaporation method using a metal mask. Thus, in this case, the light-emitting layer 13G can be regarded as having a larger thickness than the light-emitting layer 13R, and the light-emitting layer 13B can be regarded as having a larger thickness than the light-emitting layer 13G.

That is, the light-emitting device 10X that includes a stacked light-emitting layer formed by directly stacking a plurality of light-emitting layers having different emission colors can also have increased emission efficiency when the longer-wavelength-light-emitting layer among the light-emitting layers, which are stacked to have an interface therebetween, has a smaller thickness to shift the recombination center at the interface between the stacked layers to the shorter-wavelength-light-emitting layer.

Another embodiment of the present invention is a light-emitting device which includes, between a reflective electrode and a transmissive electrode, a stacked light-emitting layer formed by directly stacking two light-emitting layers (the light-emitting layer L and the light-emitting layer S) having different emission colors and in which the light-emitting layer S and the light-emitting layer L are stacked in this order in the light emission direction (i.e., the light-emitting layer S and the light-emitting layer L are stacked in an ascending order of the distance to the reflective electrode). In such a structure, the distance between the light-emitting layer S and the reflective electrode is short and the distance between the light-emitting layer L and the reflective electrode is long, which facilitates optical adjustment. In particular, such a structure is preferably used for a light-emitting device having a microcavity structure to facilitate optical adjustment. Details of a microcavity structure will be described in Embodiment 3.

Thus, in the light-emitting device 10X illustrated in FIG. 1B, it is preferable that the anode 11X be a reflective electrode, the cathode 15 be a transmissive electrode, and the combination of the two light-emitting layers be such that the light-emitting layer 13X_1 is the above-described light-emitting layer S and the light-emitting layer 13X_2 is the above-described light-emitting layer L. Specifically, in the yellow (Y)-light-emitting device 10X, it is preferable that the light-emitting layer 13X_1 be the layer including the light-emitting substance G and the light-emitting layer 13X_2 be the layer including the light-emitting substance R. In the magenta (M)-light-emitting device 10X, it is preferable that the light-emitting layer 13X_1 be the layer including the light-emitting substance B and the light-emitting layer 13X_2 be the layer including the light-emitting substance R. In the cyan (C)-light-emitting device 10X, it is preferable that the light-emitting layer 13X_1 be the layer including the light-emitting substance B and the light-emitting layer 13X_2 be the layer including the light-emitting substance G.

In another embodiment of the present invention, the stacking order of the light-emitting layer L and the light-emitting layer S is changed to change the intensity of light emitted from each light-emitting layer, which enables chromaticity adjustment.

For example, in the light-emitting device 10X illustrated in FIG. 1B, the combination of the two light-emitting layers can be such that the light-emitting layer 13X_1 is the above-described light-emitting layer L and the light-emitting layer 13X_2 is the above-described light-emitting layer S. Specifically, in the yellow (Y)-light-emitting device 10X, the light-emitting layer 13X_1 can be the layer including the light-emitting substance R and the light-emitting layer 13X_2 can be the layer including the light-emitting substance G. In the magenta (M)-light-emitting device 10X, the light-emitting layer 13X_1 can be the layer including the light-emitting substance R and the light-emitting layer 13X_2 can be the layer including the light-emitting substance B. In the cyan (C)-light-emitting device 10X, the light-emitting layer 13X_1 can be the layer including the light-emitting substance G and the light-emitting layer 13X_2 can be the layer including the light-emitting substance B.

In the white (W)-light-emitting device 10X illustrated in FIG. 3A, among the light-emitting layers that emit light of the respective three colors, the light-emitting layer 13X_1 can be the layer including the light-emitting substance R, the light-emitting layer 13X_2 can be the layer including the light-emitting substance G, and the light-emitting layer 13X_3 can be the layer including the light-emitting substance B.

Another embodiment of the present invention is a light-emitting device which includes a stacked light-emitting layer formed by directly stacking two light-emitting layers (the light-emitting layer L and the light-emitting layer S) having different emission colors and in which the light-emitting layer L has an enhanced carrier-transport property to shift the recombination center from the interface between the light-emitting layer L and the light-emitting layer S to the light-emitting layer S. The light-emitting device 10X that includes a stacked light-emitting layer formed by directly stacking a plurality of light-emitting layers having different emission colors can have increased emission efficiency when the longer-wavelength-light-emitting layer among the light-emitting layers, which are stacked to have an interface therebetween, has an enhanced carrier-transport property to shift the recombination center at the interface between the stacked layers to the shorter-wavelength-light-emitting layer.

In the case of enhancing the carrier-transport property of a light-emitting layer closer to the anode among the layers of the stacked light-emitting layer, the hole-transport property of the light-emitting layer is preferably enhanced. That is, the light-emitting layer preferably includes a hole-transport material, and further preferably has a higher hole-transport property than a light-emitting layer closer to the cathode. In the case of enhancing the carrier-transport property of the light-emitting layer closer to the cathode among the light-emitting layers, the electron-transport property of the light-emitting layer is preferably enhanced. That is, the light-emitting layer preferably includes an electron-transport material, and further preferably has a higher electron-transport property than the light-emitting layer closer to the anode. Structure examples of the hole-transport material and the electron-transport material will be described later in Embodiment 3.

Thus, in the light-emitting device 10X including two light-emitting layers of the light-emitting layer 13X_1 and the light-emitting layer 13X_2, it is preferable to enhance the carrier-transport property of one of the two light-emitting layers that emits light with a longer wavelength. For example, in the case where the wavelength of the light emitted from the light-emitting layer 13X_1 is longer than that of the light emitted from the light-emitting layer 13X_2, it is preferable to enhance the hole-transport property of the light-emitting layer 13X_1. Specifically, the light-emitting layer 13X_1 preferably includes a hole-transport material or has a higher hole-transport property than the light-emitting layer 13X_2. Alternatively, in the case where the wavelength of the light emitted from the light-emitting layer 13X_2 is longer than that of the light emitted from the light-emitting layer 13X_1, it is preferable to enhance the electron-transport property of the light-emitting layer 13X_2. Specifically, the light-emitting layer 13X_2 preferably includes an electron-transport material or has a higher electron-transport property than the light-emitting layer 13X_1. Such a structure enables shifting the recombination center from the interface between the light-emitting layer 13X_1 and the light-emitting layer 13X_2 that are stacked to the shorter-wavelength-light-emitting layer, so that the emission intensity of the shorter-wavelength-light-emitting layer can be increased, and favorable light emission can be obtained from both the longer-wavelength-light-emitting layer and the shorter-wavelength-light-emitting layer.

Specifically, in the case of the yellow (Y)-light-emitting device 10X, it is preferable to enhance the carrier-transport property of the layer including the light-emitting substance R among the light-emitting layer 13X_1 and the light-emitting layer 13X_2. For example, in the case where the light-emitting layer 13X_1 is the layer including the light-emitting substance R and the light-emitting layer 13X_2 is the layer including the light-emitting substance G, the light-emitting layer 13X_1 preferably includes a hole-transport material or has a higher hole-transport property than the light-emitting layer 13X_2. In the case where the light-emitting layer 13X_1 is the layer including the light-emitting substance G and the light-emitting layer 13X_2 is the layer including the light-emitting substance R, the light-emitting layer 13X_2 preferably includes an electron-transport material or has a higher electron-transport property than the light-emitting layer 13X_1.

In the case of the magenta (M)-light-emitting device 10X, it is preferable to enhance the carrier-transport property of the layer including the light-emitting substance R among the light-emitting layer 13X_1 and the light-emitting layer 13X_2. For example, in the case where the light-emitting layer 13X_1 is the layer including the light-emitting substance R and the light-emitting layer 13X_2 is the layer including the light-emitting substance B, the light-emitting layer 13X_1 preferably includes a hole-transport material or has a higher hole-transport property than the light-emitting layer 13X_2. In the case where the light-emitting layer 13X_1 is the layer including the light-emitting substance B and the light-emitting layer 13X_2 is the layer including the light-emitting substance R, the light-emitting layer 13X_2 preferably includes an electron-transport material or has a higher electron-transport property than the light-emitting layer 13X_1.

In the case of the cyan (C)-light-emitting device 10X, it is preferable to enhance the carrier-transport property of the layer including the light-emitting substance G among the light-emitting layer 13X_1 and the light-emitting layer 13X_2. For example, in the case where the light-emitting layer 13X_1 is the layer including the light-emitting substance G and the light-emitting layer 13X_2 is the layer including the light-emitting substance B, the light-emitting layer 13X_1 preferably includes a hole-transport material or has a higher hole-transport property than the light-emitting layer 13X_2. In the case where the light-emitting layer 13X_1 is the layer including the light-emitting substance B and the light-emitting layer 13X_2 is the layer including the light-emitting substance G, the light-emitting layer 13X_2 preferably includes an electron-transport material or has a higher electron-transport property than the light-emitting layer 13X_1.

As described above, the layer including the light-emitting substance R refers to a layer formed in the same process as the light-emitting layer 13R by a vacuum evaporation method using a metal mask. That is, a structure in which the carrier-transport property of the layer including the light-emitting substance R among the light-emitting layer 13X_1 and the light-emitting layer 13X_2 is enhanced means a structure in which the carrier-transport property of the light-emitting layer 13R is also enhanced. In the case where the light-emitting layer 13X_1 is the layer including the light-emitting substance R and includes a hole-transport material, it can be said that the light-emitting layer 13R also includes the hole-transport material. In the case where the light-emitting layer 13X_2 is the layer including the light-emitting substance R and includes an electron-transport material, it can be said that the light-emitting layer 13R also includes the electron-transport material.

As described above, the layer including the light-emitting substance G refers to a layer formed in the same process as the light-emitting layer 13G by a vacuum evaporation method using a metal mask. Accordingly, in the case where the light-emitting layer 13X_1 is the layer including the light-emitting substance R; the light-emitting layer 13X_2 is the layer including the light-emitting substance G; and the light-emitting layer 13X_1 has a higher hole-transport property than the light-emitting layer 13X_2, it can be said that the light-emitting layer 13R has a higher hole-transport property than the light-emitting layer 13G. In the case where the light-emitting layer 13X_2 is the layer including the light-emitting substance R; the light-emitting layer 13X_1 is the layer including the light-emitting substance G; and the light-emitting layer 13X_2 has a higher electron-transport property than the light-emitting layer 13X_1, it can be said that the light-emitting layer 13R has a higher electron-transport property than the light-emitting layer 13G.

As described above, the layer including the light-emitting substance B refers to a layer formed in the same process as the light-emitting layer 13B by a vacuum evaporation method using a metal mask. Accordingly, in the case where the light-emitting layer 13X_1 is the layer including the light-emitting substance R; the light-emitting layer 13X_2 is the layer including the light-emitting substance B; and the light-emitting layer 13X_1 has a higher hole-transport property than the light-emitting layer 13X_2, it can be said that the light-emitting layer 13R has a higher hole-transport property than the light-emitting layer 13B. In the case where the light-emitting layer 13X_2 is the layer including the light-emitting substance R; the light-emitting layer 13X_1 is the layer including the light-emitting substance B; and the light-emitting layer 13X_2 has a higher electron-transport property than the light-emitting layer 13X_1, it can be said that the light-emitting layer 13R has a higher electron-transport property than the light-emitting layer 13B.

In a similar manner, a structure in which the carrier-transport property of the layer including the light-emitting substance G among the light-emitting layer 13X_1 and the light-emitting layer 13X_2 is enhanced means a structure in which the carrier-transport property of the light-emitting layer 13G is also enhanced. In the case where the light-emitting layer 13X_1 is the layer including the light-emitting substance G and includes a hole-transport material, it can be said that the light-emitting layer 13G also includes the hole-transport material. In the case where the light-emitting layer 13X_2 is the layer including the light-emitting substance G and includes an electron-transport material, it can be said that the light-emitting layer 13G also includes the electron-transport material.

In the case where the light-emitting layer 13X_1 is the layer including the light-emitting substance G; the light-emitting layer 13X_2 is the layer including the light-emitting substance B; and the light-emitting layer 13X_1 has a higher hole-transport property than the light-emitting layer 13X_2, it can be said that the light-emitting layer 13G has a higher hole-transport property than the light-emitting layer 13B. In the case where the light-emitting layer 13X_2 is the layer including the light-emitting substance G; the light-emitting layer 13X_1 is the layer including the light-emitting substance B; and the light-emitting layer 13X_2 has a higher electron-transport property than the light-emitting layer 13X_1, it can be said that the light-emitting layer 13G has a higher electron-transport property than the light-emitting layer 13B.

In the case where the light-emitting layer 13R has a high carrier-transport property, the light-emitting device 10R preferably includes a carrier-blocking layer that is in contact with the light-emitting layer 13R in order to control the recombination center in the light-emitting device 10R. In the case where the light-emitting layer 13G has a high carrier-transport property, the light-emitting device 10G preferably includes a carrier-blocking layer that is in contact with the light-emitting layer 13G in order to control the recombination center in the light-emitting device 10G. Examples of the carrier-blocking layer include a hole-blocking layer and an electron-blocking layer.

Specifically, in the case where the light-emitting layer 13R has a high hole-transport property, the light-emitting device 10R preferably includes a hole-blocking layer between the light-emitting layer 13R and the cathode 15, further preferably includes a hole-blocking layer between the light-emitting layer 13R and the electron-injection/transport layer 14, still further preferably includes a hole-blocking layer that is in contact with the surface included in the light-emitting layer 13R and facing the cathode 15. In the case where the light-emitting layer 13R has a high electron-transport property, the light-emitting device 10R preferably includes an electron-blocking layer between the light-emitting layer 13R and the anode 11R, further preferably includes an electron-blocking layer between the light-emitting layer 13R and the hole-injection/transport layer 12, still further preferably includes an electron-blocking layer that is in contact with the surface included in the light-emitting layer 13R and facing the anode 11R. These structures prevent carriers from passing through the light-emitting layer 13R and facilitate carrier recombination in the light-emitting layer 13R, increasing the emission efficiency of the light-emitting device 10R.

In the case where the light-emitting layer 13G has a high hole-transport property, the light-emitting device 10G preferably includes a hole-blocking layer between the light-emitting layer 13G and the cathode 15, further preferably includes a hole-blocking layer between the light-emitting layer 13G and the electron-injection/transport layer 14, still further preferably includes a hole-blocking layer that is in contact with the surface included in the light-emitting layer 13G and facing the cathode 15. In the case where the light-emitting layer 13G has a high electron-transport property, the light-emitting device 10G preferably includes an electron-blocking layer between the light-emitting layer 13G and the anode 11G, further preferably includes an electron-blocking layer between the light-emitting layer 13G and the hole-injection/transport layer 12, still further preferably includes an electron-blocking layer that is in contact with the surface included in the light-emitting layer 13G and facing the anode 11G. These structures prevent carriers from passing through the light-emitting layer 13G and facilitate carrier recombination in the light-emitting layer 13G, increasing the emission efficiency of the light-emitting device 10G.

Note that in the case where the light-emitting layer 13R, the light-emitting layer 13G, and the like are provided with a carrier-blocking layer, the carrier-blocking layer may be a common layer or a layer formed for each device by a vacuum evaporation method using a metal mask.

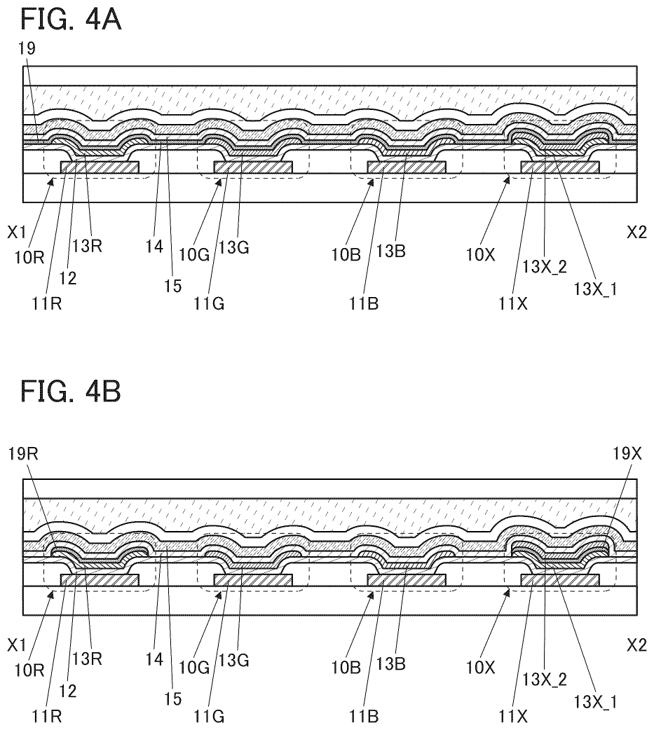

FIG. 4A illustrates an example case where the light-emitting layer 13R includes an organic compound with a high hole-transport property and a hole-blocking layer as a common layer is provided. In FIG. 4A, a hole-blocking layer 19 is shared by the light-emitting devices 10R, 10G, 10B, and 10X and is provided in contact with the surface included in the light-emitting layer 13R and facing the cathode 15, the surface included in the light-emitting layer 13G and facing the cathode 15, the surface included in the light-emitting layer 13B and facing the cathode 15, and the surface included in the light-emitting layer 13X_2 and facing the cathode 15. In the case where a hole-blocking layer as a common layer is provided, another metal mask for forming the hole-blocking layer does not need to be prepared, reducing the manufacturing cost of the display device 100.

FIG. 4B illustrates an example case where the light-emitting layer 13X_1 is the layer including the light-emitting substance R; the light-emitting layer 13X_2 is the layer including the light-emitting substance G; the light-emitting layer 13R includes an organic compound with a high hole-transport property; and a hole-blocking layer is formed by a vacuum evaporation method using a metal mask. In FIG. 4B, the light-emitting device 10R includes a hole-blocking layer 19R that is in contact with the surface included in the light-emitting layer 13R and facing the cathode 15. As illustrated in FIG. 4B, in the case where the light-emitting device 10R includes the hole-blocking layer 19R, the light-emitting device 10X may include a hole-blocking layer 19X. The hole-blocking layer 19X is located between the light-emitting layer 13X_1 and the light-emitting layer 13X_2 and is in contact with the surface included in the light-emitting layer 13X_1 and facing the cathode 15. The hole-blocking layer 19X is formed in the same process as the hole-blocking layer 19R by a vacuum evaporation method using a metal mask. In the case where the hole-blocking layer 19X and the hole-blocking layer 19R are formed in the same process by a vacuum evaporation method using a metal mask, the hole-blocking layer 19R and the hole-blocking layer 19X can be formed successively after the formation of the light-emitting layer 13R and the light-emitting layer 13X_1 without metal mask exchange. That is, another metal mask for forming the hole-blocking layer 19R and the hole-blocking layer 19X does not need to be prepared, reducing the manufacturing cost of the display device 100.

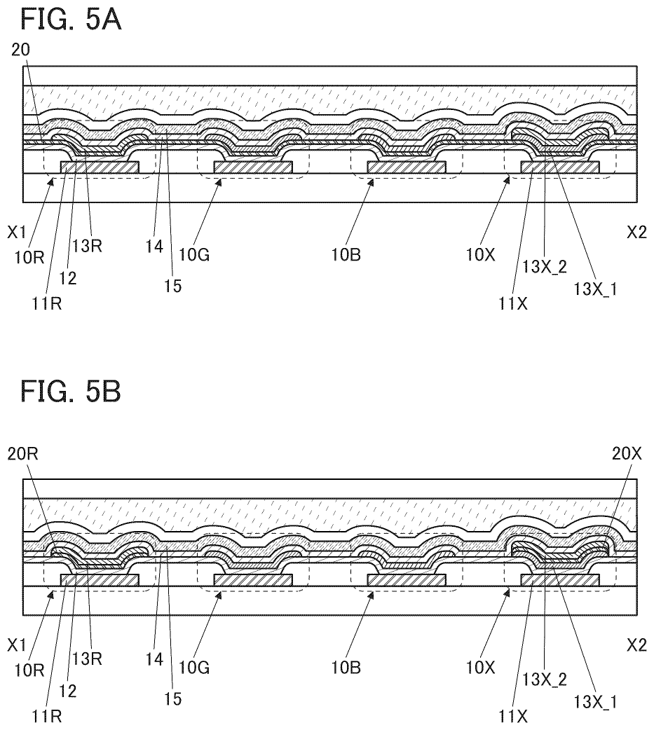

FIG. 5A illustrates an example in which the light-emitting layer 13R includes an organic compound with a high electron-transport property and an electron-blocking layer as a common layer is provided. In FIG. 5A, an electron-blocking layer 20 is shared by the light-emitting devices 10R, 10G, 10B, and 10X and is provided in contact with the surface included in the light-emitting layer 13R and facing the anode 11R, the surface included in the light-emitting layer 13G and facing the anode 11R, the surface included in the light-emitting layer 13B and facing the anode 11R, and the surface included in the light-emitting layer 13X_1 and facing the anode 11R. In the case where an electron-blocking layer as a common layer is provided, another metal mask for forming the electron-blocking layer does not need to be prepared, reducing the manufacturing cost of the display device 100.

FIG. 5B illustrates an example case where the light-emitting layer 13X_1 is the layer including the light-emitting substance G; the light-emitting layer 13X_2 is the layer including the light-emitting substance R; the light-emitting layer 13R includes an organic compound with a high electron-transport property; and an electron-blocking layer is formed by a vacuum evaporation method using a metal mask. In FIG. 5B, the light-emitting device 10R includes an electron-blocking layer 20R that is in contact with the surface included in the light-emitting layer 13R and facing the anode 11R. As illustrated in FIG. 5B, in the case where the light-emitting device 10R includes the electron-blocking layer 20R, the light-emitting device 10X may include an electron-blocking layer 20X. The electron-blocking layer 20X is located between the light-emitting layer 13X_1 and the light-emitting layer 13X_2 and is in contact with the surface included in the light-emitting layer 13X_2 and facing the anode 11X. The electron-blocking layer 20X is formed in the same process as the electron-blocking layer 20R by a vacuum evaporation method using a metal mask. In the case where the electron-blocking layer 20X and the electron-blocking layer 20R are formed in the same process by a vacuum evaporation method using a metal mask, the light-emitting layer 13R and the light-emitting layer 13X_2 can be formed successively after the formation of the electron-blocking layer 20R and the electron-blocking layer 20X without metal mask exchange. That is, another metal mask for forming the electron-blocking layer 20R and the electron-blocking layer 20X does not need to be prepared, reducing the manufacturing cost of the display device 100.

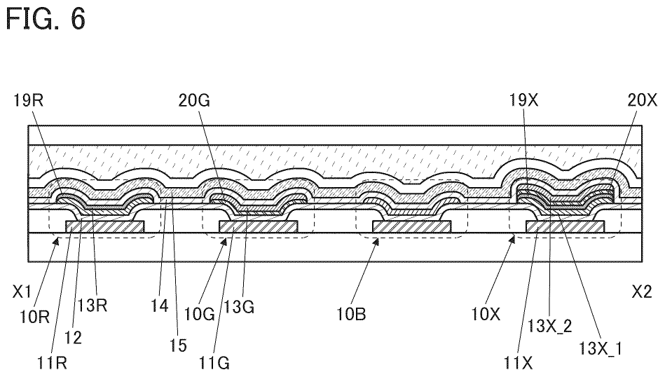

FIG. 6 illustrates an example in which a hole-blocking layer and an electron-blocking layer are each formed by a vacuum evaporation method using a metal mask. In FIG. 6, the light-emitting layer 13X_1 is the layer including the light-emitting substance R, and the light-emitting layer 13X_2 is the layer including the light-emitting substance G. In FIG. 6, the light-emitting device 10R includes the hole-blocking layer 19R that is in contact with the surface included in the light-emitting layer 13R and facing the cathode 15. Furthermore, the light-emitting device 10G includes an electron-blocking layer 20G that is in contact with the surface included in the light-emitting layer 13G and facing the anode 11G. As illustrated in FIG. 6, in the case where the light-emitting device 10R includes the hole-blocking layer 19R, the light-emitting device 10X may include the hole-blocking layer 19X. The hole-blocking layer 19X is located between the light-emitting layer 13X_1 and the light-emitting layer 13X_2 and is in contact with the surface included in the light-emitting layer 13X_1 and facing the cathode 15. The hole-blocking layer 19X is formed in the same process as the hole-blocking layer 19R by a vacuum evaporation method using a metal mask. As illustrated in FIG. 6, in the case where the light-emitting device 10G includes the electron-blocking layer 20G, the light-emitting device 10X may include the electron-blocking layer 20X. The electron-blocking layer 20X is located between the light-emitting layer 13X_1 and the light-emitting layer 13X_2 and is in contact with the surface included in the light-emitting layer 13X_2 and facing the anode 11X. The electron-blocking layer 20X is formed in the same process as the electron-blocking layer 20G by a vacuum evaporation method using a metal mask. In this manner, a structure that includes both a hole-blocking layer and an electron-blocking layer can be employed to control carrier balance.

In the case where a carrier-blocking layer is formed by a vacuum evaporation method using a metal mask, the carrier-blocking layer is sometimes sandwiched between the light-emitting layer 13X_1 and the light-emitting layer 13X_2 in the light-emitting device 10X as illustrated in FIG. 4B, FIG. 5B, and FIG. 6. In the case of employing such a structure, it is preferable that the carrier-blocking layer have a bipolar property or a small thickness. In the case where the carrier-blocking layer is formed by a vacuum evaporation method using a metal mask, the thickness of the carrier-blocking layer is preferably greater than or equal to 1 nm and less than or equal to 20 nm, further preferably greater than or equal to 3 nm and less than or equal to 10 nm. In that case, the emission efficiency of the light-emitting device 10X can be increased.

In another example method for solving the aforementioned problem, the light-emitting layer S is sandwiched between two of the light-emitting layers L. When this method is employed, the recombination center easily overlaps with the light-emitting layer S, so that the light-emitting layer S can easily receive energy.

Thus, the light-emitting device 10X may include a stacked light-emitting layer composed of a light-emitting layer 13X_1h, a light-emitting layer 13X_1e, and the light-emitting layer 13X_2 sandwiched between the light-emitting layer 13X_1h and the light-emitting layer 13X_1e. Note that the light-emitting layer 13X_1h and the light-emitting layer 13X_1e include the same light-emitting substance, which is different from the light-emitting substance included in the light-emitting layer 13X_2. For example, each of the light-emitting layer 13X_1h and the light-emitting layer 13X_1e is preferably the layer including the light-emitting substance R and the light-emitting layer 13X_2 is preferably the layer including the light-emitting substance G or the layer including the light-emitting substance B, in which case the light-emitting layer 13X_2 can easily receive energy. For another example, each of the light-emitting layer 13X_1h and the light-emitting layer 13X_1e is preferably the layer including the light-emitting substance G and the light-emitting layer 13X_2 is preferably the layer including the light-emitting substance B, in which case the light-emitting layer 13X_2 can easily receive energy. In the light-emitting device 10X having such a structure, the light-emitting layer 13X_2 including the light-emitting substance whose emission spectrum has a shorter peak wavelength is sandwiched between the light-emitting layer 13X_1h and the light-emitting layer 13X_1e including the light-emitting substance whose emission spectrum has a longer peak wavelength, so that the recombination center can be located in the light-emitting layer 13X_2. Thus, favorable light emission can be obtained from each of the light-emitting layer 13X_1h, the light-emitting layer 13X_1e, and the light-emitting layer 13X_2.

Note that the materials other than the light-emitting substance may be different between the light-emitting layer 13X_1h and the light-emitting layer 13X_1e. For example, one of the light-emitting layer 13X_1h and the light-emitting layer 13X_1e that is located closer to the anode 11X may include a hole-transport material, and the other that is closer to the cathode 15 may include an electron-transport material. In that case, the emission efficiency of the light-emitting layer 13X_2 can be increased.

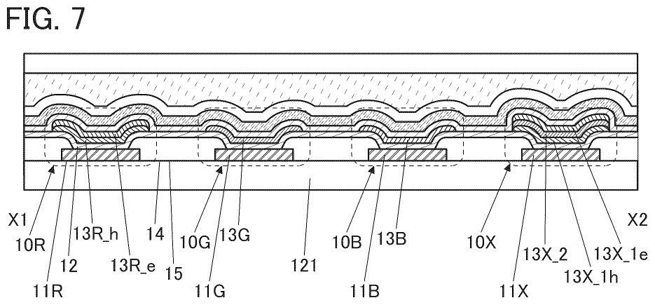

FIG. 7 illustrates an example case where the light-emitting layer 13X_1h and the light-emitting layer 13X_1e are each the layer including the light-emitting substance R and the light-emitting layer 13X_2 is the layer including the light-emitting substance G. In FIG. 7, it is preferable that the light-emitting layer 13X_1h located closer to the anode 11X include a hole-transport material and the light-emitting layer 13X_1e located closer to the cathode 15 include an electron-transport material.

In that case, the light-emitting layer 13X_1h is formed in the same process as a light-emitting layer 13R_h by a vacuum evaporation method using a metal mask, and the light-emitting layer 13X_1e is formed in the same process as a light-emitting layer 13R_e by a vacuum evaporation method using a metal mask. Thus, it is preferable that the light-emitting layer 13R_h include the hole-transport material and the light-emitting layer 13R_e include the electron-transport material.

In other words, it is preferable that in the structure illustrated in FIG. 7, the light-emitting layer 13R_h and the light-emitting layer 13X_1h be formed using the hole-transport material and the light-emitting layer 13R_e and the light-emitting layer 13X_1e be formed using the electron-transport material.

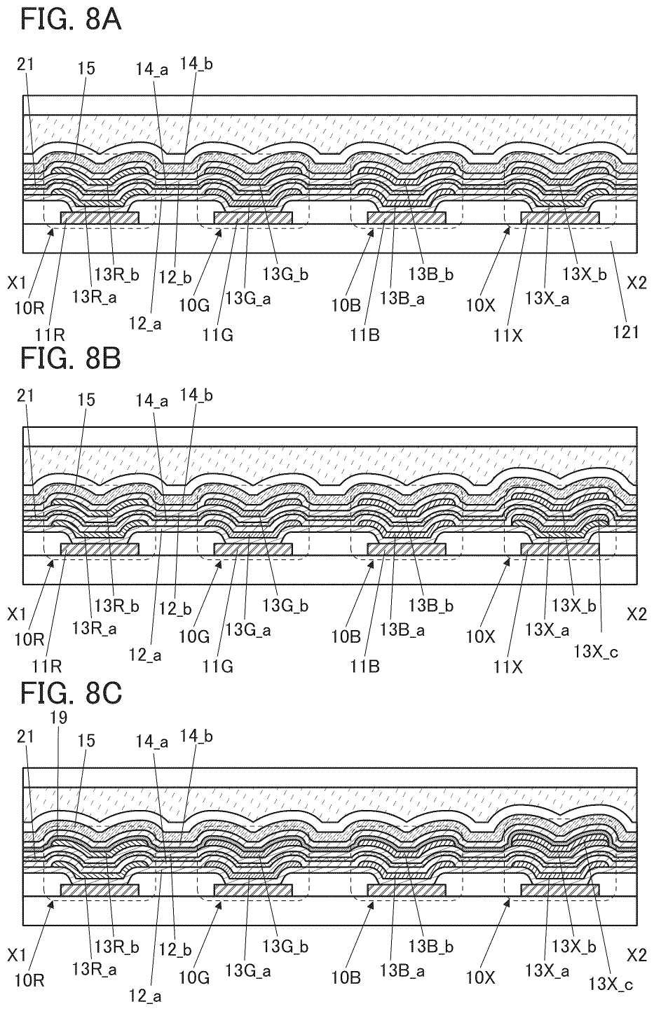

The light-emitting devices 10R, 10G, 10B, and 10X may each be what is called a tandem-type light-emitting device, in which an intermediate layer (charge-generation layer) is provided between a plurality of light-emitting layers. FIG. 8A illustrates an example in which the light-emitting devices 10R, 10G, 10B, and 10X are tandem-type light-emitting devices.

As illustrated in FIG. 8A, the tandem-type light-emitting devices 10R, 10G, 10B, and 10X are provided in the display device 100 in the following manner: the anode 11R, the anode 11G, the anode 11B, and the anode 11X are provided over the layer 121; a first hole-injection/transport layer 12_a is provided over the anode 11R, the anode 11G, the anode 11B, and the anode 11X; a first light-emitting layer 13R_a, a first light-emitting layer 13G_a, a first light-emitting layer 13B_a, and a first light-emitting layer 13X_a are provided over the first hole-injection/transport layer 12_a; a first electron-injection/transport layer 14_a is provided over the first light-emitting layer 13R_a, the first light-emitting layer 13G_a, the first light-emitting layer 13B_a, and the first light-emitting layer 13X_a; an intermediate layer 21 is provided over the first electron-injection/transport layer 14_a; a second hole-injection/transport layer 12_b is provided over the intermediate layer 21; a second light-emitting layer 13R_b, a second light-emitting layer 13G_b, a second light-emitting layer 13B_b, and a second light-emitting layer 13X_b are provided over the second hole-injection/transport layer 12_b; a second electron-injection/transport layer 14_b is provided over the second light-emitting layer 13R_b, the second light-emitting layer 13G_b, the second light-emitting layer 13B_b, and the second light-emitting layer 13X_b; and the cathode 15 is formed over the second electron-injection/transport layer 14_b.

The first hole-injection/transport layer 12_a, the second hole-injection/transport layer 12_b, the intermediate layer 21, the first electron-injection/transport layer 14_a, the second electron-injection/transport layer 14_b, and the cathode 15 are preferably common layers. The first light-emitting layers 13R_a, 13G_a, 13B_a, and 13X_a and the second light-emitting layers 13R_b, 13G_b, 13B_b, and 13X_b are preferably formed in the respective devices by a vacuum evaporation method using a metal mask.

The tandem-type light-emitting device 10R includes the first light-emitting layer 13R_a, the second light-emitting layer 13R_b, and the intermediate layer 21 between the anode 11R and the cathode 15, and the intermediate layer 21 is located between the first light-emitting layer 13R_a and the second light-emitting layer 13R_b. The first light-emitting layer 13R_a is located between the anode 11R and the intermediate layer 21. The second light-emitting layer 13R_b is located between the intermediate layer 21 and the cathode 15. The tandem-type light-emitting device 10R includes the first hole-injection/transport layer 12_a, the first electron-injection/transport layer 14_a, the second hole-injection/transport layer 12_b, and the second electron-injection/transport layer 14_b. The first hole-injection/transport layer 12_a is located between the anode 11R and the first light-emitting layer 13R_a. The first electron-injection/transport layer 14_a is located between the first light-emitting layer 13R_a and the intermediate layer 21. The second hole-injection/transport layer 12_b is located between the intermediate layer 21 and the second light-emitting layer 13R_b. The second electron-injection/transport layer 14_b is located between the second light-emitting layer 13R_b and the cathode 15. The first light-emitting layer 13R_a and the second light-emitting layer 13R_b each include at least the light-emitting substance R.

The tandem-type light-emitting device 10G includes the first light-emitting layer 13G_a, the second light-emitting layer 13G_b, and the intermediate layer 21 between the anode 11G and the cathode 15, and the intermediate layer 21 is located between the first light-emitting layer 13G_a and the second light-emitting layer 13G_b. The first light-emitting layer 13G_a is located between the anode 11G and the intermediate layer 21. The second light-emitting layer 13G_b is located between the intermediate layer 21 and the cathode 15. The tandem-type light-emitting device 10G includes the first hole-injection/transport layer 12_a, the first electron-injection/transport layer 14_a, the second hole-injection/transport layer 12_b, and the second electron-injection/transport layer 14_b. The first hole-injection/transport layer 12_a is located between the anode 11G and the first light-emitting layer 13G_a. The first electron-injection/transport layer 14_a is located between the first light-emitting layer 13G_a and the intermediate layer 21. The second hole-injection/transport layer 12_b is located between the intermediate layer 21 and the second light-emitting layer 13G_b. The second electron-injection/transport layer 14_b is located between the second light-emitting layer 13G_b and the cathode 15. The first light-emitting layer 13G_a and the second light-emitting layer 13G_b each include at least the light-emitting substance G.

The tandem-type light-emitting device 10B includes the first light-emitting layer 13B_a, the second light-emitting layer 13B_b, and the intermediate layer 21 between the anode 11B and the cathode 15, and the intermediate layer 21 is located between the first light-emitting layer 13B_a and the second light-emitting layer 13B_b. The first light-emitting layer 13B_a is located between the anode 11B and the intermediate layer 21. The second light-emitting layer 13B_b is located between the intermediate layer 21 and the cathode 15. The tandem-type light-emitting device 10B includes the first hole-injection/transport layer 12_a, the first electron-injection/transport layer 14_a, the second hole-injection/transport layer 12_b, and the second electron-injection/transport layer 14_b. The first hole-injection/transport layer 12_a is located between the anode 11B and the first light-emitting layer 13B_a. The first electron-injection/transport layer 14_a is located between the first light-emitting layer 13B_a and the intermediate layer 21. The second hole-injection/transport layer 12_b is located between the intermediate layer 21 and the second light-emitting layer 13B_b. The second electron-injection/transport layer 14_b is located between the second light-emitting layer 13B_b and the cathode 15. The first light-emitting layer 13B_a and the second light-emitting layer 13B_b each include at least the light-emitting substance B.

In the tandem-type light-emitting device 10X, the anode 11X, the first hole-injection/transport layer 12_a, the first light-emitting layer 13X_a, the first electron-injection/transport layer 14_a, the intermediate layer 21, the second hole-injection/transport layer 12_b, the second light-emitting layer 13X_b, the second electron-injection/transport layer 14_b, and the cathode 15 are stacked in this order. The first light-emitting layer 13X_a and the second light-emitting layer 13X_b include different light-emitting substances.

The first light-emitting layer 13X_a is formed in the same process as any of the first light-emitting layers 13R_a, 13G_a, and 13B_a by a vacuum evaporation method using a metal mask. The second light-emitting layer 13X_b is formed in the same process as any of the second light-emitting layers 13R_b, 13G_b, and 13B_b by a vacuum evaporation method using a metal mask.

Also in the display device 100 including the tandem-type light-emitting devices, the light-emitting device 10X can be fabricated without adding steps or materials for providing the light-emitting device 10X in the display device 100, which can reduce the cost of the display device 100.

The intermediate layer 21 includes an organic compound and an alkali metal or an alkaline earth metal. As described above, the intermediate layer 21 is preferably a common layer. Thus, the intermediate layer 21 in the light-emitting device 10R, the intermediate layer 21 in the light-emitting device 10G, the intermediate layer 21 in the light-emitting device 10B, and the intermediate layer 21 in the light-emitting device 10X each preferably include an organic compound and an alkali metal or an alkaline earth metal, further preferably include the same organic compound and the same alkali metal or alkaline earth metal.

The tandem-type light-emitting device 10X may include a third light-emitting layer 13X_c that includes a light-emitting substance different from the light-emitting substances included in the first light-emitting layer 13X_a and the second light-emitting layer 13X_b. The third light-emitting layer 13X_c is preferably provided in contact with the first light-emitting layer 13X_a or the second light-emitting layer 13X_b. The display device illustrated in FIG. 8B is a variation example of the display device illustrated in FIG. 8A and includes the light-emitting device 10X provided with the third light-emitting layer 13X_c that is in contact with the surface included in the first light-emitting layer 13X_a and facing the cathode 15.

In the case where the third light-emitting layer 13X_c is provided in contact with the first light-emitting layer 13X_a as illustrated in FIG. 8B, the third light-emitting layer 13X_c can be formed in the same process as any of the first light-emitting layers 13R_a, 13G_a, and 13B_a by a vacuum evaporation method using a metal mask. In the case where the third light-emitting layer 13X_c is provided in contact with the second light-emitting layer 13X_b, although such a structure is not shown, the third light-emitting layer 13X_c can be formed in the same process as any of the second light-emitting layers 13R_b, 13G_b, and 13B_b by a vacuum evaporation method using a metal mask.

Also in the case where the third light-emitting layer 13X_c is provided, the light-emitting device 10X can be fabricated without adding steps or materials for providing the light-emitting device 10X, which can reduce the cost of the display device 100.

In the case where the tandem-type light-emitting device 10X is provided with the third light-emitting layer 13X_c that is in contact with the first light-emitting layer 13X_a or the second light-emitting layer 13X_b, the emission intensity of the light-emitting layer L emitting light with a long wavelength is sometimes higher than the emission intensity of the light-emitting layer S emitting light with a short wavelength as in the case of the single-type light-emitting device 10X. Thus, the stacking order of the layers of the stacked light-emitting layer, the structures of the light-emitting layers, the thicknesses of the light-emitting layers, the electron-blocking layer, the hole-blocking layer, and the like in the description of the single-type light-emitting device 10X may be applied to the tandem-type light-emitting device 10X. In the case where the third light-emitting layer 13X_c is provided in contact with the first light-emitting layer 13X_a, the intermediate layer 21 can be regarded as corresponding to the cathode 15 in the single-type light-emitting device 10X, and in the case where the third light-emitting layer 13X_c is provided in contact with the second light-emitting layer 13X_b, the intermediate layer 21 can be regarded as corresponding to the anode 11X in the single-type light-emitting device 10X.

FIG. 8C illustrates an example in which the tandem-type light-emitting device 10X is provided with the third light-emitting layer 13X_c that is in contact with the surface included in the second light-emitting layer 13X_b and facing the cathode 15, the third light-emitting layer 13X_c is formed in the same process as the second light-emitting layer 13R_b by a vacuum evaporation method using a metal mask, and the hole-blocking layer 19 is provided. For example, in the case where the third light-emitting layer 13X_c and the second light-emitting layer 13R_b include an organic compound with a high hole-transport property, providing the hole-blocking layer 19 in this manner prevents holes from passing through the second light-emitting layer 13R_b in the tandem-type light-emitting device 10R and facilitates carrier recombination in the light-emitting layer 13R, whereby the emission efficiency of the light-emitting device 10R can be increased.

Since the other components of the tandem-type light-emitting device 10X are similar to those of the single-type light-emitting device 10X, the description thereof is omitted. Since the other components of the display device that includes the tandem-type light-emitting devices are similar to those of the display device that includes the single-type light-emitting devices, the description thereof is omitted.

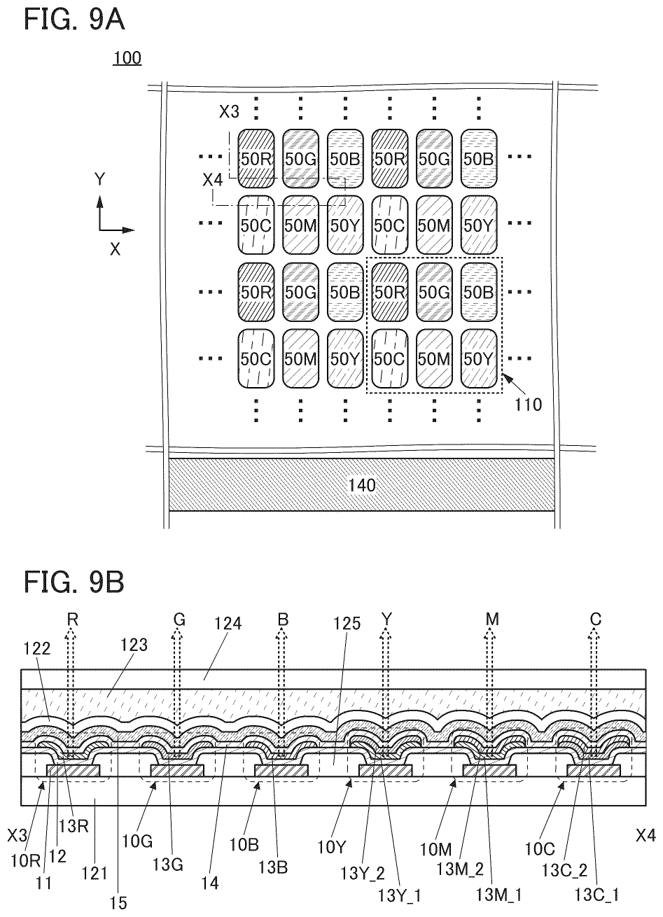

Although the pixel 110 is composed of four subpixels in the display device 100 illustrated in FIG. 1A, a pixel in a display device of one embodiment of the present invention may be composed of four or more subpixels. FIG. 9A illustrates a display device 100A that is a variation example of the display device 100. In the display device 100A, the pixel 110 illustrated in FIG. 9A includes six subpixels of the subpixels 50R, 50G, 50B, 50Y, 50C, and 50M. The subpixels 50R, 50G, 50B, 50Y, 50C, and 50M emit light of different colors. Examples of the subpixels 50R, 50G, and 50B include red (R), green (G), and blue (B) subpixels. Examples of the subpixels 50Y, 50C, and 50M include yellow (Y), cyan (C), and magenta (M) subpixels.

FIG. 9B is a cross-sectional view along the dashed-dotted line X3-X4 in FIG. 9A.

In the display device 100A, the light-emitting device 10R, the light-emitting device 10G, the light-emitting device 10B, a light-emitting device 10Y, a light-emitting device 10M, and a light-emitting device 10C are provided over the layer 121, and the protective layer 122 is provided to cover these light-emitting devices. The substrate 124 is attached above these components with the resin layer 123. The insulating layer 125 is provided in a region between adjacent light-emitting devices.

Light emitted from the light-emitting device 10R, light emitted from the light-emitting device 10G, light emitted from the light-emitting device 10B, light emitted from the light-emitting device 10Y, light emitted from the light-emitting device 10M, and light emitted from the light-emitting device 10C have different colors. For example, it is preferable that the light-emitting device 10R emit red (R) light, the light-emitting device 10G emit green (G) light, the light-emitting device 10B emit blue (B) light, the light-emitting device 10Y emit yellow (Y) light, the light-emitting device 10M emit magenta (M) light, and the light-emitting device 10C emit cyan (C) light.

As illustrated in FIG. 9B, the light-emitting devices 10R, 10G, 10B, 10Y, 10M, and 10C are provided in the display device 100A in the following manner: the anode 11R, the anode 11G, the anode 11B, an anode 11Y, an anode 11M, and an anode 11C are provided over the layer 121; the hole-injection/transport layer 12 is provided over the anode 11R, the anode 11G, the anode 11B, the anode 11Y, the anode 11M, and the anode 11C; the light-emitting layer 13R, the light-emitting layer 13G, the light-emitting layer 13B, a light-emitting layer 13Y_1, a light-emitting layer 13M_1, and a light-emitting layer 13C_1 are provided over the hole-injection/transport layer 12; a light-emitting layer 13Y_2 is provided over the light-emitting layer 13Y_1; a light-emitting layer 13M_2 is provided over the light-emitting layer 13M_1; a light-emitting layer 13C_2 is provided over the light-emitting layer 13C_1; the electron-injection/transport layer 14 is provided over the light-emitting layer 13R, the light-emitting layer 13G, the light-emitting layer 13B, the light-emitting layer 13Y_2, the light-emitting layer 13M_2, and the light-emitting layer 13C_2; and the cathode 15 is formed over the electron-injection/transport layer 14.

The light-emitting device 10Y has the same structure as the yellow (Y)-light-emitting device 10X. That is, the light-emitting device 10Y has a stacked-layer structure of light-emitting layers (13Y_1 and 13Y_2) of two colors, and one of the light-emitting layers is the layer including the light-emitting substance R and the other is the layer including the light-emitting substance G.

The light-emitting device 10M has the same structure as the magenta (M)-light-emitting device 10X. That is, the light-emitting device 10M has a stacked-layer structure of light-emitting layers (13M_1 and 13M_2) of two colors, and one of the light-emitting layers is the layer including the light-emitting substance R and the other is the layer including the light-emitting substance B.

The light-emitting device 10C has the same structure as the cyan (C)-light-emitting device 10X. That is, the light-emitting device 10C has a stacked-layer structure of light-emitting layers (13C_1 and 13C_2) of two colors, and one of the light-emitting layers is the layer including the light-emitting substance G and the other is the layer including the light-emitting substance B.

Since the other components of the display device 100A are similar to those of the display device 100, the description thereof is omitted.

When the pixel 110 includes six subpixels as in the structure of the display device 100A, the number of color gradations of the display device 100A can be increased.

The structures described in this embodiment can be used in appropriate combination with any of the structures described in the other embodiments.

### Embodiment 2

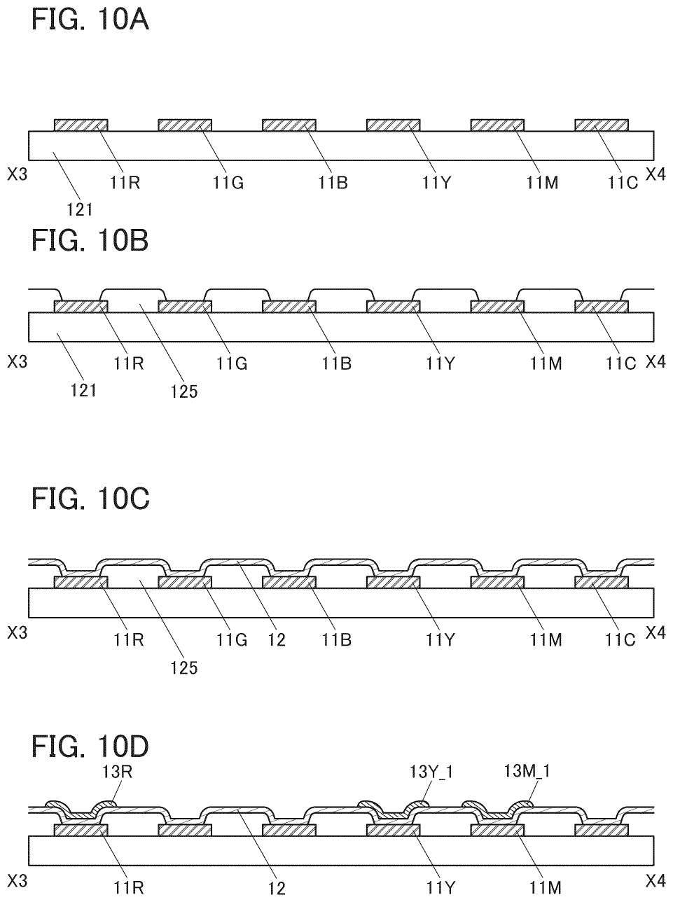

In this embodiment, a method for manufacturing the display device 100A, which is a display device of one embodiment of the present invention, is described with reference to FIGS. 10A to 10D, FIGS. 11A to 11D, and FIGS. 12A and 12B, which are cross-sectional views of the display device 100A taken along the dashed-dotted line X3-X4 in FIG. 9A.

Note that thin films included in the display device (e.g., insulating films, semiconductor films, and conductive films) can be formed by any of a sputtering method, a chemical vapor deposition (CVD) method, a vacuum evaporation method, a pulsed laser deposition (PLD) method, an atomic layer deposition (ALD) method, and the like. Examples of a CVD method include a plasma-enhanced CVD (PECVD) method and a thermal CVD method. An example of a thermal CVD method is a metal organic CVD (MOCVD) method.

Alternatively, thin films included in the display device (e.g., insulating films, semiconductor films, and conductive films) can be formed by spin coating, dipping, spray coating, ink-jetting, dispensing, screen printing, or offset printing or with a doctor knife, a slit coater, a roll coater, a curtain coater, or a knife coater.

Specifically, for fabrication of the light-emitting device, a vacuum process such as an evaporation method and a solution process such as a spin coating method or an ink-jet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a light-emitting layer, an electron-transport layer, and an electron-injection layer) included in an EL layer can be formed by an evaporation method (e.g., a vacuum evaporation method), a coating method (e.g., a dip coating method, a die coating method, a bar coating method, a spin coating method, or a spray coating method), a printing method (e.g., an ink-jet method, screen printing (stencil), offset printing (planography), flexography (relief printing), gravure printing, or micro-contact printing), or the like.

Thin films included in the display device can be processed by a photolithography method or the like. Alternatively, the thin films may be processed by a nanoimprinting method, a sandblasting method, a lift-off method, or the like. Alternatively, island-shaped thin films may be directly formed by a film formation method using a shielding mask such as a metal mask.

There are two typical examples of photolithography methods. In one of the methods, a resist mask is formed over a thin film to be processed, the thin film is processed by etching or the like, and then the resist mask is removed. In the other method, a photosensitive thin film is formed and then processed into a desired shape by light exposure and development.

As light for exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Light exposure may be performed by liquid immersion exposure technique. As the light for exposure, extreme ultraviolet (EUV) light or X-rays may also be used. Furthermore, instead of the light for exposure, an electron beam can be used. EUV, X-rays, or an electron beam is preferably used to enable extremely minute processing. Note that a photomask is not needed when light exposure is performed by scanning with a beam such as an electron beam.

For etching of thin films, a dry etching method, a wet etching method, a sandblast method, or the like can be used.

First, over the layer 121 including transistors (not illustrated), the anodes 11R, 11G, 11B, 11Y, 11M, and 11C are formed (see FIG. 10A). The anodes 11R, 11G, 11B, 11Y, 11M, and 11C can be formed in the following manner: first, a metal film is formed over the layer 121; a resist mask is then formed by a photolithography method; unnecessary portions of the conductive film are removed by etching; after that, the resist mask is removed.

Next, the insulating layer 125 is formed to cover the layer 121 and end portions of the anodes 11R, 11G, 11B, 11Y, 11M, and 11C (see FIG. 10B).

Then, the hole-injection/transport layer 12 is formed over the anodes 11R, 11G, 11B, 11Y, 11M, and 11C and the insulating layer 125 (see FIG. 10C).

Next, the light-emitting layers 13R, 13Y_1, and 13M_1 are formed over the hole-injection/transport layer 12 to overlap with the anodes 11R, 11Y, and 11M (see FIG. 10D).

The light-emitting layers 13R, 13Y_1, and 13M_1 are preferably formed in the same process by a vacuum evaporation method using a metal mask. In that case, there is no need to add steps or materials for providing the light-emitting layers 13Y_1 and 13M_1 in addition to the light-emitting layer 13R, which can reduce the manufacturing cost.

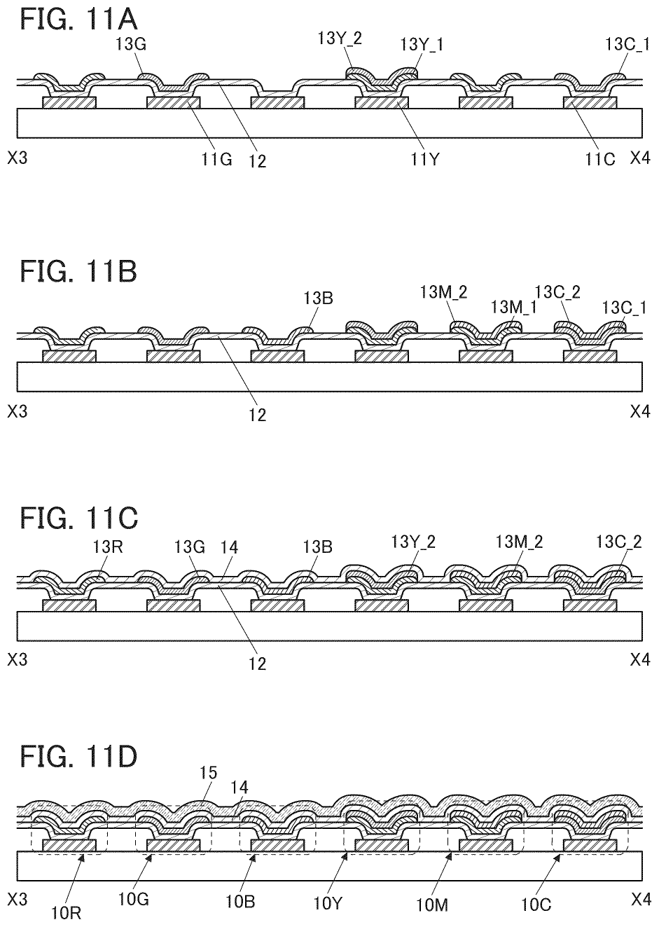

Then, the light-emitting layers 13G and 13C_1 are formed over the hole-injection/transport layer 12 to overlap with the anodes 11G and 11C, and the light-emitting layer 13Y_2 is formed over the light-emitting layer 13Y_1 (see FIG. 11A).

The light-emitting layers 13G, 13Y_2, and 13C_1 are preferably formed in the same process by a vacuum evaporation method using a metal mask. In that case, there is no need to add steps or materials for providing the light-emitting layers 13Y_2 and 13C_1 in addition to the light-emitting layer 13G, which can reduce the manufacturing cost.

Furthermore, the light-emitting layer 13B is formed over the hole-injection/transport layer 12 to overlap with the anode 11B, the light-emitting layer 13M_2 is formed over the light-emitting layer 13M_1, and the light-emitting layer 13C_2 is formed over the light-emitting layer 13C_1 (see FIG. 11B).

The light-emitting layers 13B, 13M_2, and 13C_2 are preferably formed in the same process by a vacuum evaporation method using a metal mask. In that case, there is no need to add steps or materials for providing the light-emitting layers 13M_2 and 13C_2 in addition to the light-emitting layer 13G, which can reduce the manufacturing cost.

Note that in the above manufacturing method, the light-emitting layer 13R is formed first, the light-emitting layer 13G is formed next, and the light-emitting layer 13B is formed last; however, the light-emitting layers 13R, 13G, and 13B are not necessarily formed in this order. For example, the light-emitting layer 13B may be formed first, the light-emitting layer 13G may be formed next, and the light-emitting layer 13R may be formed last. In that case, the light-emitting layers 13M_1 and 13C_1 are preferably formed in the same process as the light-emitting layer 13B; the light-emitting layers 13Y_1 and 13C_2 are preferably formed in the same process as the light-emitting layer 13G; and the light-emitting layers 13Y_2 and 13M_2 are preferably formed in the same process as the light-emitting layer 13R.

Next, the electron-injection/transport layer 14 is formed over the light-emitting layers 13R, 13G, 13B, 13Y_2, 13M_2, and 13C_2 (see FIG. 11C).

Then, the cathode 15 is formed over the electron-injection/transport layer 14 (FIG. 11D), whereby the light-emitting devices 10R, 10G, 10B, 10Y, 10M, and 10C are provided. The cathode 15 can be formed by a sputtering method or a vacuum evaporation method, for example.

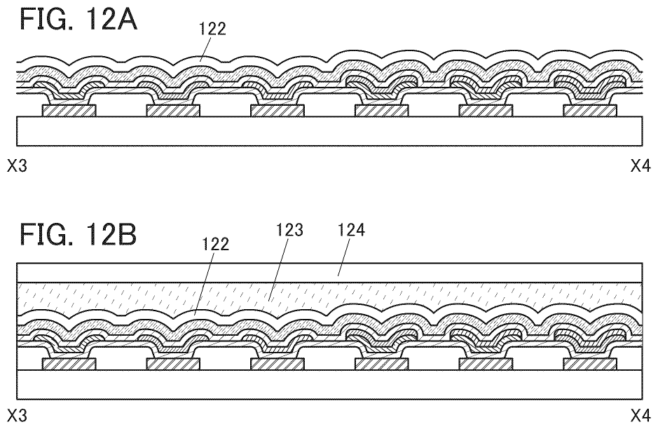

Then, the protective layer 122 is formed over the cathode 15 to cover the light-emitting devices 10R, 10G, 10B, 10Y, 10M, and 10C (FIG. 12A).

Lastly, the substrate 124 is attached using the resin layer 123, so that the display device of one embodiment of the present invention can be manufactured (FIG. 12B).

In manufacture of the display device of one embodiment of the present invention by the above-described manufacturing method, the light-emitting devices 10Y, 10M, and 10C can be fabricated in addition to the light-emitting devices 10R, 10G, and 10B without adding steps or materials, which can reduce the manufacturing cost.

The structures described in this embodiment can be used in appropriate combination with any of the structures described in the other embodiments.

### Embodiment 3

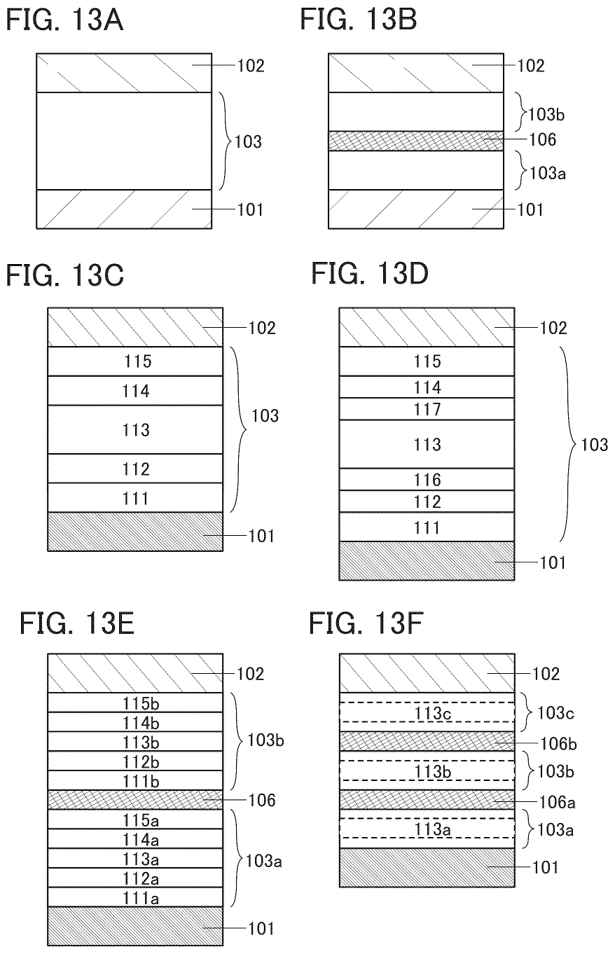

In this embodiment, structures of a light-emitting device that can be used in a display device of one embodiment of the present invention will be described with reference to FIGS. 13A to 13F.

### <<Basic Structure of Light-Emitting Device>>

A basic structure of a light-emitting device is described. FIG. 13A illustrates a light-emitting device including, between a pair of electrodes, an EL layer (also referred to as an organic compound layer) including a light-emitting layer. Specifically, an EL layer 103 is located between a first electrode 101 and a second electrode 102.

FIG. 13B illustrates a light-emitting device that has a stacked-layer structure (tandem-type structure) in which a plurality of EL layers (two EL layers 103a and 103b in FIG. 13B) are provided between a pair of electrodes and a charge-generation layer 106 is provided between the EL layers. A light-emitting device having a tandem-type structure enables manufacturing a light-emitting apparatus that has high efficiency without changing the amount of current.

The charge-generation layer 106 has a function of injecting electrons into one of the EL layers 103a and 103b and injecting holes into the other of the EL layers 103a and 103b when a potential difference is caused between the first electrode 101 and the second electrode 102. Thus, when voltage is applied such that the potential of the first electrode 101 is higher than that of the second electrode 102 in FIG. 13B, the charge-generation layer 106 injects electrons into the EL layer 103a and injects holes into the EL layer 103b.

Note that in terms of light extraction efficiency, the charge-generation layer 106 preferably has a property of transmitting visible light (specifically, the charge-generation layer 106 preferably has a visible light transmittance higher than or equal to 40%). The charge-generation layer 106 functions even if it has lower conductivity than the first electrode 101 and the second electrode 102.

FIG. 13C illustrates a stacked-layer structure of the EL layer 103 in the light-emitting device. In this case, the first electrode 101 is regarded as functioning as an anode, and the second electrode 102 is regarded as functioning as a cathode. The EL layer 103 has a structure in which a hole-injection layer 111, a hole-transport layer 112, a light-emitting layer 113, an electron-transport layer 114, and an electron-injection layer 115 are stacked in this order over the first electrode 101. As described in Embodiment 1, the stacked-layer structure of the hole-injection layer 111 and the hole-transport layer 112 may be collectively referred to as a hole-injection/transport layer. As described in Embodiment 1, the stacked-layer structure of the electron-transport layer 114 and the electron-injection layer 115 may be collectively referred to as an electron-injection/transport layer. The light-emitting layer 113 may have a structure in which a plurality of light-emitting layers having different emission colors are stacked to be in contact with each other as described in Embodiment 1. When the first electrode 101 is the cathode and the second electrode 102 is the anode, the stacking order of the layers in the EL layer 103 is reversed. Specifically, the layer 111 over the first electrode 101 serving as the cathode is an electron-injection layer; the layer 112 is an electron-transport layer; the layer 113 is a light-emitting layer; the layer 114 is a hole-transport layer; and the layer 115 is a hole-injection layer.

FIG. 13D illustrates a variation example of the stacked-layer structure illustrated in FIG. 13C. Also in this case, the first electrode 101 is regarded as functioning as an anode, and the second electrode 102 is regarded as functioning as a cathode. In this variation example, a hole-blocking layer and an electron-blocking layer are provided. That is, the EL layer 103 has a structure in which the hole-injection layer 111, the hole-transport layer 112, an electron-blocking layer 116, the light-emitting layer 113, a hole-blocking layer 117, the electron-transport layer 114, and the electron-injection layer 115 are stacked in this order over the first electrode 101. Note that the light-emitting layer 113 is located between the first electrode 101 and the second electrode 102. The light-emitting layer 113 may have a structure in which a plurality of light-emitting layers having different emission colors are stacked to be in contact with each other as described in Embodiment 1. The hole-transport layer 112 is located between the first electrode 101 and the light-emitting layer 113. The electron-transport layer 114 is located between the light-emitting layer 113 and the second electrode 102. The hole-injection layer 111 is located between the first electrode 101 and the hole-transport layer 112. The electron-injection layer 115 is located between the electron-transport layer 114 and the second electrode 102. The electron-blocking layer 116 is located between the hole-transport layer 112 and the light-emitting layer 113. In other words, the hole-blocking layer 117 is located between the light-emitting layer 113 and the electron-transport layer 114.

The electron-blocking layer 116 is provided to prevent passing of electrons from the light-emitting layer 113 to the first electrode 101 side, for example. The hole-blocking layer 117 is provided to prevent passing of holes from the light-emitting layer 113 to the second electrode 102 side, for example.

The light-emitting device illustrated in FIG. 13E is an example of the light-emitting device having the tandem-type structure illustrated in FIG. 13B, and includes two EL layers (103a and 103b) stacked with a charge-generation layer (106) located therebetween, as illustrated in FIG. 13E. The two EL layers (103a and 103b) include the respective light-emitting layers (113a and 113b), and the emission colors of the light-emitting layers can be selected freely. The light-emitting layers (113a and 113b) may each have a structure in which a plurality of light-emitting layers having different emission colors are stacked to be in contact with each other as described in Embodiment 1. The light-emitting device has a microcavity structure, enabling extraction of light (monochromatic light) with different wavelengths emitted from the EL layers (103a and 103b). Details of the microcavity structure will be described in <<Specific structure of light-emitting device>>. Thus, it is unnecessary to separately form EL layers for obtaining a plurality of emission colors (e.g., R, G, and B). Thus, high resolution can be easily achieved. A combination with coloring layers (color filters) is also possible. Furthermore, the emission intensity of light with a specific wavelength in the front direction can be increased, whereby power consumption can be reduced.

The light-emitting device illustrated in FIG. 13F is an example of the light-emitting device having the tandem-type structure illustrated in FIG. 13B, and includes three EL layers (103a, 103b, and 103c) stacked with charge-generation layers (106a and 106b) located therebetween, as illustrated in FIG. 13F. The three EL layers (103a, 103b, and 103c) include the respective light-emitting layers (113a, 113b, and 113c), and the emission colors of the light-emitting layers can be selected freely. For example, the light-emitting layer 113a can emit blue light, the light-emitting layer 113b can emit red light, green light, or yellow light, and the light-emitting layer 113c can emit blue light, or the light-emitting layer 113a can emit red light, the light-emitting layer 113b can emit blue light, green light, or yellow light, and the light-emitting layer 113c can emit red light. The light-emitting layers (113a, 113b, and 113c) may each have a structure in which a plurality of light-emitting layers having different emission colors are stacked to be in contact with each other as described in Embodiment 1.

### <<Specific Structure of Light-Emitting Device>>

Next, a specific structure of the light-emitting device of one embodiment of the present invention will be described. Here, the description is made using FIG. 13E illustrating the tandem-type structure. Note that the structure of the EL layer of each of the light-emitting devices with the single-type structure illustrated in FIGS. 13A, 13C, and 13D is similar to the structure of the EL layer of the light-emitting device with the tandem-type structure that will be described below.

### <First Electrode and Second Electrode>

As materials for the first electrode 101 and the second electrode 102, any of the following materials can be used in an appropriate combination as long as the above functions of the electrodes can be fulfilled. For example, a metal, an alloy, an electrically conductive compound, a mixture of these, and the like can be used as appropriate. Specifically, In—Sn oxide (also referred to as ITO), In—Si—Sn oxide (also referred to as ITSO), In—Zn oxide, or In—W—Zn oxide can be used. In addition, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use a Group 1 element or a Group 2 element in the periodic table that is not described above (e.g., lithium (Li), cesium (Cs), calcium (Ca), or strontium (Sr)), a rare earth metal such as europium (Eu) or ytterbium (Yb), an alloy containing an appropriate combination of any of these elements, graphene, or the like.

In the light-emitting device in FIG. 13E, when the first electrode 101 is the anode, a hole-injection layer 111a and a hole-transport layer 112a of the EL layer 103a are sequentially stacked over the first electrode 101 by a vacuum evaporation method. After the EL layer 103a and the charge-generation layer 106 are formed, a hole-injection layer 111b and a hole-transport layer 112b of the EL layer 103b are sequentially stacked over the charge-generation layer 106 in a similar manner.

Each of the light-emitting devices illustrated in FIGS. 13A to 13F can have a micro optical resonator (microcavity) structure when the first electrode 101 is a reflective electrode and the second electrode 102 is a transflective electrode. Thus, light from the light-emitting layer 113 in the EL layer 103 can be resonated between the electrodes and light emitted through the second electrode 102 can be intensified.

Note that when the first electrode 101 of the light-emitting device is a reflective electrode having a stacked-layer structure of a reflective conductive material and a light-transmitting conductive material (transparent conductive film), optical adjustment can be performed by adjusting the thickness of the transparent conductive film. Specifically, when the wavelength of light obtained from the light-emitting layer 113 is k, the optical path length between the first electrode 101 and the second electrode 102 (the product of the thickness and the refractive index) is preferably adjusted to be mλ/2 (m is an integer greater than or equal to 1) or close to mλ/2.

To amplify desired light (wavelength: λ) obtained from the light-emitting layer 113, it is preferable to adjust each of the optical path length from the first electrode 101 to a region where the desired light is obtained in the light-emitting layer 113 (light-emitting region) and the optical path length from the second electrode 102 to the region where the desired light is obtained in the light-emitting layer 113 (light-emitting region) to be (2m′+1)λ/4 (m′ is an integer greater than or equal to 1) or close to (2m′+1)λ/4. Here, the light-emitting region means a region where holes and electrons are recombined in the light-emitting layer 113.

By such optical adjustment, the spectrum of specific monochromatic light obtained from the light-emitting layer 113 can be narrowed and light emission with high color purity can be obtained.

In the above case, the optical path length between the first electrode 101 and the second electrode 102 is, to be exact, the total thickness from a reflective region in the first electrode 101 to a reflective region in the second electrode 102. However, it is difficult to precisely determine the reflective regions in the first electrode 101 and the second electrode 102; thus, it is assumed that the above effect can be sufficiently obtained wherever the reflective regions may be set in the first electrode 101 and the second electrode 102. Furthermore, the optical path length between the first electrode 101 and the light-emitting layer that emits the desired light is, to be exact, the optical path length between the reflective region in the first electrode 101 and the light-emitting region in the light-emitting layer that emits the desired light. However, it is difficult to precisely determine the reflective region in the first electrode 101 and the light-emitting region in the light-emitting layer that emits the desired light; thus, it is assumed that the above effect can be sufficiently obtained wherever the reflective region and the light-emitting region may be set in the first electrode 101 and the light-emitting layer that emits the desired light, respectively.

In the above light-emitting device of one embodiment of the present invention, at least one of the first electrode 101 and the second electrode 102 is a light-transmitting electrode (e.g., a transparent electrode or a transflective electrode). In the case where the light-transmitting electrode is a transparent electrode, the transparent electrode has a visible light transmittance higher than or equal to 40%. In the case where the light-transmitting electrode is a transflective electrode, the transflective electrode has a visible light reflectance higher than or equal to 20% and lower than or equal to 80%, preferably higher than or equal to 40% and lower than or equal to 70%. These electrodes preferably have a resistivity lower than or equal to 1×10⁻² Ωcm.

When one of the first electrode 101 and the second electrode 102 is a reflective electrode in the above light-emitting device of one embodiment of the present invention, the visible light reflectance of the reflective electrode is higher than or equal to 40% and lower than or equal to 100%, preferably higher than or equal to 70% and lower than or equal to 100%. This electrode preferably has a resistivity lower than or equal to 1×10⁻² Ωcm.

### <Hole-Injection Layer>

The hole-injection layers (111, 111a, and 111b) inject holes from the first electrode 101 serving as the anode and the charge-generation layers (106, 106a, and 106b) to the EL layers (103, 103a, and 103b) and include an organic acceptor material and a material having a high hole-injection property.

The organic acceptor material allows holes to be generated in another organic compound whose HOMO level is close to the LUMO level of the organic acceptor material when charge separation is caused between the organic acceptor material and the organic compound. Thus, as the organic acceptor material, a compound having an electron-withdrawing group (e.g., a halogen group or a cyano group), such as a quinodimethane derivative, a chloranil derivative, or a hexaazatriphenylene derivative, can be used. Examples of the organic acceptor material include 7,7,8,8-tetracyano-2,3,5,6-tetrafluoroquinodimethane (abbreviation: F₄-TCNQ), 3,6-difluoro-2,5,7,7,8,8-hexacyanoquinodimethane, chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylen-1,3,4,5,6,8,9,10-octafluoro-7H-pyren-2-ylidene)malononitrile. Note that among organic acceptor materials, a compound in which electron-withdrawing groups are bonded to fused aromatic rings each having a plurality of heteroatoms, such as HAT-CN, is particularly preferable because it has a high acceptor property and stable film quality against heat. Besides, a [3]radialene derivative having an electron-withdrawing group (particularly a cyano group or a halogen group such as a fluoro group), which has a very high electron-accepting property, is preferable; specific examples include α,α′,α″-1,2,3-cyclopropanetriylidenetris[4-cyano-2,3,5,6-tetrafluorobenzeneacetonitrile], α,α′, α″-1,2,3-cyclopropanetriylidenetris[2,6-dichloro-3,5-difluoro-4-(trifluoromethyl)benzeneacetonitrile], and α,α, α′-1,2,3-cyclopropanetriylidenetris[2,3,4,5,6-pentafluorobenzeneacetonitrile].

As the material having a high hole-injection property, an oxide of a metal belonging to Group 4 to Group 8 of the periodic table (e.g., a transition metal oxide such as molybdenum oxide, vanadium oxide, ruthenium oxide, tungsten oxide, or manganese oxide) can be used. Specific examples include molybdenum oxide, vanadium oxide, niobium oxide, tantalum oxide, chromium oxide, tungsten oxide, manganese oxide, and rhenium oxide. Among the above oxides, molybdenum oxide is preferable because it is stable in the air, has a low hygroscopic property, and is easily handled. Other examples include a perylenetetracarboxylic acid derivative such as diquinoxalino[2,3-a:2′,3′-c]phenazine (abbreviation: HATNA), 2,3,8,9,14,15-hexafluorodiquinoxalino[2,3-a:2′,3′-c]phenazine (abbreviation: HATNA-F6), 3,4,9,10-perylenetetracarboxylic diimide (abbreviation: PTCDI), or 3,4,9,10-perylenetetracarboxyl-bis-benzimidazole (abbreviation: PTCBI); (C₆₀-Iₕ)[5,6]fullerene (abbreviation: C₆₀); (C₇₀-D₅ₕ)[5,6]fullerene (abbreviation: C₇₀); an organic compound such as phthalocyanine (abbreviation: H₂Pc); and a metal phthalocyanine containing copper, zinc, cobalt, iron, chromium, nickel, or the like or a derivative thereof, such as copper phthalocyanine (abbreviation: CuPc), zinc phthalocyanine (abbreviation: ZnPc), cobalt phthalocyanine (abbreviation: CoPc), iron phthalocyanine (abbreviation: FePc), tin phthalocyanine (abbreviation: SnPc), tin oxide phthalocyanine (abbreviation: SnOPc), titanium oxide phthalocyanine (abbreviation: TiOPc), or vanadium oxide phthalocyanine (abbreviation: VOPc). A phthalocyanine-based metal complex such as CuPc or ZnPc and 2,3,8,9,14,15-hexafluorodiquinoxalino[2,3-a:2′,3′-c]phenazine are especially preferable. Among these materials, CuPc and ZnPc are preferable because they are inexpensive and have favorable characteristics. Using ZnPc, which has a low diffusion coefficient with respect to silicon, reduces the probability that metal diffusion to a semiconductor adversely affects the semiconductor characteristics; accordingly, ZnPc is particularly suitable for a display device manufactured using a silicon semiconductor.

Other examples include aromatic amine compounds, which are low-molecular compounds, such as 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl (abbreviation: DPAB), N,N-bis[4-bis(3-methylphenyl)aminophenyl]-N,N-diphenyl-4,4′-diaminobiphenyl (abbreviation: DNTPD), 1,3,5-tris[N-(4-diphenylaminophenyl)-N-phenylamino]benzene (abbreviation: DPA3B), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), and 3-[N-(1-naphthyl)-N-(9-phenylcarbazol-3-yl)amino]-9-phenylcarbazole (abbreviation: PCzPCN1).

Other examples include high-molecular compounds (e.g., oligomers, dendrimers, and polymers) such as poly(N-vinylcarbazole) (abbreviation: PVK), poly(4-vinyltriphenylamine) (abbreviation: PVTPA), poly[N-(4-{N-[4-(4-diphenylamino)phenyl]phenyl-N-phenylamino}phenyl)methacrylamide] (abbreviation: PTPDMA), and poly[N,N-bis(4-butylphenyl)-N,N-bis(phenyl)benzidine] (abbreviation: Poly-TPD). Alternatively, it is possible to use a high-molecular compound to which acid is added, such as poly(3,4-ethylenedioxythiophene)/polystyrenesulfonic acid (abbreviation: PEDOT/PSS) or polyaniline/polystyrenesulfonic acid (abbreviation: PAni/PSS), for example.

As the material having a high hole-injection property, a mixed material containing a hole-transport material and the above-described organic acceptor material (electron-accepting material) can be used. In that case, the organic acceptor material extracts electrons from the hole-transport material, so that holes are generated in the hole-injection layer 111 and the holes are injected into the light-emitting layer 113 through the hole-transport layer 112. Note that the hole-injection layer 111 may be formed to have a single-layer structure using a mixed material containing a hole-transport material and an organic acceptor material (electron-accepting material), or a stacked-layer structure of a layer including a hole-transport material and a layer including an organic acceptor material (electron-accepting material).

The hole-transport material preferably has a hole mobility higher than or equal to 1×10⁻⁶ cm²/Vs in the case where the square root of the electric field strength [V/cm] is 600. Note that other substances can also be used as long as the substances have hole-transport properties higher than electron-transport properties.

Preferable examples of the hole-transport material include hole-transport materials such as a compound having a π-electron rich heteroaromatic ring (e.g., a carbazole derivative, a furan derivative, and a thiophene derivative) and an aromatic amine (an organic compound having an aromatic amine skeleton).

Examples of the carbazole derivative (an organic compound having a carbazole ring) include a bicarbazole derivative (e.g., a 3,3′-bicarbazole derivative) and an aromatic amine having a carbazolyl group.

Specific examples of the bicarbazole derivative (e.g., a 3,3′-bicarbazole derivative) include 9,9′-diphenyl-9H,9′H-3,3′-bicarbazole (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), and 9-(2-naphthyl)-9′-phenyl-9H,9′H-3,3′-bicarbazole (abbreviation: βNCCP).

Specific examples of the aromatic amine having a carbazolyl group include 4-phenyl-4′-(9-phenyl-9H-carbazol-3-yl)triphenylamine (abbreviation: PCBA1BP), N-(biphenyl-4-yl)-N-(9,9-dimethyl-9H-fluoren-2-yl)-9-phenyl-9H-carbazol-3-amine (abbreviation: PCBiF), N-(biphenyl-4-yl)-N-[4-(9-phenyl-9H-carbazol-3-yl)phenyl]-9,9-dimethyl-9H-fluoren-2-amine (abbreviation: PCBBiF), N-[4-(9-phenyl-9H-carbazol-3-yl)phenyl]bis(9,9-dimethyl-9H-fluoren-2-yl)amine (abbreviation: PCBFF), N-(1,1′-biphenyl-4-yl)-N-[4-(9-phenyl-9H-carbazol-3-yl)phenyl]-9,9-dimethyl-9H-fluoren-4-amine, N-[4-(9-phenyl-9H-carbazol-3-yl)phenyl]-(9,9-dimethyl-9H-fluoren-2-yl)-9,9-dimethyl-9H-fluoren-4-amine, N-(1,1′-biphenyl-4-yl)-N-[4-(9-phenyl-9H-carbazol-3-yl)phenyl]-9,9-diphenyl-9H-fluoren-2-amine, N-(1,1′-biphenyl-4-yl)-N-[4-(9-phenyl-9H-carbazol-3-yl)phenyl]-9,9-diphenyl-9H-fluoren-4-amine, N-(1,1′-biphenyl-4-yl)-N-[4-(9-phenyl-9H-carbazol-3-yl)phenyl]-9,9′-spirobi(9H-fluoren)-2-amine, N-(1,1′-biphenyl-4-yl)-N-[4-(9-phenyl-9H-carbazol-3-yl)phenyl]-9,9′-spirobi(9H-fluoren)-4-amine, N-[4-(9-phenyl-9H-carbazol-3-yl)phenyl]-N-(1,1′:3′,1″-terphenyl-4-yl)-9,9-dimethyl-9H-fluoren-2-amine, N-[4-(9-phenyl-9H-carbazol-3-yl)phenyl]-N-(1,1′:4′,1″-terphenyl-4-yl)-9,9-dimethyl-9H-fluoren-2-amine, N-[4-(9-phenyl-9H-carbazol-3-yl)phenyl]-N-(1,1′:3′,1″-terphenyl-4-yl)-9,9-dimethyl-9H-fluoren-4-amine, N-[4-(9-phenyl-9H-carbazol-3-yl)phenyl]-N-(1,1′:4′,1″-terphenyl-4-yl)-9,9-dimethyl-9H-fluoren-4-amine, 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 4-phenyldiphenyl-(9-phenyl-9H-carbazol-3-yl)amine (abbreviation: PCA1BP), N,N′-bis(9-phenylcarbazol-3-yl)-N,N′-diphenylbenzene-1,3-diamine (abbreviation: PCA2B), N,N′,N″-triphenyl-N,N,N-″tris(9-phenylcarbazol-3-yl)benzene-1,3,5-triamine (abbreviation: PCA3B), 9,9-dimethyl-N-phenyl-N-[4-(9-phenyl-9H-carbazol-3-yl)phenyl]fluoren-2-amine (abbreviation: PCBAF), N-phenyl-N-[4-(9-phenyl-9H-carbazol-3-yl)phenyl]-9,9′-spirobi[9H-fluoren]-2-amine (abbreviation: PCBASF), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 3-[N-(4-diphenylaminophenyl)-N-phenylamino]-9-phenylcarbazole (abbreviation: PCzDPA1), 3,6-bis[N-(4-diphenylaminophenyl)-N-phenylamino]-9-phenylcarbazole (abbreviation: PCzDPA2), 3,6-bis[N-(4-diphenylaminophenyl)-N-(1-naphthyl)amino]-9-phenylcarbazole (abbreviation: PCzTPN2), N-(9,9-spirobi[9H-fluoren]-2-yl)-N,9-diphenylcarbazol-3-amine (abbreviation: PCASF), N-(4-biphenyl)-4-(carbazol-9-yl)phenylaniline (abbreviation: YGA1BP), N,N′-bis[4-(carbazol-9-yl)phenyl]-N,N′-diphenyl-9,9-dimethylfluorene-2,7-diamine (abbreviation: YGA2F), and 4,4′,4″-tris(carbazol-9-yl)triphenylamine (abbreviation: TCTA).

Other examples of the carbazole derivative include 9-[4-(9-phenyl-9H-carbazol-3-yl)phenyl]phenanthrene (abbreviation: PCPPn), 3-[4-(1-naphthyl)phenyl]-9-phenyl-9H-carbazole (abbreviation: PCPN), 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 1,3,5-tris[4-(N-carbazolyl)phenyl]benzene (abbreviation: TCPB), and 9-[4-(10-phenyl-9-anthracenyl)phenyl]-9H-carbazole (abbreviation: CzPA).

Specific examples of the furan derivative (an organic compound having a furan ring) include 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II).

Specific examples of the thiophene derivative (an organic compound having a thiophene ring) include organic compounds having a thiophene ring such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV).

Specific examples of the aromatic amine include 4,4′-bis[N-(1-naphthyl)-N-phenylamino]biphenyl (abbreviation: NPB or α-NPD), N,N-diphenyl-N,N-bis(3-methylphenyl)-4,4′-diaminobiphenyl (abbreviation: TPD), N,N-bis(9,9′-spirobi[9H-fluoren]-2-yl)-N,N-diphenyl-4-4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), N-(9,9-dimethyl-9H-fluoren-2-yl)-N-{9,9-dimethyl-2-[N-phenyl-N-(9,9-dimethyl-9H-fluoren-2-yl)amino]-9H-fluoren-7-yl}phenylamine (abbreviation: DFLADFL), N-(9,9-dimethyl-2-diphenylamino-9H-fluoren-7-yl)diphenylamine (abbreviation: DPNF), N-(9,9-spirobi[9H-fluoren]-2-yl)-N,N,N-triphenyl-1,4-phenyldiamine (abbreviation: DPASF), N,N-diphenyl-N,N-bis(4-diphenylaminophenyl)spirobi[9H-fluorene]-2,7-diamine (abbreviation: DPA2SF), 4,4′,4″-tris[N-(1-naphthyl)-N-phenylamino]triphenylamine (abbreviation: 1′-TNATA), 4,4′,4″-tris(N,N-diphenylamino)triphenylamine (abbreviation: TDATA), 4,4′,4″-tris[N-(3-methylphenyl)-N-phenylamino]triphenylamine (abbreviation: m-MTDATA), N,N-di(p-tolyl)-N,N-diphenyl-p-phenylenediamine (abbreviation: DTDPPA), 4,4′-bis[N-(4-diphenylaminophenyl)-N-phenylamino]biphenyl (abbreviation: DPAB), DNTPD, 1,3,5-tris[N-(4-diphenylaminophenyl)-N-phenylamino]benzene (abbreviation: DPA3B), N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)-triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-[4-(9-phenylfluoren-9-yl)phenyl]triphenylamine (abbreviation: BPAFLBi), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

Other examples of the hole-transport material include high-molecular compounds (e.g., oligomers, dendrimers, and polymers) such as poly(N-vinylcarbazole) (abbreviation: PVK), poly(4-vinyltriphenylamine) (abbreviation: PVTPA), poly[N-(4-{N-[4-(4-diphenylamino)phenyl]phenyl-N-phenylamino}phenyl)methacrylamide] (abbreviation: PTPDMA), and poly[N,N-bis(4-butylphenyl)-N,N-bis(phenyl)benzidine] (abbreviation: Poly-TPD). Alternatively, it is possible to use a high-molecular compound to which acid is added, such as poly(3,4-ethylenedioxythiophene)/polystyrenesulfonic acid (abbreviation: PEDOT/PSS) or polyaniline/polystyrenesulfonic acid (abbreviation: PAni/PSS), for example.

Note that the hole-transport material is not limited to the above examples, and any of a variety of known materials may be used alone or in combination as the hole-transport material.

The hole-injection layers (111, 111a, and 111b) can be formed by any of known film formation methods such as a vacuum evaporation method.

### <Hole-Transport Layer>

The hole-transport layers (112, 112a, and 112b) transport the holes, which are injected from the first electrodes 101 by the hole-injection layers (111, 111a, and 111b), to the light-emitting layers (113, 113a, and 113b). Note that the hole-transport layers (112, 112a, and 112b) each include a hole-transport material. Thus, the hole-transport layers (112, 112a, and 112b) can be formed using any of the hole-transport materials that can be used for the hole-injection layers (111, 111a, and 111b).

Note that in the light-emitting device of one embodiment of the present invention, the organic compound used for the hole-transport layers (112, 112a, and 112b) can also be used for the light-emitting layers (113, 113a, and 113b). The same organic compound is preferably used for the hole-transport layers (112, 112a, and 112b) and the light-emitting layers (113, 113a, and 113b), in which case holes can be efficiently transported from the hole-transport layers (112, 112a, and 112b) to the light-emitting layers (113, 113a, and 113b).

### <Electron-Blocking Layer>

The electron-blocking layer 116 is provided to prevent passing of electrons from the light-emitting layer 113 to the first electrode 101 side. A material having an excellent hole-transport property, a low electron-transport property, and a high LUMO level is suitable for the electron-blocking layer 116. Among the above-described substances that can be used as a material of the hole-transport layer 112, a material whose LUMO level is higher (preferably more than or equal to 0.30 eV higher) than that of a material (at least a host material) included in the light-emitting layer is preferably used to form the electron-blocking layer 116. Note that the electron-blocking layer, which transports holes, can also be regarded as part of the hole-transport layer 112.

### <Light-Emitting Layer>

The light-emitting layers (113, 113a, and 113b) include a light-emitting substance. Note that as a light-emitting substance that can be used in the light-emitting layers (113, 113a, and 113b), a substance whose emission color is blue, violet, bluish violet, green, yellowish green, yellow, orange, red, or the like can be used as appropriate. When a plurality of light-emitting layers are provided, the use of different light-emitting substances for the light-emitting layers enables exhibiting different emission colors (e.g., white light emission obtained by a combination of complementary emission colors). When a plurality of light-emitting layers are provided, the light-emitting layers can exhibit the same color. The structure in which a plurality of light-emitting layers that emit light of the same color are stacked can sometimes achieve higher reliability than a single-layer structure. Furthermore, one light-emitting layer may have a stacked-layer structure including different light-emitting substances.

The light-emitting layers (113, 113a, and 113b) may each include one or more kinds of organic compounds (e.g., a host material) in addition to a light-emitting substance (a guest material).

In the case where a plurality of host materials are used in the light-emitting layers (113, 113a, and 113b), a second host material that is additionally used is preferably a substance having a larger energy gap than those of a known guest material and a first host material. Preferably, the lowest singlet excitation energy level (Si level) of the second host material is higher than that of the first host material, and the lowest triplet excitation energy level (T1 level) of the second host material is higher than that of the guest material. Preferably, the lowest triplet excitation energy level (T1 level) of the second host material is higher than that of the first host material. With such a structure, an exciplex can be formed by the two kinds of host materials. To form an exciplex efficiently, it is particularly preferable to combine a compound that easily accepts holes (hole-transport material) and a compound that easily accepts electrons (electron-transport material). With the above structure, high efficiency, low voltage, and a long lifetime can be achieved at the same time.

As an organic compound used as the host material (including the first host material and the second host material), any of organic compounds such as the hole-transport materials usable for the hole-transport layers (112, 112a, and 112b) described above and electron-transport materials usable for electron-transport layers (114, 114a, and 114b) described later can be used as long as they satisfy requirements for the host material used in the light-emitting layer. Another example is an exciplex formed by two or more kinds of organic compounds (the first host material and the second host material). An exciplex whose excited state is formed by two or more kinds of organic compounds has an extremely small difference between the S1 level and the T1 level and functions as a thermally activated delayed fluorescent (TADF) material capable of converting triplet excitation energy into singlet excitation energy. In an example of a preferable combination of two or more kinds of organic compounds forming an exciplex, one compound of the two or more kinds of organic compounds has a π-electron deficient heteroaromatic ring and the other compound has a π-electron rich heteroaromatic ring. A phosphorescent substance such as an iridium-, rhodium-, or platinum-based organometallic complex or a metal complex may be used as one compound of the combination for forming an exciplex.

There is no particular limitation on the light-emitting substances that can be used for the light-emitting layers (113, 113a, and 113b), and a light-emitting substance that converts singlet excitation energy into light in the visible light range or a light-emitting substance that converts triplet excitation energy into light in the visible light range can be used.

<<Light-Emitting Substance that Converts Singlet Excitation Energy into Light>>

The following substances that emit fluorescent light (fluorescent substances) can be given as examples of the light-emitting substance that converts singlet excitation energy into light and can be used in the light-emitting layers (113, 113a, and 113b): a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative. A pyrene derivative is particularly preferable because it has a high emission quantum yield. Specific examples of the pyrene derivative include N,N-bis(3-methylphenyl)-N,N-bis[3-(9-phenyl-9H-fluoren-9-yl)phenyl]pyrene-1,6-diamine (abbreviation: 1,6mMemFLPAPrn), N,N-diphenyl-N,N-bis[4-(9-phenyl-9H-fluoren-9-yl)phenyl]pyrene-1,6-diamine (abbreviation: 1,6FLPAPrn), N,N-bis(dibenzofuran-2-yl)-N,N-diphenylpyrene-1,6-diamine (abbreviation: 1,6FrAPrn), N,N-bis(dibenzothiophen-2-yl)-N,N-diphenylpyrene-1,6-diamine (abbreviation: 1,6ThAPrn), N,N-(pyrene-1,6-diyl)bis[(N-phenylbenzo[b]naphtho[1,2-d]furan)-6-amine] (abbreviation: 1,6BnfAPrn), N,N-(pyrene-1,6-diyl)bis[(N-phenylbenzo[b]naphtho[1,2-d]furan)-8-amine] (abbreviation: 1,6BnfAPrn-02), and N,N-(pyrene-1,6-diyl)bis[(6,N-diphenylbenzo[b]naphtho[1,2-d]furan)-8-amine] (abbreviation: 1,6BnfAPrn-03).

In addition, it is possible to use, for example, 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-bis[4-(9H-carbazol-9-yl)phenyl]-N,N-diphenyl-4,4′-stilbenediamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), 4-(10-phenyl-9-anthryl)-4′-(9-phenyl-9H-carbazol-3-yl)triphenylamine (abbreviation: PCBAPA), 4-[4-(10-phenyl-9-anthryl)phenyl]-4′-(9-phenyl-9H-carbazol-3-yl)triphenylamine (abbreviation: PCBAPBA), perylene, 2,5,8,11-tetra-tert-butylperylene (abbreviation: TBP), N,N′-(2-tert-butylanthracene-9,10-diyldi-4,1-phenylene)bis(N,N,N-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), or N-[4-(9,10-diphenyl-2-anthryl)phenyl]-N,N,N-triphenyl-1,4-phenylenediamine (abbreviation: 2DPAPPA).

It is also possible to use, for example, N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N,N-triphenyl-1,4-phenylenediamine (abbreviation: 2DPAPA), N-[9,10-bis(biphenyl-2-yl)-2-anthryl]-N,N,N-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N,N-tetrakis(4-methylphenyl)tetracene-5,11-diamine (abbreviation: p-mPhTD), 7,14-diphenyl-N,N,N,N-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), 1,6BnfAPrn-03, 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), or 3,10-bis[N-(dibenzofuran-3-yl)-N-phenylamino]naphtho[2,3-b;6,7-b′]bisbenzofuran (abbreviation: 3,10FrA2Nbf(IV)-02). In particular, a pyrenediamine compound such as 1,6FLPAPrn, 1,6mMemFLPAPrn, or 1,6BnfAPm-03 can be used, for example.

<<Light-Emitting Substance that Converts Triplet Excitation Energy into Light>>

Examples of the light-emitting substance that converts triplet excitation energy into light and can be used in the light-emitting layer 113 include substances that emit phosphorescent light (phosphorescent substances) and TADF materials that exhibit thermally activated delayed fluorescence.

A phosphorescent substance is a compound that emits phosphorescent light but does not emit fluorescent light at a temperature higher than or equal to a low temperature (e.g., 77 K) and lower than or equal to room temperature (i.e., higher than or equal to 77 K and lower than or equal to 313 K). The phosphorescent substance preferably contains a metal element with large spin-orbit interaction, and can be an organometallic complex, a metal complex (platinum complex), or a rare earth metal complex, for example. Specifically, the phosphorescent substance preferably contains a transition metal element. It is preferable that the phosphorescent substance contain a platinum group element (ruthenium (Ru), rhodium (Rh), palladium (Pd), osmium (Os), iridium (Ir), or platinum (Pt)), especially iridium, in which case the probability of direct transition between the singlet ground state and the triplet excited state can be increased.

<<Phosphorescent Substance (from 450 nm to 570 nm: Blue or Green)>>

As examples of a phosphorescent substance which emits blue or green light and whose emission spectrum has a peak wavelength greater than or equal to 450 nm and less than or equal to 570 nm, the following substances can be given.

Examples include organometallic complexes having a 4H-triazole ring, such as tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), tris[4-(3-biphenyl)-5-isopropyl-3-phenyl-4H-1,2,4-triazolato]iridium(III) (abbreviation: [Ir(iPrptz-3b)₃]), and tris[3-(5-biphenyl)-5-isopropyl-4-phenyl-4H-1,2,4-triazolato]iridium(III) (abbreviation: [Ir(iPr5btz)₃]); organometallic complexes having a 1H-triazole ring, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(III) (abbreviation: [Ir(Prptz1-Me)₃]); organometallic complexes having an imidazole ring, such as fac-tris[1-(2,6-diisopropylphenyl)-2-phenyl-1H-imidazole]iridium(III) (abbreviation: [Ir(iPrpim)₃]) and tris[3-(2,6-dimethylphenyl)-7-methylimidazo[1,2-f]phenanthridinato]iridium(III) (abbreviation: [Ir(dmpimpt-Me)₃]); and organometallic complexes in which a phenylpyridine derivative having an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), and bis[2-(4′,6′-difluorophenyl)pyridinato-N,C²′]iridium(III) acetylacetonate (abbreviation: FIr(acac)).

<<Phosphorescent Substance (from 495 nm to 590 nm: Green or Yellow)>>

As examples of a phosphorescent substance which emits green or yellow light and whose emission spectrum has a peak wavelength greater than or equal to 495 nm and less than or equal to 590 nm, the following substances can be given.

Examples of the phosphorescent substance include organometallic iridium complexes having a pyrimidine ring, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), (acetylacetonato)bis{4,6-dimethyl-2-[6-(2,6-dimethylphenyl)-4-pyrimidinyl-κN³]phenyl-κC}iridium(III) (abbreviation: [Ir(dmppm-dmp)₂(acac)]), and (acetylacetonato)bis(4,6-diphenylpyrimidinato)iridium(III) (abbreviation: [Ir(dppm)₂(acac)]); organometallic iridium complexes having a pyrazine ring, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes having a pyridine ring, such as tris(2-phenylpyridinato-N,C^{2′})iridium(III) (abbreviation: [Ir(ppy)₃]), bis(2-phenylpyridinato-N,C²′)iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C²′)iridium(III) (abbreviation: [Ir(pq)₃]), bis(2-phenylquinolinato-N,C^{2′})iridium(III) acetylacetonate (abbreviation: [Ir(pq)₂(acac)]), bis[2-(2-pyridinyl-κN)phenyl-KC][2-(4-phenyl-2-pyridinyl-κN)phenyl-κC]iridium(III) (abbreviation: [Ir(ppy)₂(4dppy)]), bis[2-(2-pyridinyl-κN)phenyl-κC][2-(4-methyl-5-phenyl-2-pyridinyl-κN)phenyl-κC], [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: [Ir(5mppy-d3)₂(mbfpypy-d3)]), {2-(methyl-d₃)-8-[4-(1-methylethyl-1-d)-2-pyridinyl-κN]benzofuro[2,3-b]pyridin-7-yl-κC}bis{5-(methyl-d)-2-[5-(methyl-d₃)-2-pyridinyl-κN]phenyl-κC}iridium(III) (abbreviation: Ir(5mtpy-d6)₂(mbfpypy-iPr-d4)), [2-d₃-methyl-(2-pyridinyl-κN)benzofuro[2,3-b]pyridine-κC]bis[2-(2-pyridinyl-κN)phenyl-κC]iridium(III) (abbreviation: Ir(ppy)₂(mbfpypy-d3)), and [2-(4-methyl-5-phenyl-2-pyridinyl-κN)phenyl-κC]bis[2-(2-pyridinyl-κN)phenyl-κC]iridium(III) (abbreviation: Ir(ppy)₂(mdppy)); organometallic complexes such as bis(2,4-diphenyl-1,3-oxazolato-N,C^{2′})iridium(III) acetylacetonate (abbreviation: [Ir(dpo)₂(acac)]), bis{2-[4′-(perfluorophenyl)phenyl]pyridinato-N,C²′}iridium(III) acetylacetonate (abbreviation: [Ir(p-PF-ph)₂(acac)]), and bis(2-phenylbenzothiazolato-N,C^{2′})iridium(III) acetylacetonate (abbreviation: [Ir(bt)₂(acac)]); and a rare earth metal complex such as tris(acetylacetonato)(monophenanthroline)terbium(III) (abbreviation: [Tb(acac)₃(Phen)]).

<<Phosphorescent Substance (from 570 nm to 750 nm: Yellow or Red)>>

As examples of a phosphorescent substance which emits yellow or red light and whose emission spectrum has a peak wavelength greater than or equal to 570 nm and less than or equal to 750 nm, the following substances can be given.

Examples of the phosphorescent substance include organometallic complexes having a pyrimidine ring, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and (dipivaloylmethanato)bis[4,6-di(naphthalen-1-yl)pyrimidinato]iridium(III) (abbreviation: [Ir(d1npm)₂(dpm)]); organometallic complexes having a pyrazine ring, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), bis{4,6-dimethyl-2-[3-(3,5-dimethylphenyl)-5-phenyl-2-pyrazinyl-κN]phenyl-κC}(2,6-dimethyl-3,5-heptanedionato-κ²O,O′)iridium(III) (abbreviation: [Ir(dmdppr-P)₂(dibm)]), bis{4,6-dimethyl-2-[5-(4-cyano-2,6-dimethylphenyl)-3-(3,5-dimethylphenyl)-2-pyrazinyl-κN]phenyl-κC}(2,2,6,6-tetramethyl-3,5-heptanedionato-κ²O,O′)iridium(III) (abbreviation: [Ir(dmdppr-dmCP)₂(dpm)]), bis{2-[5-(2,6-dimethylphenyl)-3-(3,5-dimethylphenyl)-2-pyrazinyl-κN]-4,6-dimethylphenyl-κC}(2,2′,6,6′-tetramethyl-3,5-heptanedionato-κ²O,O′)iridium(III) (abbreviation: [Ir(dmdppr-dmp)₂(dpm)]), (acetylacetonato)bis(2-methyl-3-phenylquinoxalinato-N,C²′)iridium(III) (abbreviation: [Ir(mpq)₂(acac)]), (acetylacetonato)bis(2,3-diphenylquinoxalinato-N,C^{2′})iridium(III) (abbreviation: [Ir(dpq)₂(acac)]), and (acetylacetonato)bis[2,3-bis(4-fluorophenyl)quinoxalinato]iridium(III) (abbreviation: [Ir(Fdpq)₂(acac)]); organometallic complexes having a pyridine ring, such as tris(1-phenylisoquinolinato-N,C^{2′})iridium(III) (abbreviation: [Ir(piq)₃]), bis(1-phenylisoquinolinato-N,C²′)iridium(III) acetylacetonate (abbreviation: [Ir(piq)₂(acac)]), and bis[4,6-dimethyl-2-(2-quinolinyl-κN)phenyl-κC](2,4-pentanedionato-κ²O,O′)iridium(III) (abbreviation: [Ir(dmpqn)₂(acac)]); a platinum complex such as 2,3,7,8,12,13,17,18-octaethyl-21H,23H-porphyrin platinum(II) (abbreviation: [PtOEP]); and rare earth metal complexes such as tris(1,3-diphenyl-1,3-propanedionato)(monophenanthroline)europium(III) (abbreviation: [Eu(DBM)₃(Phen)]) and tris[1-(2-thenoyl)-3,3,3-trifluoroacetonato](monophenanthroline)europium(III) (abbreviation: [Eu(TTA)₃(Phen)]).

### <<TADF Material>>

Any of materials described below can be used as the TADF material. The TADF material is a material that has a small difference between its S1 and T1 levels (preferably less than or equal to 0.20 eV), enables up-conversion of a triplet excited state into a singlet excited state (i.e., reverse intersystem crossing) using a little thermal energy, and efficiently exhibits light (fluorescent light) from the singlet excited state. The thermally activated delayed fluorescence is efficiently obtained under the condition where the difference in energy between the triplet excitation energy level and the singlet excitation energy level is greater than or equal to 0.00 eV and less than or equal to 0.20 eV, preferably greater than or equal to 0.00 eV and less than or equal to 0.10 eV. Delayed fluorescent light by the TADF material refers to light emission having a spectrum similar to that of normal fluorescent light and an extremely long lifetime. The lifetime is longer than or equal to 1×10⁻⁶ seconds, or longer than or equal to 1×10⁻³ seconds.

Note that the TADF material can be also used as an electron-transport material, a hole-transport material, or a host material.

Examples of the TADF material include fullerene, a derivative thereof, an acridine derivative such as proflavine, and eosin. Other examples thereof include a metal-containing porphyrin such as a porphyrin containing magnesium (Mg), zinc (Zn), cadmium (Cd), tin (Sn), platinum (Pt), indium (In), or palladium (Pd). Examples of the metal-containing porphyrin include a protoporphyrin-tin fluoride complex (abbreviation: SnF₂(Proto IX)), a mesoporphyrin-tin fluoride complex (abbreviation: SnF₂(Meso IX)), a hematoporphyrin-tin fluoride complex (abbreviation: SnF₂(Hemato IX)), a coproporphyrin tetramethyl ester-tin fluoride complex (abbreviation: SnF₂(Copro III-4Me)), an octaethylporphyrin-tin fluoride complex (abbreviation: SnF₂(OEP)), an etioporphyrin-tin fluoride complex (abbreviation: SnF₂(Etio I)), and an octaethylporphyrin-platinum chloride complex (abbreviation: PtCl₂OEP).

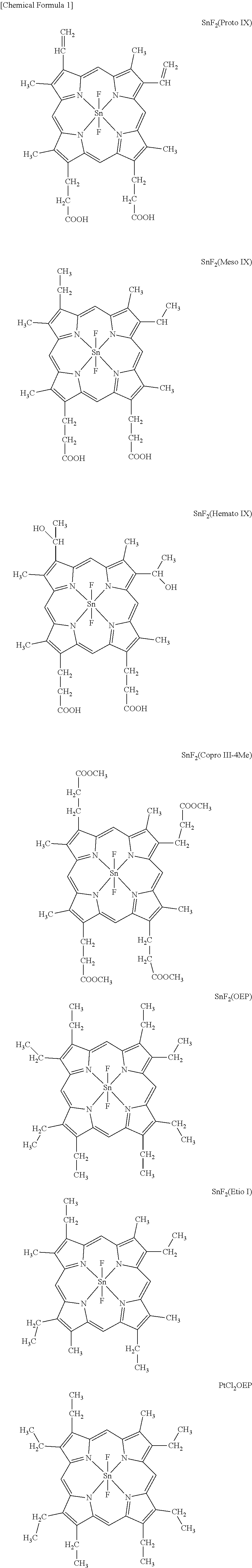

Additionally, a heteroaromatic compound having a π-electron rich heteroaromatic compound and a π-electron deficient heteroaromatic compound, such as 2-(biphenyl-4-yl)-4,6-bis(12-phenylindolo[2,3-a]carbazol-11-yl)-1,3,5-triazine (abbreviation: PIC-TRZ), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), 10-phenyl-10H,10′H-spiro[acridin-9,9′-anthracen]-10′-one (abbreviation: ACRSA), 4-(9′-phenyl-3,3′-bi-9H-carbazol-9-yl)benzofuro[3,2-d]pyrimidine (abbreviation: 4PCCzBfpm), 4-[4-(9′-phenyl-3,3′-bi-9H-carbazol-9-yl)phenyl]benzofuro[3,2-d]pyrimidine (abbreviation: 4PCCzPBfpm), or 9-[3-(4,6-diphenyl-1,3,5-triazin-2-yl)phenyl]-9′-phenyl-2,3′-bi-9H-carbazole (abbreviation: mPCCzPTzn-02) may be used.

Note that a substance in which a π-electron rich heteroaromatic compound is directly bonded to a π-electron deficient heteroaromatic compound is particularly preferable because both the donor property of the π-electron rich heteroaromatic compound and the acceptor property of the π-electron deficient heteroaromatic compound are enhanced and the energy difference between the singlet excited state and the triplet excited state becomes small. As the TADF material, a TADF material in which the singlet and triplet excited states are in thermal equilibrium (TADF100) may be used. Since such a TADF material enables a short emission lifetime (excitation lifetime), the efficiency of a light-emitting device in a high-luminance region can be less likely to decrease.

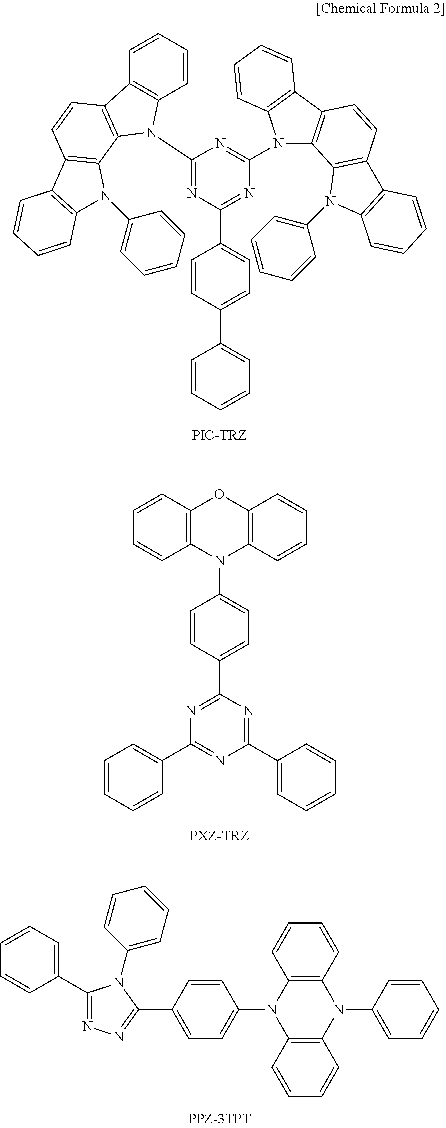 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1]

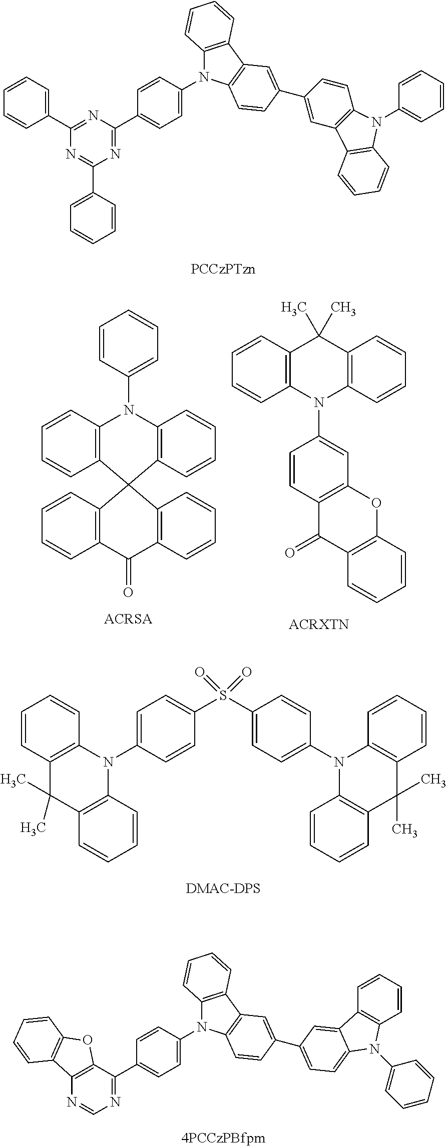

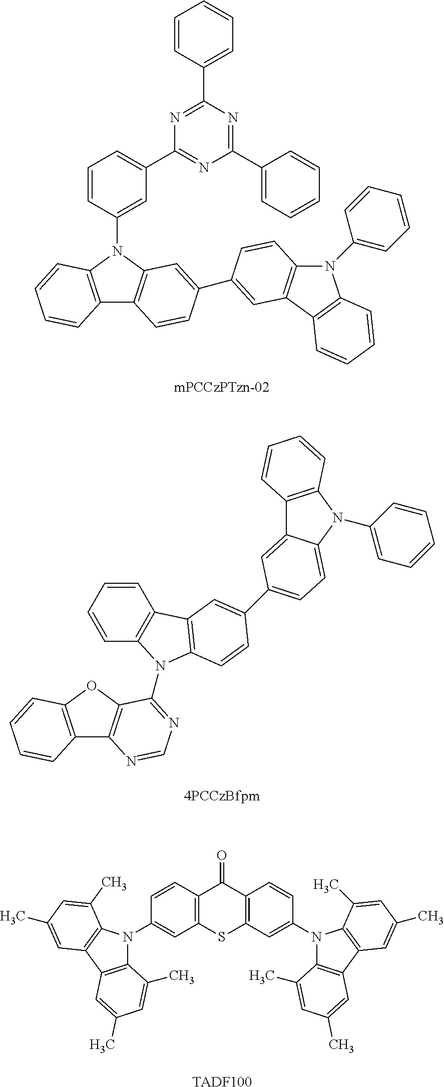

In addition to the above, another example of a material having a function of converting triplet excitation energy into light is a nano-structure of a transition metal compound having a perovskite structure. In particular, a nano-structure of a metal halide perovskite material is preferable. The nano-structure is preferably a nanoparticle or a nanorod.

As the organic compound (e.g., the host material) used in combination with the above-described light-emitting substance (guest material) in the light-emitting layers (113, 113a, 113b, and 113c), one or more selected from substances having a larger energy gap than the light-emitting substance (guest material) can be used.

### <<Host Material for Fluorescence>>

In the case where the light-emitting substance used in the light-emitting layers (113, 113a, 113b, and 113c) is a fluorescent substance, an organic compound (host material) used in combination with the fluorescent substance is preferably an organic compound that has a high energy level in a singlet excited state and has a low energy level in a triplet excited state or an organic compound having a high fluorescence quantum yield. Thus, the hole-transport material (described above) and the electron-transport material (described below) shown in this embodiment, for example, can be used as long as they are organic compounds that satisfy such a condition.

In terms of a preferable combination with the light-emitting substance (fluorescent substance), examples of the organic compound (host material), some of which overlap the above specific examples, include fused polycyclic aromatic compounds such as an anthracene derivative, a tetracene derivative, a phenanthrene derivative, a pyrene derivative, a chrysene derivative, and a dibenzo[g,p]chrysene derivative.

Specific examples of the organic compound (host material) that is preferably used in combination with the fluorescent substance include 9-phenyl-3-[4-(10-phenyl-9-anthryl)phenyl]-9H-carbazole (abbreviation: PCzPA), 3,6-diphenyl-9-[4-(10-phenyl-9-anthryl)phenyl]-9H-carbazole (abbreviation: DPCzPA), 3-[4-(1-naphthyl)phenyl]-9-phenyl-9H-carbazole (abbreviation: PCPN), 9,10-diphenylanthracene (abbreviation: DPAnth), N,N-diphenyl-9-[4-(10-phenyl-9-anthryl)phenyl]-9H-carbazol-3-amine (abbreviation: CzA1PA), 4-(10-phenyl-9-anthryl)triphenylamine (abbreviation: DPhPA), YGAPA, PCAPA, N,9-diphenyl-N-{4-[4-(10-phenyl-9-anthryl)phenyl]phenyl}-9H-carbazol-3-amine (abbreviation: PCAPBA), N-(9,10-diphenyl-2-anthryl)-N,9-diphenyl-9H-carbazol-3-amine (abbreviation: 2PCAPA), 6,12-dimethoxy-5,11-diphenylchrysene, N,N,N,N,N″,N″,N″,N″-octaphenyldibenzo[g,p]chrysene-2,7,10,15-tetraamine (abbreviation: DBC1), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4′-(9-phenyl-9H-fluoren-9-yl)biphenyl-4-yl]anthracene (abbreviation: FLPPA), 9,10-bis(3,5-diphenylphenyl)anthracene (abbreviation: DPPA), 9,10-di(2-naphthyl)anthracene (abbreviation: DNA), 2-tert-butyl-9,10-di(2-naphthyl)anthracene (abbreviation: t-BuDNA), 9-(1-naphthyl)-10-(2-naphthyl)anthracene (abbreviation: α,β-ADN), 2-(10-phenylanthracen-9-yl)dibenzofuran, 2-(10-phenyl-9-anthracenyl)benzo[b]naphtho[2,3-d]furan (abbreviation: Bnf(II)PhA), 9-(1-naphthyl)-10-[4-(2-naphthyl)phenyl]anthracene (abbreviation: αN-βNPAnth), 2,9-di(1-naphthyl)-10-phenylanthracene (abbreviation: 2αN-αNPhA), 9-(1-naphthyl)-10-[3-(1-naphthyl)phenyl]anthracene (abbreviation: αN-mαNPAnth), 9-(2-naphthyl)-10-[3-(1-naphthyl)phenyl]anthracene (abbreviation: βN-mαNPAnth), 9-(1-naphthyl)-10-[4-(1-naphthyl)phenyl]anthracene (abbreviation: αN-αNPAnth), 9-(2-naphthyl)-10-[4-(2-naphthyl)phenyl]anthracene (abbreviation: βN-βNPAnth), 2-(1-naphthyl)-9-(2-naphthyl)-10-phenylanthracene (abbreviation: 2αN-βNPhA), 9-(2-naphthyl)-10-[3-(2-naphthyl)phenyl]anthracene (abbreviation: βN-mβNPAnth), 1-{4-[10-(biphenyl-4-yl)-9-anthracenyl]phenyl}-2-ethyl-1H-benzimidazole (abbreviation: EtBImPBPhA), 9,9′-bianthryl (abbreviation: BANT), 9,9′-(stilbene-3,3′-diyl)diphenanthrene (abbreviation: DPNS), 9,9′-(stilbene-4,4′-diyl)diphenanthrene (abbreviation: DPNS2), 1,3,5-tri(1-pyrenyl)benzene (abbreviation: TPB3), 5,12-diphenyltetracene, and 5,12-bis(biphenyl-2-yl)tetracene.

### <<Host Material for Phosphorescence>>

In the case where the light-emitting substance used in the light-emitting layers (113, 113a, 113b, and 113c) is a phosphorescent substance, an organic compound having triplet excitation energy (an energy difference between a ground state and a triplet excited state) which is higher than that of the light-emitting substance may be selected as the organic compound (host material) used in combination with the phosphorescent substance. Note that when a plurality of organic compounds (e.g., a first host material and a second host material (or an assist material)) are used in combination with a light-emitting substance to form an exciplex, the plurality of organic compounds are preferably mixed with the phosphorescent substance.

With such a structure, light emission can be efficiently obtained by exciplex-triplet energy transfer (ExTET), which is energy transfer from an exciplex to a light-emitting substance. Note that a combination of the plurality of organic compounds that easily forms an exciplex is preferable, and it is particularly preferable to combine a compound that easily accepts holes (hole-transport material) and a compound that easily accepts electrons (electron-transport material).

In terms of a preferable combination with the light-emitting substance (phosphorescent substance), examples of the organic compounds (the host material and the assist material), some of which overlap the above specific examples, include an aromatic amine (an organic compound having an aromatic amine skeleton), a carbazole derivative (an organic compound having a carbazole ring), a dibenzothiophene derivative (an organic compound having a dibenzothiophene ring), a dibenzofuran derivative (an organic compound having a dibenzofuran ring), an oxadiazole derivative (an organic compound having an oxadiazole ring), a triazole derivative (an organic compound having an triazole ring), a benzimidazole derivative (an organic compound having an benzimidazole ring), a quinoxaline derivative (an organic compound having a quinoxaline ring), a dibenzoquinoxaline derivative (an organic compound having a dibenzoquinoxaline ring), a pyrimidine derivative (an organic compound having a pyrimidine ring), a triazine derivative (an organic compound having a triazine ring), a pyridine derivative (an organic compound having a pyridine ring), a bipyridine derivative (an organic compound having a bipyridine ring), a phenanthroline derivative (an organic compound having a phenanthroline ring), a furodiazine derivative (an organic compound having a furodiazine ring), and zinc- or aluminum-based metal complexes.

Among the above organic compounds, specific examples of the aromatic amine and the carbazole derivative, which are organic compounds having a high hole-transport property, are the same as the specific examples of the hole-transport materials described above, and those materials are preferable as the host material.

Among the above organic compounds, specific examples of the dibenzothiophene derivative and the dibenzofuran derivative, which are organic compounds having a high hole-transport property, include 4-{3-[3-(9-phenyl-9H-fluoren-9-yl)phenyl]phenyl}dibenzofuran (abbreviation: mmDBFFLBi-II), 4,4′,4″-(benzene-1,3,5-triyl)tri(dibenzofuran) (abbreviation: DBF3P-II), DBT3P-II, 2,8-diphenyl-4-[4-(9-phenyl-9H-fluoren-9-yl)phenyl]dibenzothiophene (abbreviation: DBTFLP-III), 4-[4-(9-phenyl-9H-fluoren-9-yl)phenyl]-6-phenyldibenzothiophene (abbreviation: DBTFLP-IV), and 4-[3-(triphenylen-2-yl)phenyl]dibenzothiophene (abbreviation: mDBTPTp-II). These derivatives are preferable as the host material.

Other examples of preferable host materials include metal complexes having an oxazole-based or thiazole-based ligand, such as bis[2-(2-benzoxazolyl)phenolato]zinc(II) (abbreviation: ZnPBO) and bis[2-(2-benzothiazolyl)phenolato]zinc(II) (abbreviation: ZnBTZ).

Among the above organic compounds, specific examples of the oxadiazole derivative, the triazole derivative, the benzimidazole derivative, the quinoxaline derivative, the dibenzoquinoxaline derivative, the quinazoline derivative, and the phenanthroline derivative, which are organic compounds having a high electron-transport property, include an organic compound including a heteroaromatic ring having a polyazole ring such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 3-(4-biphenylyl)-4-phenyl-5-(4-tert-butylphenyl)-1,2,4-triazole (abbreviation: TAZ), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOs); an organic compound including a heteroaromatic ring having a phenanthroline ring such as bathophenanthroline (abbreviation: Bphen), bathocuproine (abbreviation: BCP), 2,9-di(naphthalen-2-yl)-4,7-diphenyl-1,10-phenanthroline (abbreviation: NBphen), or 2,2′-(1,3-phenylene)bis(9-phenyl-1,10-phenanthroline) (abbreviation: mPPhen2P); and an organic compound including a heteroaromatic ring having a dibenzoquinoxaline ring such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 2-{4-[9,10-di(2-naphthyl)-2-anthryl]phenyl}-1-phenyl-1H-benzimidazole (abbreviation: ZADN), or 2-4′-(9-phenyl-9H-carbazol-3-yl)-3,1′-biphenyl-1-yl]dibenzo[f,h]quinoxaline (abbreviation: 2mpPCBPDBq). These organic compounds are preferable as the host material.

Among the above organic compounds, specific examples of the pyridine derivative, the diazine derivative (e.g., the pyrimidine derivative, the pyrazine derivative, and the pyridazine derivative), the triazine derivative, and the furodiazine derivative, which are organic compounds having a high electron-transport property, include organic compounds including a heteroaromatic ring having a diazine ring such as 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), 9,9′-[pyrimidine-4,6-diylbis(biphenyl-3,3′-diyl)]bis(9H-carbazole) (abbreviation: 4,6mCzBP2Pm), 2-[3′-(9,9-dimethyl-9H-fluoren-2-yl)biphenyl-3-yl]-4,6-diphenyl-1,3,5-triazine (abbreviation: mFBPTzn), 8-(biphenyl-4-yl)-4-[3-(dibenzothiophen-4-yl)phenyl]-[1]benzofuro[3,2-d]pyrimidine (abbreviation: 8BP-4mDBtPBfpm), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 11-[3′-(dibenzothiophen-4-yl)biphenyl-3-yl]phenanthro[9′,10′:4,5]furo[2,3-b]pyrazine (abbreviation: 11mDBtBPPnfpr), 11-[3′-(dibenzothiophen-4-yl)biphenyl-4-yl]phenanthro[9′,10′:4,5]furo[2,3-b]pyrazine, 11-[3′-(9H-carbazol-9-yl)biphenyl-3-yl]phenanthro[9′,10′:4,5]furo[2,3-b]pyrazine, 12-(9′-phenyl-3,3′-bi-9H-carbazol-9-yl)phenanthro[9′,10′:4,5]furo[2,3-b]pyrazine (abbreviation: 12PCCzPnfpr), 9-[3′-(9-phenyl-9H-carbazol-3-yl)biphenyl-4-yl]naphtho[1′,2′:4,5]furo[2,3-b]pyrazine (abbreviation: 9pmPCBPNfpr), 9-(9′-phenyl-3,3′-bi-9H-carbazol-9-yl)naphtho[1′,2′:4,5]furo[2,3-b]pyrazine (abbreviation: 9PCCzNfpr), 10-(9′-phenyl-3,3′-bi-9H-carbazol-9-yl)naphtho[1′,2′:4,5]furo[2,3-b]pyrazine (abbreviation: 10PCCzNfpr), 9-[3′-(6-phenylbenzo[b]naphtho[1,2-d]furan-8-yl)biphenyl-3-yl]naphtho[1′,2′:4,5]furo[2,3-b]pyrazine (abbreviation: 9mBnfBPNfpr), 9-{3-[6-(9,9-dimethylfluoren-2-yl)dibenzothiophen-4-yl]phenyl}naphtho[1′,2′:4,5]furo[2,3-b]pyrazine (abbreviation: 9mFDBtPNfpr), 9-[3′-(6-phenyldibenzothiophen-4-yl)biphenyl-3-yl]naphtho[1′,2′:4,5]furo[2,3-b]pyrazine (abbreviation: 9mDBtBPNfpr-02), 9-[3-(9′-phenyl-3,3′-bi-9H-carbazol-9-yl)phenyl]naphtho[1′,2′:4,5]furo[2,3-b]pyrazine (abbreviation: 9mPCCzPNfpr), 9-[3′-(2,8-diphenyldibenzothiophen-4-yl)biphenyl-3-yl]naphtho[1′,2′:4,5]furo[2,3-b]pyrazine, 11-[3′-(2,8-diphenyldibenzothiophen-4-yl)biphenyl-3-yl]phenanthro[9′,10′:4,5]furo[2,3-b]pyrazine, 5-[3-(4,6-diphenyl-1,3,5-triazin-2-yl)phenyl]-7,7-dimethyl-5H,7H-indeno[2,1-b]carbazole (abbreviation: mINc(II)PTzn), 2-[3′-(triphenylen-2-yl)biphenyl-3-yl]-4,6-diphenyl-1,3,5-triazine (abbreviation: mTpBPTzn), 2-(biphenyl-4-yl)-4-phenyl-6-(9,9′-spirobi[9H-fluoren]-2-yl)-1,3,5-triazine (abbreviation: BP-SFTzn), 2,6-bis(4-naphthalen-1-ylphenyl)-4-[4-(3-pyridyl)phenyl]pyrimidine (abbreviation: 2,4NP-6PyPPm), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn), 6-(biphenyl-3-yl)-4-[3,5-bis(9H-carbazol-9-yl)phenyl)-2-phenylpyrimidine (abbreviation: 6mBP-4Cz2PPm), and 4-[3,5-bis(9H-carbazol-9-yl)phenyl]-2-phenyl-6-(biphenyl-4-yl)pyrimidine (abbreviation: 6BP-4Cz2PPm), and those materials are preferable as the host material.

Among the above organic compounds, specific examples of metal complexes that are organic compounds having a high electron-transport property include zinc- or aluminum-based metal complexes, such as tris(8-quinolinolato)aluminum(III) (abbreviation: Alq), tris(4-methyl-8-quinolinolato)aluminum(III) (abbreviation: Almq₃), bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), and bis(8-quinolinolato)zinc(II) (abbreviation: Znq), and metal complexes having a quinoline ring or a benzoquinoline ring. These metal complexes are preferable as the host material.

Moreover, high-molecular compounds such as poly(2,5-pyridinediyl) (abbreviation: PPy), poly [(9,9-dihexylfluorene-2,7-diyl)-co-(pyridine-3,5-diyl)] (abbreviation: PF-Py), and poly[(9,9-dioctylfluorene-2,7-diyl)-co-(2,2′-bipyridine-6,6′-diyl)] (abbreviation: PF-BPy) are preferable as the host material.

Furthermore, the following organic compounds with a diazine ring, which have a bipolar property, a high hole-transport property, and a high electron-transport property, can be used as the host material: 9-phenyl-9′-(4-phenyl-2-quinazolinyl)-3,3′-bi-9H-carbazole (abbreviation: PCCzQz), 2-[4′-(9-phenyl-9H-carbazol-3-yl)-3,1′-biphenyl-1-yl]dibenzo[f,h]quinoxaline (abbreviation: 2mpPCBPDBq), 5-[3-(4,6-diphenyl-1,3,5-triazin-2-yl)phenyl]-7,7-dimethyl-5H,7H-indeno[2,1-b]carbazole (abbreviation: mINc(II)PTzn), 11-[4-(biphenyl-4-yl)-6-phenyl-1,3,5-triazin-2-yl]-11,12-dihydro-12-phenyl-indolo[2,3-a]carbazole (abbreviation: BP-Icz(II)Tzn), and 7-[4-(9-phenyl-9H-carbazol-2-yl)quinazolin-2-yl]-7H-dibenzo[c,g]carbazole (abbreviation: PC-cgDBCzQz).

### <Hole-Blocking Layer>

The hole-blocking layer 117 is provided to prevent passing of holes from the light-emitting layer 113 to the second electrode 102 side. A material having an excellent electron-transport property, a low hole-transport property, and a deep HOMO level is suitable for the hole-blocking layer 117. Among later-described substances that can be used as a material of the electron-transport layer 114, a material whose HOMO level is lower (preferably more than or equal to 0.30 eV lower) than that of a material (at least a host material) included in the light-emitting layer is preferably used to form the hole-blocking layer 117. Note that the hole-blocking layer, which transports electrons, can also be regarded as part of the electron-transport layer 114.

### <Electron-Transport Layer>

The electron-transport layers (114, 114a, and 114b) transport the electrons, which are injected from the second electrode 102 and the charge-generation layers (106, 106a, and 106b) by the electron-injection layers (115, 115a, and 115b) described later, to the light-emitting layers (113, 113a, and 113b). The heat resistance of the light-emitting device of one embodiment of the present invention can be improved by including the stacked electron-transport layers. The electron-transport material used in the electron-transport layers (114, 114a, and 114b) is preferably a substance having an electron mobility higher than or equal to 1×10⁻⁶ cm²/Vs in the case where the square root of the electric field strength [V/cm] is 600. Note that any other substance can also be used as long as the substance has an electron-transport property higher than a hole-transport property. The electron-transport layers (114, 114a, and 114b) can function even with a single-layer structure and may have a stacked-layer structure including two or more layers. When a photolithography process is performed over the electron-transport layer including the above-described mixed material, which has heat resistance, an adverse effect of the thermal process on the device characteristics can be reduced.

### <<Electron-Transport Material>>

As the electron-transport material that can be used for the electron-transport layers (114, 114a, and 114b), an organic compound having a high electron-transport property can be used, and for example, a heteroaromatic compound can be used. The term heteroaromatic compound refers to a cyclic compound including at least two different kinds of elements in a ring. Examples of cyclic structures include a three-membered ring, a four-membered ring, a five-membered ring, a six-membered ring, and the like, among which a five-membered ring and a six-membered ring are particularly preferable. The elements included in the heteroaromatic compound are preferably one or more of nitrogen, oxygen, and sulfur, in addition to carbon. In particular, a heteroaromatic compound containing nitrogen (a nitrogen-containing heteroaromatic compound) is preferable, and any of materials having a high electron-transport property (electron-transport materials), such as a nitrogen-containing heteroaromatic compound and a π-electron deficient heteroaromatic compound including the nitrogen-containing heteroaromatic compound, is preferably used.

Note that the electron-transport material can be different from the materials used in the light-emitting layer. Not all excitons formed by recombination of carriers in the light-emitting layer can contribute to light emission and some excitons are diffused into a layer in contact with the light-emitting layer or a layer in the vicinity of the light-emitting layer. In order to avoid this phenomenon, the energy level (the lowest singlet excitation level or the lowest triplet excitation level) of a material used for the layer in contact with the light-emitting layer or the layer in the vicinity of the light-emitting layer is preferably higher than that of a material used for the light-emitting layer. Thus, when a material different from the material of the light-emitting layer is used as the electron-transport material, a device having high efficiency can be obtained.

The heteroaromatic compound is an organic compound including at least one heteroaromatic ring.

The heteroaromatic ring includes any one of a pyridine ring, a diazine ring, a triazine ring, a polyazole ring, an oxazole ring, a thiazole ring, and the like. A heteroaromatic ring having a diazine ring includes a heteroaromatic ring having a pyrimidine ring, a pyrazine ring, a pyridazine ring, or the like. A heteroaromatic ring having a polyazole ring includes a heteroaromatic ring having an imidazole ring, a triazole ring, or an oxadiazole ring.

The heteroaromatic ring includes a fused heteroaromatic ring having a fused ring structure. Examples of the fused heteroaromatic ring include a quinoline ring, a benzoquinoline ring, a quinoxaline ring, a dibenzoquinoxaline ring, a quinazoline ring, a benzoquinazoline ring, a dibenzoquinazoline ring, a phenanthroline ring, a furodiazine ring, and a benzimidazole ring.

Examples of the heteroaromatic compound having a five-membered ring structure, which is a heteroaromatic compound containing carbon and one or more of nitrogen, oxygen, and sulfur, include a heteroaromatic compound having an imidazole ring, a heteroaromatic compound having a triazole ring, a heteroaromatic compound having an oxazole ring, a heteroaromatic compound having an oxadiazole ring, a heteroaromatic compound having a thiazole ring, and a heteroaromatic compound having a benzimidazole ring.

Examples of the heteroaromatic compound having a six-membered ring structure, which is a heteroaromatic compound containing carbon and one or more of nitrogen, oxygen, and sulfur, include a heteroaromatic compound having a heteroaromatic ring, such as a pyridine ring, a diazine ring (a pyrimidine ring, a pyrazine ring, a pyridazine ring, or the like), a triazine ring, or a polyazole ring. Other examples include a heteroaromatic compound having a bipyridine structure, a heteroaromatic compound having a terpyridine structure, and the like, which are included in examples of a heteroaromatic compound in which pyridine rings are connected.

Examples of the heteroaromatic compound having a fused ring structure partly including the above six-membered ring structure include a heteroaromatic compound having a fused heteroaromatic ring such as a quinoline ring, a benzoquinoline ring, a quinoxaline ring, a dibenzoquinoxaline ring, a phenanthroline ring, a furodiazine ring (including a structure in which an aromatic ring is fused to a furan ring of a furodiazine ring), or a benzimidazole ring.

Specific examples of the above-described heteroaromatic compound having a five-membered ring structure (a polyazole ring (including an imidazole ring, a triazole ring, or an oxadiazole ring), an oxazole ring, a thiazole ring, or a benzimidazole ring) include 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 3-(4-biphenylyl)-4-phenyl-5-(4-tert-butylphenyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), and 4,4′-bis(5-methylbenzoxazol-2-yl)stilbene (abbreviation: BzOs).

Specific examples of the above-described heteroaromatic compound having a six-membered ring structure (including a heteroaromatic ring having a pyridine ring, a diazine ring, a triazine ring, or the like) include a heteroaromatic compound including a heteroaromatic ring having a pyridine ring, such as 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB); a heteroaromatic compound including a heteroaromatic ring having a triazine ring, such as 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-[3′-(triphenylen-2-yl)biphenyl-3-yl]-4,6-diphenyl-1,3,5-triazine (abbreviation: mTpBPTzn), 2-(biphenyl-4-yl)-4-phenyl-6-(9,9′-spirobi[9H-fluoren]-2-yl)-1,3,5-triazine (abbreviation: BP-SFTzn), 2,6-bis(4-naphthalen-1-ylphenyl)-4-[4-(3-pyridyl)phenyl]pyrimidine (abbreviation: 2,4NP-6PyPPm), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn), 2-{3-[3-(dibenzothiophen-4-yl)phenyl]phenyl}-4,6-diphenyl-1,3,5-triazine (abbreviation: mDBtBPTzn), or mFBPTzn; and a heteroaromatic compound including a heteroaromatic ring having a diazine (pyrimidine) ring, such as 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 4,6mCzBP2Pm, 6-(biphenyl-3-yl)-4-[3,5-bis(9H-carbazol-9-yl)phenyl]-2-phenylpyrimidine (abbreviation: 6mBP-4Cz2PPm), 4-[3,5-bis(9H-carbazol-9-yl)phenyl]-2-phenyl-6-(biphenyl-4-yl)pyrimidine (abbreviation: 6BP-4Cz2PPm), 4-[3-(dibenzothiophen-4-yl)phenyl]-8-(naphthalen-2-yl)-[1]benzofuro[3,2-d]pyrimidine (abbreviation: 8PN-4mDBtPBfpm), 8BP-4mDBtPBfpm, 9mDBtBPNfpr, 9pmDBtBPNfpr, 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)biphenyl-3-yl]naphtho[1′,2′:4,5]furo[3,2-d]pyrimidine (abbreviation: 8mDBtBPNfpm), or 8-[(2,2′-binaphthalen)-6-yl]-4-[3-(dibenzothiophen-4-yl)phenyl]-[1]benzofuro[3,2-d]pyrimidine (abbreviation: 8(βN2)-4mDBtPBfpm). Note that examples of the above aromatic compounds including a heteroaromatic ring include a heteroaromatic compound having a fused heteroaromatic ring.

Other examples include heteroaromatic compounds including a heteroaromatic ring having a diazine (pyrimidine) ring, such as 2,2′-(pyridine-2,6-diyl)bis(4-phenylbenzo[h]quinazoline) (abbreviation: 2,6(P-Bqn)₂Py), 2,2′-(2,2′-bipyridine-6,6′-diyl)bis(4-phenylbenzo[h]quinazoline) (abbreviation: 6,6′(P-Bqn)2BPy), 2,2′-(pyridine-2,6-diyl)bis{4-[4-(2-naphthyl)phenyl]-6-phenylpyrimidine} (abbreviation: 2,6(NP-PPm)2Py), or 6-(biphenyl-3-yl)-4-[3,5-bis(9H-carbazol-9-yl)phenyl]-2-phenylpyrimidine (abbreviation: 6mBP-4Cz2PPm), and a heteroaromatic compound including a heteroaromatic ring having a triazine ring, such as 2,4,6-tris(3′-(pyridin-3-yl)biphenyl-3-yl)-1,3,5-triazine (abbreviation: TmPPPyTz), 2,4,6-tris(2-pyridyl)-1,3,5-triazine (abbreviation: 2Py3Tz), or 2-[3-(2,6-dimethyl-3-pyridyl)-5-(9-phenanthryl)phenyl]-4,6-diphenyl-1,3,5-triazine (abbreviation: mPn-mDMePyPTzn).

Specific examples of the above-described heteroaromatic compound having a fused ring structure partly including a six-membered ring structure (the heteroaromatic compound having a fused ring structure) include a heteroaromatic compound having a quinoxaline ring, such as bathophenanthroline (abbreviation: Bphen), bathocuproine (abbreviation: BCP), 2,9-di(naphthalen-2-yl)-4,7-diphenyl-1,10-phenanthroline (abbreviation: NBphen), 2,2′-(1,3-phenylene)bis(9-phenyl-1,10-phenanthroline) (abbreviation: mPPhen2P), 2,2′-(pyridin-2,6-diyl)bis(4-phenylbenzo[h]quinazoline) (abbreviation: 2,6(P-Bqn)2Py), 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), and 2mpPCBPDBq.

For the electron-transport layers (114, 114a, and 114b), any of the metal complexes given below can be used as well as the heteroaromatic compounds described above. Examples of the metal complexes include a metal complex having a quinoline ring or a benzoquinoline ring, such as tris(8-quinolinolato)aluminum(III) (abbreviation: Alq₃), Almq₃, 8-quinolinolato-lithium (abbreviation: Liq), BeBq₂, bis(2-methyl-8-quinolinolato)(4-phenylphenolato)aluminum(III) (abbreviation: BAlq), or bis(8-quinolinolato)zinc(II) (abbreviation: Znq), and a metal complex having an oxazole ring or a thiazole ring, such as bis[2-(2-benzoxazolyl)phenolato]zinc(II) (abbreviation: ZnPBO), or bis[2-(2-benzothiazolyl)phenolato]zinc(II) (abbreviation: ZnBTZ).

High-molecular compounds such as poly(2,5-pyridinediyl) (abbreviation: PPy), poly [(9,9-dihexylfluorene-2,7-diyl)-co-(pyridine-3,5-diyl)] (abbreviation: PF-Py), and poly[(9,9-dioctylfluorene-2,7-diyl)-co-(2,2′-bipyridine-6,6′-diyl)] (abbreviation: PF-BPy) can be used as the electron-transport material.

Each of the electron-transport layers (114, 114a, and 114b) is not limited to a single layer and may be a stack of two or more layers each including any of the above substances.

### <Electron-Injection Layer>

The electron-injection layers (115, 115a, and 115b) include a substance having a high electron-injection property. The electron-injection layers (115, 115a, and 115b) are layers for increasing the efficiency of electron injection from the second electrode 102 and are preferably formed using a material whose value of the LUMO level has a small difference (less than or equal to 0.50 eV) from the work function of a material used for the second electrode 102. Thus, the electron-injection layer 115 can be formed using an alkali metal, an alkaline earth metal, or a compound thereof, such as lithium, cesium, lithium fluoride (LiF), cesium fluoride (CsF), calcium fluoride (CaF₂), 8-quinolinolato-lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), an oxide of lithium (LiOₓ), or cesium carbonate. A rare earth metal or a compound of a rare earth metal, such as erbium fluoride (ErF₃) or ytterbium (Yb), can also be used. It is also possible to use a compound including a 1,3,4,6,7,8-tetrahydro-2H-pyrimido[1,2-a]pyrimidine skeleton, such as 1-(9,9′-spirobi[9H-fluoren]-2-yl)-1,3,4,6,7,8-hexahydro-2H-pyrimido[1,2-a]pyrimidine (abbreviation: 2hppSF), 1,1′-(9,9′-spirobi[9H-fluorene]-2,7-diyl)bis(1,3,4,6,7,8-hexahydro-2H-pyrimido[1,2-a]pyrimidine) (abbreviation: 2,7hpp2SF), or 1,1′-pyridine-2,6-diyl-bis(1,3,4,6,7,8-hexahydro-2H-pyrimido[1,2-a]pyrimidine) (abbreviation: hpp2Py). For the electron-injection layers (115, 115a, and 115b), a plurality of kinds of materials given above may be mixed or stacked as films. Electride may also be used for the electron-injection layers (115, 115a, and 115b). Examples of the electride include a substance in which electrons are added at high concentration to calcium oxide-aluminum oxide. Any of the substances used for the electron-transport layers (114, 114a, and 114b), which are given above, can also be used.

A mixed material in which an organic compound and an electron donor (donor) are mixed may also be used for the electron-injection layers (115, 115a, and 115b). Such a mixed material is excellent in an electron-injection property and an electron-transport property because electrons are generated in the organic compound by the electron donor. The organic compound here is preferably a material excellent in transporting the generated electrons; specifically, for example, the above-described electron-transport materials used for the electron-transport layers (114, 114a, and 114b), such as a metal complex and a heteroaromatic compound, can be used. As the electron donor, a substance showing an electron-donating property with respect to an organic compound can be used. Specifically, an alkali metal, an alkaline earth metal, and a rare earth metal are preferable, and lithium, cesium, magnesium, calcium, erbium, ytterbium, and the like are given as examples. In addition, an alkali metal oxide and an alkaline earth metal oxide are preferable, and lithium oxide, calcium oxide, barium oxide, and the like are given as examples. Alternatively, a Lewis base such as magnesium oxide can be used. Further alternatively, an organic compound such as tetrathiafulvalene (abbreviation: TTF) can be used. Alternatively, a stack of two or more of these materials may be used.

A mixed material in which an organic compound and a metal are mixed may also be used for the electron-injection layers (115, 115a, and 115b). The organic compound used here preferably has a LUMO level higher than or equal to −3.60 eV and lower than or equal to −2.30 eV. Moreover, a material having an unshared electron pair is preferable.

Thus, as the organic compound used in the above mixed material, a mixed material obtained by mixing a metal and the heteroaromatic compound given above as the material that can be used for the electron-transport layer may be used. Preferable examples of the heteroaromatic compound include materials having an unshared electron pair, such as a heteroaromatic compound having a five-membered ring structure (e.g., an imidazole ring, a triazole ring, an oxazole ring, an oxadiazole ring, a thiazole ring, or a benzimidazole ring), a heteroaromatic compound having a six-membered ring structure (e.g., a pyridine ring, a diazine ring (including a pyrimidine ring, a pyrazine ring, a pyridazine ring, or the like), a triazine ring, a bipyridine ring, or a terpyridine ring), and a heteroaromatic compound having a fused ring structure partly including a six-membered ring structure (e.g., a quinoline ring, a benzoquinoline ring, a quinoxaline ring, a dibenzoquinoxaline ring, or a phenanthroline ring). Since the materials are specifically described above, description thereof is omitted here.

As a metal used for the above mixed material, a transition metal that belongs to Group 5, Group 7, Group 9, or Group 11 or a material that belongs to Group 13 in the periodic table is preferably used, and examples include Ag, Cu, Al, and In. Here, the organic compound forms a singly occupied molecular orbital (SOMO) with the transition metal.

To amplify light obtained from the light-emitting layer 113b, for example, the optical path length between the second electrode 102 and the light-emitting layer 113b is preferably less than one fourth of the wavelength k of light emitted from the light-emitting layer 113b. In that case, the optical path length can be adjusted by changing the thickness of the electron-transport layer 114b or the electron-injection layer 115b.

When the charge-generation layer 106 is provided between the two EL layers (103a and 103b) as in the light-emitting device in FIG. 13E, a structure in which a plurality of EL layers are stacked between the pair of electrodes (the structure is also referred to as a tandem-type structure) can be obtained.

### <Charge-Generation Layer>

The charge-generation layer 106 has a function of injecting electrons into the EL layer 103a and injecting holes into the EL layer 103b when voltage is applied between the first electrode (anode) 101 and the second electrode (cathode) 102. The charge-generation layer 106 may be either a p-type layer in which an electron acceptor (acceptor) is added to a hole-transport material or an electron-injection buffer layer in which an electron donor (donor) is added to an electron-transport material. Alternatively, both of these structures may be stacked. Furthermore, an electron-relay layer may be provided between the p-type layer and the electron-injection buffer layer. Note that forming the charge-generation layer 106 with the use of any of the above materials can inhibit an increase in driving voltage caused by the stack of the EL layers.

In the case where the charge-generation layer 106 is a p-type layer in which an electron acceptor is added to a hole-transport material, which is an organic compound, any of the materials described in this embodiment can be used as the hole-transport material. Examples of the electron acceptor include 7,7,8,8-tetracyano-2,3,5,6-tetrafluoroquinodimethane (abbreviation: F₄-TCNQ) and chloranil. Other examples include oxides of metals that belong to Group 4 to Group 8 of the periodic table. Specific examples include vanadium oxide, niobium oxide, tantalum oxide, chromium oxide, molybdenum oxide, tungsten oxide, manganese oxide, and rhenium oxide. Any of the above-described acceptor materials may be used. Furthermore, a mixed film obtained by mixing materials of a p-type layer or a stack of films including the respective materials may be used.

In the case where the charge-generation layer 106 is an electron-injection buffer layer in which an electron donor is added to an electron-transport material, any of the materials described in this embodiment can be used as the electron-transport material. As the electron donor, it is possible to use an alkali metal, an alkaline earth metal, a rare earth metal, a metal belonging to Group 2 or Group 13 of the periodic table, or an oxide or a carbonate thereof. Specifically, lithium (Li), cesium (Cs), magnesium (Mg), calcium (Ca), ytterbium (Yb), indium (In), lithium oxide (Li₂O), cesium carbonate, or the like is preferably used. An alkali metal compound such as Liq may be used. An organic compound such as tetrathianaphthacene may be used as the electron donor. An organic compound including a 1,3,4,6,7,8-tetrahydro-2H-pyrimido[1,2-a]pyrimidine skeleton, such as 2hppSF, 2,7hpp2SF, or hpp2Py may be used as the electron donor. When any of these organic compounds is used as the electron donor, the electron-transport material to be combined with the electron donor is preferably an organic compound including a heteroaromatic ring having a phenanthroline ring, such as bathophenanthroline (abbreviation: Bphen), bathocuproine (abbreviation: BCP), 2,9-di(naphthalen-2-yl)-4,7-diphenyl-1,10-phenanthroline (abbreviation: NBphen), or 2,2′-(1,3-phenylene)bis(9-phenyl-1,10-phenanthroline) (abbreviation: mPPhen2P), in which case driving voltage of the light-emitting device can be reduced.

When an electron-relay layer is provided between a p-type layer and an electron-injection buffer layer in the charge-generation layer 106, the electron-relay layer includes at least a substance having an electron-transport property and has a function of preventing an interaction between the electron-injection buffer layer and the p-type layer and transferring electrons smoothly. The LUMO level of the substance having an electron-transport property in the electron-relay layer is preferably between the LUMO level of the acceptor substance in the p-type layer and the LUMO level of the substance having an electron-transport property in the electron-transport layer in contact with the charge-generation layer 106. Specifically, the LUMO level of the substance having an electron-transport property in the electron-relay layer is preferably higher than or equal to −5.00 eV, further preferably higher than or equal to −5.00 eV and lower than or equal to −3.00 eV. Note that as the substance having an electron-transport property in the electron-relay layer, a phthalocyanine-based material or a metal complex having a metal-oxygen bond and an aromatic ligand is preferably used.

Note that in terms of light extraction efficiency, the charge-generation layer 106 preferably has a property of transmitting visible light (specifically, the charge-generation layer 106 preferably has a visible light transmittance higher than or equal to 40%). The charge-generation layer 106 functions even if it has lower conductivity than the first electrode 101 and the second electrode 102.

Although FIG. 13E illustrates the structure in which two of the EL layers 103 are stacked, three or more EL layers may be stacked with charge-generation layers each provided between two adjacent EL layers.

### <Cap Layer>

Although not illustrated in FIGS. 13A to 13E, a cap layer may be provided over the second electrode 102 of the light-emitting device. For example, a material with a high refractive index can be used for the cap layer. When the cap layer is provided over the second electrode 102, extraction efficiency of light emitted through the second electrode 102 can be improved.

Specific examples of a material that can be used for the cap layer include 5,5′-diphenyl-2,2′-di-5H-[1]benzothieno[3,2-c]carbazole (abbreviation: BisBTc) and 4,4′,4″-(benzene-1,3,5-triyl)tri(dibenzothiophene) (abbreviation: DBT3P-II).

### <Substrate>

The light-emitting device described in this embodiment can be formed over a variety of substrates. Note that the type of substrate is not limited to a certain type. Examples of the substrate include semiconductor substrates (e.g., a single crystal substrate and a silicon substrate), an SOI substrate, a glass substrate, a quartz substrate, a plastic substrate, a metal substrate, a stainless steel substrate, a substrate including stainless steel foil, a tungsten substrate, a substrate including tungsten foil, a flexible substrate, an attachment film, and paper or a base material film including a fibrous material.

Examples of the glass substrate include a barium borosilicate glass substrate, an aluminoborosilicate glass substrate, and a soda lime glass substrate. Examples of the flexible substrate, the attachment film, and the base material film include plastics typified by polyethylene terephthalate (PET), polyethylene naphthalate (PEN), and polyether sulfone (PES), a synthetic resin such as an acrylic resin, polypropylene, polyester, polyvinyl fluoride, polyvinyl chloride, polyamide, polyimide, aramid, an epoxy resin, an inorganic vapor deposition film, and paper.

For manufacturing the light-emitting device in this embodiment, a gas phase method such as an evaporation method or a liquid phase method such as a spin coating method or an ink-jet method can be used. When an evaporation method is used, a physical vapor deposition method (PVD method) such as a sputtering method, an ion plating method, an ion beam evaporation method, a molecular beam evaporation method, or a vacuum evaporation method, a chemical vapor deposition method (CVD method), or the like can be used. Specifically, the layers having various functions (the hole-injection layer 111, the hole-transport layer 112, the light-emitting layer 113, the electron-transport layer 114, and the electron-injection layer 115) included in the EL layers of the light-emitting device can be formed by an evaporation method (e.g., a vacuum evaporation method), a coating method (e.g., a dip coating method, a die coating method, a bar coating method, a spin coating method, or a spray coating method), a printing method (e.g., an ink-jet method, screen printing (stencil), offset printing (planography), flexography (relief printing), gravure printing, or micro-contact printing), or the like.

In the case where a film formation method such as the coating method or the printing method is employed, a high-molecular compound (e.g., an oligomer, a dendrimer, or a polymer), a middle-molecular compound (a compound between a low-molecular compound and a high-molecular compound with a molecular weight of 400 to 4000), an inorganic compound (e.g., a quantum dot material), or the like can be used. The quantum dot material can be a colloidal quantum dot material, an alloyed quantum dot material, a core-shell quantum dot material, a core quantum dot material, or the like.

Materials that can be used for the layers (the hole-injection layer 111, the hole-transport layer 112, the light-emitting layer 113, the electron-transport layer 114, and the electron-injection layer 115) included in the EL layer 103 of the light-emitting device described in this embodiment are not limited to the materials described in this embodiment, and other materials can be used in combination as long as the functions of the layers are fulfilled.

The structures described in this embodiment can be used in appropriate combination with any of the structures described in the other embodiments.

### Embodiment 4

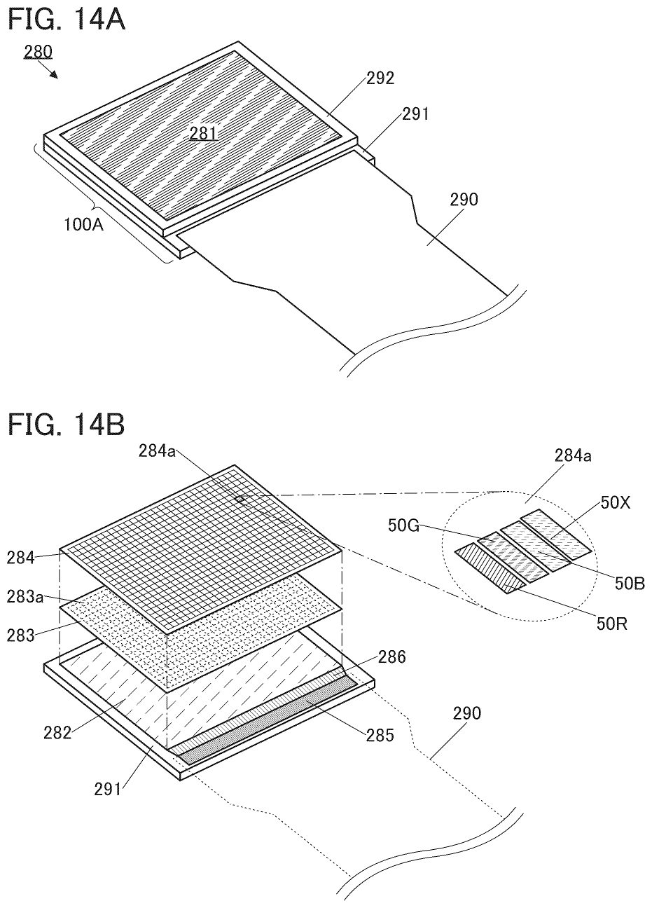

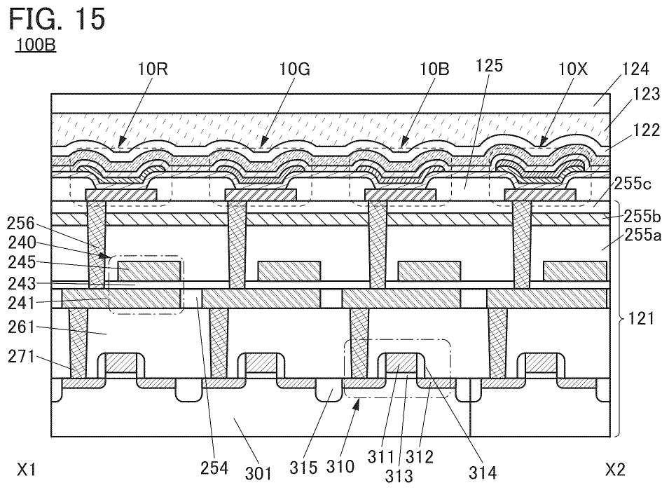

In this embodiment, display devices of embodiments of the present invention will be described with reference to FIGS. 14A and 14B and FIG. 15.

The display device in this embodiment can be a high-resolution display device. Accordingly, the display device in this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

The display device in this embodiment can be a high-definition display device or a large-sized display device. Accordingly, the display device in this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or notebook personal computer, a monitor of a computer or the like, digital signage, and a large game machine such as a pachinko machine.

### [Display Module]

FIG. 14A is a perspective view of a display module 280. The display module 280 includes the display device 100A and an FPC 290.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 14B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is provided in a portion not overlapping with the pixel portion 284 over the substrate 291. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 14B. The pixel 284a can employ any of the structures described in the above embodiments. FIG. 14B illustrates an example where a structure similar to that of the pixel 110 illustrated in FIG. 1A is employed.

The pixel circuit portion 283 includes a plurality of pixel circuits 283a arranged periodically.

Each of the pixel circuits 283a is a circuit that controls driving of a plurality of elements included in one pixel 284a. Each of the pixel circuits 283a can be provided with three circuits each of which controls light emission of one light-emitting device. For example, the pixel circuit 283a can include at least one selection transistor, one current control transistor (driving transistor), and a capacitor for one light-emitting device. In this case, a gate signal is input to a gate of the selection transistor, and a source signal is input to a source of the selection transistor. Thus, an active-matrix display device is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; thus, the aperture ratio (the effective display area ratio) of the display portion 281 can be significantly high. For example, the aperture ratio of the display portion 281 can be greater than or equal to 40% and less than 100%, preferably greater than or equal to 50% and less than or equal to 95%, and further preferably greater than or equal to 60% and less than or equal to 95%. Furthermore, the pixels 284a can be arranged extremely densely and thus the display portion 281 can have extremely high resolution. For example, the pixels 284a are preferably arranged in the display portion 281 with a resolution greater than or equal to 2000 ppi, preferably greater than or equal to 3000 ppi, further preferably greater than or equal to 5000 ppi, still further preferably greater than or equal to 6000 ppi, and less than or equal to 20000 ppi or less than or equal to 30000 ppi.

Such a display module 280 has extremely high resolution, and thus can be suitably used for a device for VR such as an HMD or a glasses-type device for AR. For example, even in the case of a structure in which the display portion of the display module 280 is seen through a lens, pixels of the extremely-high-resolution display portion 281 included in the display module 280 are prevented from being seen when the display portion is enlarged by the lens, so that display providing a high sense of immersion can be performed. Without being limited thereto, the display module 280 can be suitably used for electronic devices including a relatively small display portion. For example, the display module 280 can be suitably used in a display portion of a wearable electronic device, such as a wrist watch.

### [Display Device 100B]

A display device 100B illustrated in FIG. 15 includes a substrate 301, the light-emitting device 10R, the light-emitting device 10G, the light-emitting device 10B, the light-emitting device 10X, and transistors 310.

The subpixel 50R illustrated in FIG. 14B includes the light-emitting device 10R, the subpixel 50G includes the light-emitting device 10G, the subpixel 50B includes the light-emitting device 10B, and the subpixel 50X includes the light-emitting device 10X.

The substrate 301 corresponds to the substrate 291 in FIGS. 14A and 14B. A stacked-layer structure including the substrate 301 and the components thereover up to an insulating layer 255c corresponds to the layer 121 including transistors in Embodiment 1.

The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is located between the substrate 301 and the conductive layer 311 and functions as a gate insulating layer. The low-resistance region 312 is a region where the substrate 301 is doped with an impurity, and functions as one of a source and a drain. The insulating layer 314 is provided to cover a side surface of the conductive layer 311.

An element isolation layer 315 is provided so as to be embedded in the substrate 301 between two of the transistors 310 that are adjacent to each other.

Furthermore, an insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

Note that a conductive layer surrounding the outer surface of the display portion 281 (or the pixel portion 284) is preferably provided in at least one layer of the conductive layers included in the layer 121 including transistors. The conductive layer can be referred to as a guard ring. By providing the conductive layer, elements such as a transistor and a light-emitting device can be inhibited from being broken by high voltage application due to electrostatic discharge (ESD) or charging caused by a step using plasma.

The insulating layer 255a is provided to cover the capacitor 240, the insulating layer 255b is provided over the insulating layer 255a, and the insulating layer 255c is provided over the insulating layer 255b. The light-emitting devices 10R, 10G, 10B, and 10X are provided over the insulating layer 255c.

The anodes of the light-emitting devices 10R, 10G, 10B, and 10X are each electrically connected to the one of the source and the drain of the transistor 310 through a plug 256 embedded in the insulating layers 243, 255a, 255b, and 255c, the conductive layer 241 embedded in the insulating layer 254, and the plug 271 embedded in the insulating layer 261. The surface of the insulating layer 255c that is in contact with the anode and the surface of the plug 256 that is in contact with the anode are level or substantially level with each other. Any of a variety of conductive materials can be used for the plugs.

The protective layer 122 is provided over the light-emitting devices 10R, 10G, 10B, and 10X. The substrate 124 is attached to the protective layer 122 with the resin layer 123. Embodiment 1 can be referred to for the details of the light-emitting devices and the components thereover up to the substrate 124. The substrate 124 corresponds to the substrate 292 in FIG. 14A.

As the protective layer 122, at least one of an insulating film, a semiconductor film, and a conductive film can be used. The protective layer 122 including an inorganic film can inhibit deterioration of the light-emitting devices by preventing oxidation of cathodes and inhibiting entry of impurities (e.g., moisture and oxygen) into the light-emitting devices, for example; thus, the reliability of the display device can be improved.

As the protective layer 122, an inorganic insulating film such as an oxide insulating film, a nitride insulating film, an oxynitride insulating film, or a nitride oxide insulating film can be used, for example. Specific examples of these inorganic insulating films are as listed in the description of the insulating layer 125. In particular, the protective layer 122 preferably includes a nitride insulating film or a nitride oxide insulating film, and further preferably includes a nitride insulating film.

For the resin layer 123, any of a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene-vinyl acetate (EVA) resin. In particular, a material with low moisture permeability, such as an epoxy resin, is preferable. A two-component-mixture-type resin may be used. An adhesive sheet or the like may be used.

For the substrate 124, glass, quartz, ceramic, sapphire, a resin, a metal, an alloy, a semiconductor, or the like can be used. The substrate through which light from the light-emitting devices is extracted is formed using a material that transmits the light. When a flexible material is used for the substrate 124, the flexibility of the display device can be increased. Furthermore, a polarizing plate or the like may be used. As described above, any of a variety of members can be used as the substrate.

For the substrate 124, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as the substrate 124.

An inorganic insulating film is preferably used as the insulating layer 125. As the inorganic insulating film, a silicon nitride film, a silicon oxynitride film, a silicon oxide film, a silicon nitride oxide film, an aluminum oxide film, or an aluminum nitride film can be used, for example. Alternatively, a hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used.

There is no particular limitation on the structure of the transistors included in the display device of this embodiment. For example, a planar transistor, a staggered transistor, or an inverted staggered transistor can be used. A top-gate transistor or a bottom-gate transistor can be used. Alternatively, gates may be provided above and below a semiconductor layer where a channel is formed.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case deterioration of the transistor characteristics can be inhibited.

It is preferable that a semiconductor layer of a transistor include a metal oxide (also referred to as an oxide semiconductor). That is, a transistor including a metal oxide in its channel formation region (hereinafter referred to as an OS transistor) is preferably used in the display device of this embodiment.

As examples of the oxide semiconductor having crystallinity, a c-axis aligned crystalline oxide semiconductor (CAAC-OS), a nanocrystalline oxide semiconductor (nc-OS), and the like are given.

Alternatively, a transistor including silicon in its channel formation region (a Si transistor) may be used. Examples of silicon include single crystal silicon, polycrystalline silicon, and amorphous silicon. In particular, a transistor including low-temperature polysilicon (LTPS) in its semiconductor layer (hereinafter also referred to as an LTPS transistor) can be used. The LTPS transistor has high field-effect mobility and excellent frequency characteristics.

With the use of Si transistors such as LTPS transistors, a circuit required to be driven at a high frequency (e.g., a source driver circuit) can be formed on the same substrate as the display portion. This enables simplification of an external circuit mounted on the display device and a reduction in costs of parts and mounting costs.

The OS transistor has much higher field-effect mobility than a transistor including amorphous silicon. In addition, the OS transistor has an extremely low leakage current between a source and a drain in an off state (hereinafter also referred to as off-state current), and electric charge accumulated in a capacitor that is connected in series to the transistor can be held for a long period. Furthermore, the power consumption of the display device can be reduced with the OS transistor.

To increase the emission luminance of the light-emitting device included in the pixel circuit, the amount of current fed through the light-emitting device needs to be increased. To increase the current amount, the source-drain voltage of a driving transistor included in the pixel circuit needs to be increased. An OS transistor has a higher breakdown voltage between a source and a drain than a Si transistor; hence, high voltage can be applied between the source and the drain of the OS transistor. Thus, with use of an OS transistor as a driving transistor included in the pixel circuit, the amount of current flowing through the light-emitting device can be increased, resulting in an increase in emission luminance of the light-emitting device.

When transistors operate in a saturation region, a change in source-drain current relative to a change in gate-source voltage can be smaller in an OS transistor than in a Si transistor. Accordingly, when an OS transistor is used as the driving transistor in the pixel circuit, a current flowing between the source and the drain can be set minutely in accordance with a change in gate-source voltage; hence, the amount of current flowing through the light-emitting device can be controlled. Consequently, the number of gray levels expressed by the pixel circuit can be increased.

Regarding saturation characteristics of current flowing when transistors operate in a saturation region, even in the case where the source-drain voltage of an OS transistor increases gradually, a more stable current (saturation current) can be fed through the OS transistor than through a Si transistor. Thus, by using an OS transistor as the driving transistor, a stable current can be fed through light-emitting devices even when the current-voltage characteristics of the light-emitting devices vary, for example. In other words, when the OS transistor operates in the saturation region, the source-drain current hardly changes with an increase in the source-drain voltage; hence, the emission luminance of the light-emitting device can be stable.

As described above, by using OS transistors as the driving transistors included in the pixel circuits, it is possible to inhibit black-level degradation, increase the emission luminance, increase the number of gray levels, and suppress variations in light-emitting devices, for example.

The semiconductor layer preferably includes indium, M (M is one or more of gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more of aluminum, gallium, yttrium, and tin.

It is particularly preferable that an oxide containing indium (In), gallium (Ga), and zinc (Zn) (also referred to as IGZO) be used for the semiconductor layer. Alternatively, it is preferable to use an oxide containing indium, tin, and zinc. Further alternatively, it is preferable to use an oxide containing indium, gallium, tin, and zinc. Further alternatively, it is preferable to use an oxide containing indium (In), aluminum (Al), and zinc (Zn) (also referred to as IAZO). Further alternatively, it is preferable to use an oxide containing indium (In), aluminum (Al), gallium (Ga), and zinc (Zn) (also referred to as IAGZO).

When the semiconductor layer is an In-M-Zn oxide, the atomic proportion of In is preferably greater than or equal to the atomic proportion of M in the In-M-Zn oxide. Examples of the atomic ratio of the metal elements in such an In-M-Zn oxide are In:M:Zn=1:1:1, 1:1:1.2, 1:3:2, 1:3:4, 2:1:3, 3:1:2, 4:2:3, 4:2:4.1, 5:1:3, 5:1:6, 5:1:7, 5:1:8, 6:1:6, and 5:2:5 and a composition in the vicinity of any of the above atomic ratios. Note that the vicinity of the atomic ratio includes ±30% of an intended atomic ratio.

For example, when the atomic ratio is described as In:Ga:Zn=4:2:3 or a composition in the vicinity thereof, the case is included where the atomic proportion of Ga is greater than or equal to 1 and less than or equal to 3 and the atomic proportion of Zn is greater than or equal to 2 and less than or equal to 4 with the atomic proportion of In being 4. In addition, when the atomic ratio is described as In:Ga:Zn=5:1:6 or a composition in the vicinity thereof, the case is included where the atomic proportion of Ga is greater than 0.1 and less than or equal to 2 and the atomic proportion of Zn is greater than or equal to 5 and less than or equal to 7 with the atomic proportion of In being 5. Furthermore, when the atomic ratio is described as In:Ga:Zn=1:1:1 or a composition in the vicinity thereof, the case is included where the atomic proportion of Ga is greater than 0.1 and less than or equal to 2 and the atomic proportion of Zn is greater than 0.1 and less than or equal to 2 with the atomic proportion of In being 1.

The structures described in this embodiment can be used in appropriate combination with any of the structures described in the other embodiments.

### Embodiment 5

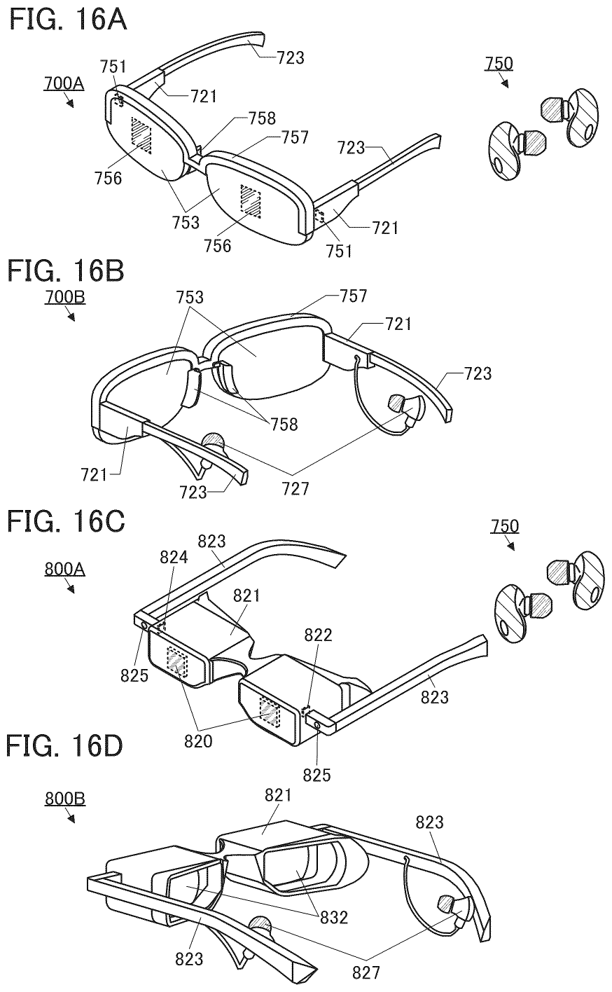

In this embodiment, electronic devices of embodiments of the present invention will be described with reference to FIGS. 16A to 16D, FIGS. 17A to 17F, and FIGS. 18A to 18G.

Electronic devices of this embodiment are each provided with the display device of one embodiment of the present invention in a display portion. The display device of one embodiment of the present invention can be easily increased in resolution and definition. Thus, the display device of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and notebook personal computers, a monitor of a computer or the like, digital signage, and a large game machine such as a pachinko machine.

In particular, the display device of one embodiment of the present invention can have a high resolution, and thus can be favorably used for an electronic device having a relatively small display portion. Examples of such an electronic device include watch-type and bracelet-type information terminal devices (wearable devices) and wearable devices capable of being worn on a head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display device of one embodiment of the present invention is preferably higher than or equal to 100 ppi, further preferably higher than or equal to 300 ppi, still further preferably higher than or equal to 500 ppi, yet still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. With such a display device having one or both of high definition and high resolution, the electronic device can provide higher realistic sensation, sense of depth, and the like in personal use such as portable use or home use. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device in this embodiment can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of a wearable device capable of being worn on a head will be described with reference to FIGS. 16A to 16D. The wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 700A illustrated in FIG. 16A and an electronic device 700B illustrated in FIG. 16B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic devices are capable of performing ultrahigh-resolution display.

The electronic devices 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic devices 700A and 700B are electronic devices capable of performing AR display.

In the electronic devices 700A and 700B, a camera capable of capturing images of the front side may be provided as the image capturing portion. Furthermore, when the electronic devices 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic devices 700A and 700B are provided with a battery so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables executing various types of processing. For example, a moving image can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving device. One or both of an inorganic semiconductor and an organic semiconductor can be used for an active layer of the photoelectric conversion device.

An electronic device 800A illustrated in FIG. 16C and an electronic device 800B illustrated in FIG. 16D each include a pair of display portions 820, a housing 821, a communication portion 822, a pair of wearing portions 823, a control portion 824, a pair of image capturing portions 825, and a pair of lenses 832.

The display device of one embodiment of the present invention can be used for the display portions 820. Thus, the electronic devices are capable of performing ultrahigh-resolution display. Such electronic devices provide a high sense of immersion to the user.

The display portions 820 are positioned inside the housing 821 so as to be seen through the lenses 832. When the pair of display portions 820 display different images, three-dimensional display using parallax can be performed.

The electronic devices 800A and 800B can be regarded as electronic devices for VR. The user who wears the electronic device 800A or 800B can see images displayed on the display portions 820 through the lenses 832.

The electronic devices 800A and 800B preferably include a mechanism for adjusting the lateral positions of the lenses 832 and the display portions 820 so that the lenses 832 and the display portions 820 are located optimally in accordance with the positions of the user's eyes. Moreover, the electronic devices 800A and 800B preferably include a mechanism for adjusting focus by changing the distance between the lenses 832 and the display portions 820.

The electronic device 800A or 800B can be mounted on the user's head with the wearing portions 823. FIG. 16C and the like illustrate examples where the wearing portion 823 has a shape like a temple (also referred to as a joint or the like) of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example where the image capturing portion 825 is provided is shown here, a range sensor (hereinafter also referred to as a sensing portion) capable of measuring a distance between the user and an object just needs to be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy video and sound only by wearing the electronic device 800A.

The electronic devices 800A and 800B may each include an input terminal (also referred to as an input portion). To the input terminal, a cable for supplying a video signal from a video output device or the like, power for charging the battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A in FIG. 16A has a function of transmitting information to the earphones 750 with the wireless communication function. For another example, the electronic device 800A in FIG. 16C has a function of transmitting information to the earphones 750 with the wireless communication function.

The electronic device may include an earphone portion. The electronic device 700B in FIG. 16B includes earphone portions 727. For example, the earphone portion 727 can be connected to the control portion by wire. Part of a wiring that connects the earphone portion 727 and the control portion may be located inside the housing 721 or the wearing portion 723.

Similarly, the electronic device 800B in FIG. 16D includes earphone portions 827. For example, the earphone portion 827 can be connected to the control portion 824 by wire. Part of a wiring that connects the earphone portion 827 and the control portion 824 may be located inside the housing 821 or the wearing portion 823. Alternatively, the earphone portions 827 and the wearing portions 823 may include magnets. This structure is preferably employed, in which case the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic devices 700A and 700B) and the goggles-type device (e.g., the electronic devices 800A and 800B) are preferable as the electronic device of one embodiment of the present invention.

The electronic device of one embodiment of the present invention can transmit information to earphones by wire or wirelessly.

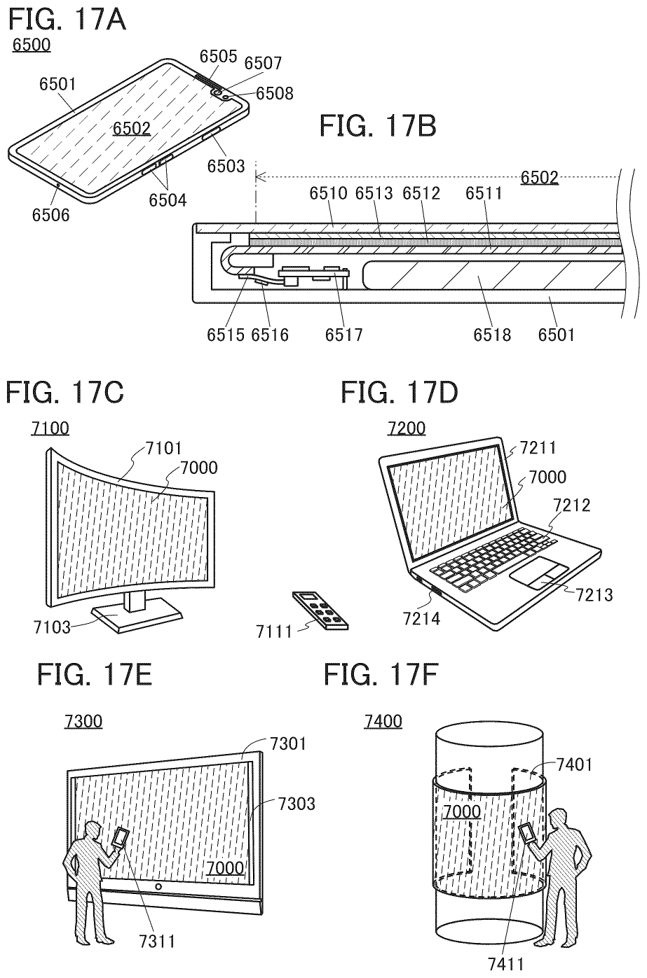

An electronic device 6500 illustrated in FIG. 17A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502.

FIG. 17B is a schematic cross-sectional view including an end portion of the housing 6501 closer to the microphone 6506.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display device of one embodiment of the present invention can be used for the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be achieved.

FIG. 17C illustrates an example of a television device. In a television device 7100, a display portion 7000 is incorporated in a housing 7101. Here, the housing 7101 is supported by a stand 7103.

The display device of one embodiment of the present invention can be used in the display portion 7000.

Operation of the television device 7100 illustrated in FIG. 17C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may be provided with a display portion for displaying information output from the remote control 7111. With operation keys or a touch panel provided in the remote control 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 17D illustrates an example of a notebook personal computer. The notebook personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000.

FIGS. 17E and 17F illustrate examples of digital signage.

Digital signage 7300 illustrated in FIG. 17E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 17F illustrates digital signage 7400 attached to a cylindrical pillar 7401. The digital signage 7400 includes the display portion 7000 provided along a curved surface of the pillar 7401.

The display device of one embodiment of the present invention can be used in the display portion 7000 illustrated in each of FIGS. 17E and 17F.

A larger area of the display portion 7000 allows a larger amount of information to be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIGS. 17E and 17F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

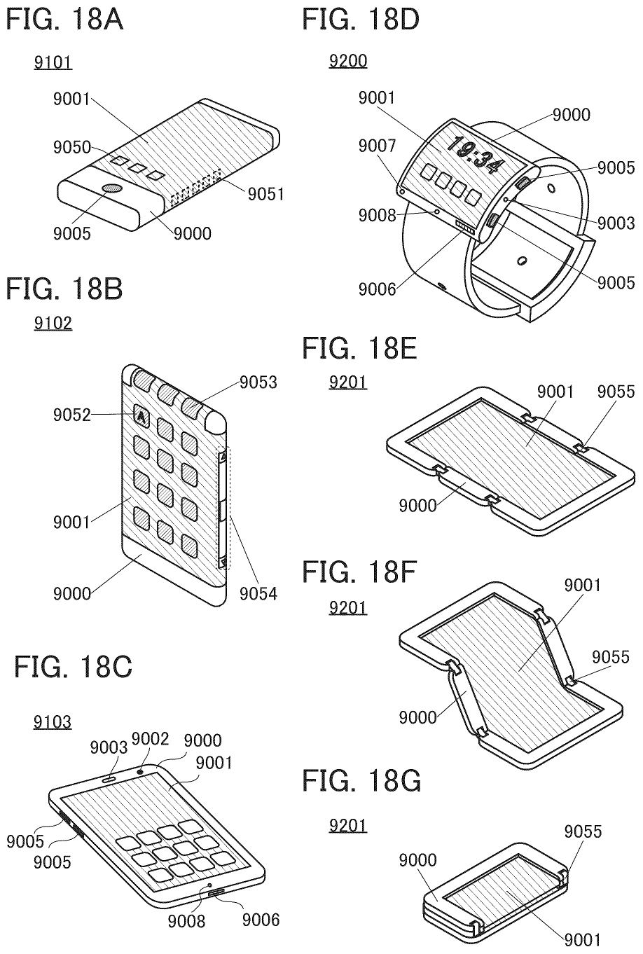

Electronic devices illustrated in FIGS. 18A to 18G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, a smell, or infrared rays), a microphone 9008, and the like.

The electronic devices illustrated in FIGS. 18A to 18G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may be provided with a camera or the like and have a function of capturing a still image or a moving image, a function of storing the captured image in a storage medium (an external storage medium or a storage medium incorporated in the camera), a function of displaying the captured image on the display portion, and the like.

The electronic devices in FIGS. 18A to 18G will be described in detail below.

FIG. 18A is a perspective view of a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 18A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 18B is a perspective view of a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. Thus, the user can see the display without taking out the portable information terminal 9102 from the pocket and decide whether to answer the call, for example.

FIG. 18C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 18D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 18E to 18G are perspective views of a foldable portable information terminal 9201. FIG. 18E is a perspective view illustrating the portable information terminal 9201 that is opened. FIG. 18G is a perspective view illustrating the portable information terminal 9201 that is folded. FIG. 18F is a perspective view illustrating the portable information terminal 9201 that is shifted from one of the states in FIGS. 18E and 18G to the other. The portable information terminal 9201 is highly portable when folded. When the portable information terminal 9201 is opened, a seamless large display region is highly browsable. The display portion 9001 of the portable information terminal 9201 is supported by three of the housings 9000 joined together by hinges 9055. The display portion 9001 can be folded with a radius of curvature greater than or equal to 0.1 mm and less than or equal to 150 mm, for example.

The structures described in this embodiment can be used in appropriate combination with any of the structures described in the other embodiments.

This application is based on Japanese Patent Application Serial No. 2023-123339 filed with Japan Patent Office on Jul. 28, 2023, the entire contents of which are hereby incorporated by reference.

What is claimed is:

1. A display device comprising:
a first light-emitting device;
a second light-emitting device; and
a third light-emitting device,
wherein the first light-emitting device comprises a first anode, a first cathode, and a first light-emitting layer, the first light-emitting layer being between the first anode and the first cathode,
wherein the second light-emitting device comprises a second anode, a second cathode, and a second light-emitting layer, the second light-emitting layer being between the second anode and the second cathode,
wherein the third light-emitting device comprises a third anode, a third cathode, a third light-emitting layer, and a fourth light-emitting layer, the third light-emitting layer and the fourth light-emitting layer being between the third anode and the third cathode,
wherein the fourth light-emitting layer is between the third light-emitting layer and the third cathode and is in contact with the third light-emitting layer,
wherein a color of light emitted from the first light-emitting device, a color of light emitted from the second light-emitting device, and a color of light emitted from the third light-emitting device are different from each other,
wherein the first light-emitting layer and the third light-emitting layer comprise a first light-emitting substance,
wherein the second light-emitting layer and the fourth light-emitting layer comprise a second light-emitting substance, and
wherein a peak wavelength of an emission spectrum of the first light-emitting substance and a peak wavelength of an emission spectrum of the second light-emitting substance are different from each other.

2. The display device according to claim 1,
wherein the peak wavelength of the emission spectrum of the first light-emitting substance is longer than the peak wavelength of the emission spectrum of the second light-emitting substance, and
wherein a thickness of the third light-emitting layer is smaller than a thickness of the fourth light-emitting layer.

3. The display device according to claim 1,
wherein the peak wavelength of the emission spectrum of the first light-emitting substance is longer than the peak wavelength of the emission spectrum of the second light-emitting substance, and
wherein the first light-emitting layer and the third light-emitting layer comprise a hole-transport material.

4. The display device according to claim 3,
wherein the first light-emitting device comprises a hole-blocking layer between the first light-emitting layer and the first cathode.

5. The display device according to claim 1, further comprising a fourth light-emitting device,
wherein the fourth light-emitting device comprises a fourth anode, a fourth cathode, and a fifth light-emitting layer, the fifth light-emitting layer being between the fourth anode and the fourth cathode,
wherein the third light-emitting device comprises a sixth light-emitting layer between the third anode and the third cathode,
wherein the sixth light-emitting layer is between the fourth light-emitting layer and the third cathode and is in contact with the fourth light-emitting layer,
wherein the fifth light-emitting layer and the sixth light-emitting layer comprise a third light-emitting substance, and
wherein a peak wavelength of an emission spectrum of the third light-emitting substance is different from the peak wavelength of the emission spectrum of the first light-emitting substance and the peak wavelength of the emission spectrum of the second light-emitting substance.

6. A display device comprising:
a first light-emitting device;
a second light-emitting device; and
a third light-emitting device,
wherein the first light-emitting device comprises a first anode, a first cathode, a first light-emitting layer, and a first hole-blocking layer, the first light-emitting layer and the first hole-blocking layer being between the first anode and the first cathode,
wherein the first hole-blocking layer is between the first light-emitting layer and the first cathode,
wherein the second light-emitting device comprises a second anode, a second cathode, and a second light-emitting layer, the second light-emitting layer being between the second anode and the second cathode,
wherein the third light-emitting device comprises a third anode, a third cathode, a third light-emitting layer, and a fourth light-emitting layer, the third light-emitting layer and the fourth light-emitting layer being between the third anode and the third cathode,
wherein the fourth light-emitting layer is between the third light-emitting layer and the third cathode,
wherein a color of light emitted from the first light-emitting device, a color of light emitted from the second light-emitting device, and a color of light emitted from the third light-emitting device are different from each other,
wherein the first light-emitting layer and the third light-emitting layer comprise a first light-emitting substance and a hole-transport material,
wherein the second light-emitting layer and the fourth light-emitting layer comprise a second light-emitting substance, and
wherein a peak wavelength of an emission spectrum of the first light-emitting substance and a peak wavelength of an emission spectrum of the second light-emitting substance are different from each other.

7. The display device according to claim 6,
wherein the third light-emitting device comprises a second hole-blocking layer between the third light-emitting layer and the fourth light-emitting layer.

8. A display device comprising:
a first light-emitting device;
a second light-emitting device; and
a third light-emitting device,
wherein the first light-emitting device comprises a first anode, a first cathode, a first light-emitting layer, a second light-emitting layer, and a first intermediate layer, the first light-emitting layer, the second light-emitting layer, and the first intermediate layer being between the first anode and the first cathode,
wherein the first intermediate layer is between the first light-emitting layer and the second light-emitting layer,
wherein the second light-emitting device comprises a second anode, a second cathode, a third light-emitting layer, a fourth light-emitting layer, and a second intermediate layer, the third light-emitting layer, the fourth light-emitting layer, and the second intermediate layer being between the second anode and the second cathode,
wherein the second intermediate layer is between the third light-emitting layer and the fourth light-emitting layer,
wherein the third light-emitting device comprises a third anode, a third cathode, a fifth light-emitting layer, a sixth light-emitting layer, and a third intermediate layer, the fifth light-emitting layer, the sixth light-emitting layer, and the third intermediate layer being between the third anode and the third cathode,
wherein the third intermediate layer is between the fifth light-emitting layer and the sixth light-emitting layer,
wherein a color of light emitted from the first light-emitting device, a color of light emitted from the second light-emitting device, and a color of light emitted from the third light-emitting device are different from each other,
wherein the first light-emitting layer, the second light-emitting layer, and the fifth light-emitting layer comprise a first light-emitting substance,
wherein the third light-emitting layer, the fourth light-emitting layer, and the sixth light-emitting layer comprise a second light-emitting substance, and
wherein a peak wavelength of an emission spectrum of the first light-emitting substance and a peak wavelength of an emission spectrum of the second light-emitting substance are different from each other.

9. The display device according to claim 8,
wherein the first intermediate layer, the second intermediate layer, and the third intermediate layer each comprise an organic compound and an alkali metal or an alkaline earth metal.

10. The display device according to claim 8,
wherein the first intermediate layer, the second intermediate layer, and the third intermediate layer comprise the same organic compound and the same alkali metal or the same alkaline earth metal.

11. The display device according to claim 8, further comprising a fourth light-emitting device,
wherein the fourth light-emitting device comprises a fourth anode, a fourth cathode, a seventh light-emitting layer, an eighth light-emitting layer, and a fourth intermediate layer, the seventh light-emitting layer, the eighth light-emitting layer, and the fourth intermediate layer being between the fourth anode and the fourth cathode,
wherein the fourth intermediate layer is between the seventh light-emitting layer and the eighth light-emitting layer,
wherein the third light-emitting device comprises a ninth light-emitting layer between the third anode and the third cathode,
wherein the ninth light-emitting layer is in contact with the sixth light-emitting layer,
wherein the seventh light-emitting layer, the eighth light-emitting layer, and the ninth light-emitting layer comprise a third light-emitting substance, and
wherein a peak wavelength of an emission spectrum of the third light-emitting substance is different from the peak wavelength of the emission spectrum of the first light-emitting substance and the peak wavelength of the emission spectrum of the second light-emitting substance.

12. The display device according to claim 11,
wherein the first intermediate layer, the second intermediate layer, the third intermediate layer, and the fourth intermediate layer each comprise an organic compound and an alkali metal or an alkaline earth metal.

13. The display device according to claim 11,
wherein the first intermediate layer, the second intermediate layer, the third intermediate layer, and the fourth intermediate layer comprise the same organic compound and the same alkali metal or the same alkaline earth metal.
